(19) United States
(12) Patent Application Publication
(10) Pub. No.: US 2025/0142999 A1
(43) Pub. Date: May 1, 2025

(54) PHOTODETECTOR AND METHOD OF MANUFACTURING PHOTODETECTOR

(71) Applicant: SONY SEMICONDUCTOR SOLUTIONS CORPORATION, Kanagawa (JP)

(72) Inventors: Yusuke KOHYAMA, Kanagawa (JP); Junpei YAMAMOTO, Kanagawa (JP); Kentaro EDA, Kumamoto (JP); Ryoji HASUMI, Kanagawa (JP); Hirofumi YAMASHITA, Kanagawa (JP)

(73) Assignee: SONY SEMICONDUCTOR SOLUTIONS CORPORATION, Kanagawa (JP)

(21) Appl. No.: 18/836,277

(22) PCT Filed: Feb. 14, 2023
(86) PCT No.: PCT/JP2023/004896

§ 371 Date: Aug. 6, 2024

Related U.S. Application Data
(60) Provisional application No. 63/310,284, filed on Feb. 15, 2022.

(51) Int. Cl. H10F 39/00; H10F 39/18

(52) U.S. Cl. CPC H10F 39/807; H10F 39/014; H10F 39/18; H10F 39/8037

(57) ABSTRACT

A first photodetector according to an embodiment of the present disclosure includes: a semiconductor substrate having a first surface and a second surface that are opposed to each other, and including a plurality of pixels arranged in an array; one or a plurality of transistors provided on the first surface of the semiconductor substrate in the pixel; and a first isolation trench that is provided in the semiconductor substrate, and isolates the plurality of pixels adjacent to each other from each other, and the first isolation trench being in contact with at least one of a source region or a drain region of the one or plurality of transistors in a plan view.

### TECHNICAL FIELD

The present disclosure relates to, for example, a photodetector that isolates active elements in a pixel by a trench, and a method of manufacturing a photodetector.

### BACKGROUND ART

For example, NPTL 1 discloses a solid-state imaging element in which a silicon (Si) substrate is provided with an FDTI (Front Deep Trench Isolation) and an STI (Shallow Trench Isolation). The FDTI is for isolating pixels, and the STI is for isolating various devices provided on a surface of the Si substrate.

### CITATION LIST

### Non-Patent Literature

NPTL 1: J. Park et al., ISSCC, p. 122, 2021

### SUMMARY OF THE INVENTION

In a photodetector used, for example, as an imaging device or the like in such a manner, a reduction in pixel size is desired.

It is desirable to provide a photodetector that makes it possible to reduce a pixel size, and a method of manufacturing the same.

A first photodetector according to an embodiment of the present disclosure includes: a semiconductor substrate having a first surface and a second surface that are opposed to each other, and including a plurality of pixels arranged in an array; one or a plurality of transistors provided on the first surface of the semiconductor substrate in the pixel; and a first isolation trench that is provided in the semiconductor substrate, and isolates the plurality of pixels adjacent to each other from each other, and the first isolation trench being in contact with at least one of a source region or a drain region of the one or plurality of transistors in a plan view.

A method of manufacturing a first photodetector according to an embodiment of the present disclosure includes: forming a groove in a semiconductor substrate having a first surface and a second surface that are opposed to each other, the groove extending from the first surface to the second surface; forming a first insulating film on a side surface and a bottom surface of the groove, and thereafter forming a polysilicon film in a lower portion of the groove; forming a second insulating film on a side surface of an upper portion of the groove, and thereafter, removing the polysilicon film and the first insulating film; forming a p-type impurity region in the semiconductor substrate exposed to the lower portion of the groove, and thereafter, removing the first insulating film and the second insulating film in the upper portion of the groove; and embedding a third insulating film in the groove to thereby self-alignedly form a first isolator and a second isolator, and thereafter, forming one or a plurality of transistors and a well contact region, the first isolator including a p-type impurity region on a side surface, the second isolator that isolates side of the first surface of the semiconductor substrate, and the well contact region that applies a reference potential to the semiconductor substrate.

In the firsts photodetector according to the embodiment of the present disclosure and the method of manufacturing the photodetector according to the embodiment of the present disclosure, the one or plurality of transistors formed on the first surface of the semiconductor substrate including the plurality of pixels arranged in an array is isolated with use of the first isolation trench that isolates the pixels adjacent to each other. This reduces an isolation distance between a plurality of active elements formed on the first surface of the semiconductor substrate.

A second photodetector according to an embodiment of the present disclosure includes: a semiconductor substrate having a first surface and a second surface that are opposed to each other, and including a plurality of pixels arranged in an array; a plurality of light-receiving sections formed to be embedded in the semiconductor substrate for the plurality of respective pixels, the plurality of light-receiving sections that generates electric charge corresponding to an amount of received light by photoelectric conversion; a first isolation trench that penetrates between the first surface and the second surface of the semiconductor substrate, and isolates the plurality of pixels adjacent to each other; a plurality of active elements provided on the first surface of the semiconductor substrate in the pixel; and a second isolation trench that is provided on the first surface of the semiconductor substrate to be spaced apart from the first isolation trench, and isolates the plurality of active elements.

In the second photodetector according to the embodiment of the present disclosure, the first isolation trench that penetrates between the first surface and the second surface of the semiconductor substrate, and the second isolation trench that isolates the plurality of active elements provided on the first surface of the semiconductor substrate in the pixel are formed to be spaced apart from each other. This independently control depths of the second isolation trench formed on the first isolation trench and the second isolation trench that isolates the active elements in the pixel.

A third photodetector according to an embodiment of the present disclosure includes: a semiconductor substrate having a first surface and a second surface that are opposed to each other, and including a plurality of pixels arranged in an array; a plurality of light-receiving sections formed to be embedded in the semiconductor substrate for the plurality of respective pixels, the plurality of light-receiving sections that generates electric charge corresponding to an amount of received light by photoelectric conversion; a first isolation trench that penetrates between the first surface and the second surface of the semiconductor substrate, and isolates the plurality of pixels adjacent to each other; a well contact region that is embedded in the first isolation trench and is formed inside the semiconductor substrate, the well contact region including a first p-type impurity region that applies a reference potential to the semiconductor substrate; and a floating diffusion layer provided on the first surface of the semiconductor substrate in the pixel, and including an n-type impurity region that temporarily holds the electric charge generated by the light-receiving section.

In the third photodetector according to the embodiment of the present disclosure, the well contact region including the first p-type impurity region that applies the reference potential to the semiconductor substrate is embedded in the first isolation trench that isolates the plurality of pixels adjacent to each other, and the well contact region is provided inside the semiconductor substrate. This reduces an area of the second isolation trench formed on the first surface of the semiconductor substrate 10.

A fourth photodetector according to an embodiment of the present disclosure includes: a semiconductor substrate having a first surface and a second surface that are opposed to each other, and including a plurality of pixels arranged in an array; a plurality of light-receiving sections formed to be embedded in the semiconductor substrate for the plurality of respective pixels, the plurality of light-receiving sections that generates electric charge corresponding to an amount of received light by photoelectric conversion; a plurality of active elements provided on the first surface of the semiconductor substrate in the pixel: a first isolation trench that extends between the first surface and the second surface of the semiconductor substrate, and isolates the plurality of pixels adjacent to each other; a second isolation trench that extends from the first surface to the second surface of the semiconductor substrate and has a bottom inside the semiconductor substrate, and isolates the plurality of active elements; a third isolation trench that extends from the first surface to the second surface of the semiconductor substrate, is stacked on the first isolation trench, and has a bottom closer to the second surface than the bottom of the second isolation trench; a fifth p-type impurity region formed along a side surface of the first isolation trench; and a floating diffusion layer provided on the first surface of the semiconductor substrate in the pixel, and including an n-type impurity region that temporarily holds the electric charge generated by the light-receiving section.

In the fourth photodetector according to the embodiment of the present disclosure, the third isolation trench deeper than the second isolation trench that isolates the active elements adjacent to each other in the pixel is stacked on the first isolation trench that penetrates between the first surface and the second surface of the semiconductor substrate. This increases a distance between the fifth p-type impurity region and the n-type impurity region. The fifth p-type impurity region is formed along the side surface of the first isolation trench that isolates the plurality of pixels adjacent to each other. The n-type impurity region is included in the floating diffusion layer formed on the first surface of the semiconductor substrate.

### BRIEF DESCRIPTION OF DRAWINGS

FIG. 1 is a schematic cross-sectional view of an example of a configuration of a photodetector according to a first embodiment of the present disclosure.

FIG. 2 is a block diagram illustrating an entire configuration of the photodetector illustrated in FIG. 1.

FIG. 3 is an equivalent circuit diagram of a unit pixel illustrated in FIG. 1.

FIG. 4 is a schematic view of an example of a planar configuration of the unit pixel of the photodetector illustrated in FIG. 1.

FIG. 5 is a schematic view of an example of layout in a pixel section including the unit pixel illustrated in FIG. 4.

FIG. 6 is a schematic cross-sectional view taken along a line II-II′ illustrated in FIG. 4.

FIG. 7A is a schematic cross-sectional view for describing a method of manufacturing the photodetector illustrated in FIG. 1.

FIG. 7B is a cross-sectional view of a process subsequent to FIG. 7A.

FIG. 7C is a cross-sectional view of a process subsequent to FIG. 7B.

FIG. 7D is a cross-sectional view of a process subsequent to FIG. 7C.

FIG. 7E is a cross-sectional view of a process subsequent to FIG. 7D.

FIG. 7F is a cross-sectional view of a process subsequent to FIG. 7E.

FIG. 7G is a cross-sectional view of a process subsequent to FIG. 7F.

FIG. 7H is a cross-sectional view of a process subsequent to FIG. 7G.

FIG. 8A is a cross-sectional view of a process subsequent to FIG. 7H.

FIG. 8B is a cross-sectional view of a process subsequent to FIG. 8A.

FIG. 8C is a cross-sectional view of a process subsequent to FIG. 8B.

FIG. 8D is a cross-sectional view of a process subsequent to FIG. 8C.

FIG. 8E is a cross-sectional view of a process subsequent to FIG. 8D.

FIG. 9 is a cross-sectional view of an example of a configuration of a typical photodetector.

FIG. 10 is a schematic cross-sectional view of an example of a configuration of a photodetector according to a modification example 1 of the present disclosure.

FIG. 11 is a schematic cross-sectional view of an example of a configuration of a photodetector according to a modification example 2 of the present disclosure.

FIG. 12 a schematic cross-sectional view of an example of a configuration of a photodetector according to a modification example 3 of the present disclosure.

FIG. 13A is a schematic cross-sectional view for describing a method of manufacturing the photodetector illustrated in FIG. 12.

FIG. 13B is a cross-sectional view of a process subsequent to FIG. 13A.

FIG. 14 is a schematic cross-sectional view of an example of a configuration of a photodetector according to a modification example 4 of the present disclosure.

FIG. 15A is a schematic cross-sectional view for describing a method of manufacturing the photodetector illustrated in FIG. 14.

FIG. 15B is a cross-sectional view of a process subsequent to FIG. 15A.

FIG. 15C is a cross-sectional view of a process subsequent to FIG. 15B.

FIG. 15D is a cross-sectional view of a process subsequent to FIG. 15C.

FIG. 16A is a schematic cross-sectional view for describing a method of manufacturing a photodetector described in a modification example 5 of the present disclosure.

FIG. 16B is a cross-sectional view of a process subsequent to FIG. 16A.

FIG. 17 is a schematic view of an example of a planar configuration of a unit pixel of a photodetector according to a second embodiment of the present disclosure.

FIG. 18A is a schematic cross-sectional view of an example of a configuration of the photodetector taken along a line III-III′ illustrated in FIG. 17.

FIG. 18B is a schematic cross-sectional view of an example of the configuration of the photodetector taken along a line IV-IV′ illustrated in FIG. 17.

FIG. 19 is a schematic cross-sectional view of another example of the configuration of the photodetector taken along a line III-III′ illustrated in FIG. 17.

FIG. 20A is a schematic cross-sectional view for describing a method of manufacturing the photodetector illustrated in FIG. 17.

FIG. 20B is a cross-sectional view of a process subsequent to FIG. 20A.

FIG. 20C is a cross-sectional view of a process subsequent to FIG. 20B.

FIG. 20D is a cross-sectional view of a process subsequent to FIG. 20C.

FIG. 20E is a cross-sectional view of a process subsequent to FIG. 20D.

FIG. 20F is a cross-sectional view of a process subsequent to FIG. 20E.

FIG. 20G is a cross-sectional view of a process subsequent to FIG. 20F.

FIG. 21 is a schematic view of an example of a planar configuration of a unit pixel of a photodetector according to a modification example 6 of the present disclosure.

FIG. 22 is a schematic cross-sectional view of an example of a configuration of the photodetector taken along a line VI-VI′ illustrated in FIG. 21.

FIG. 23 is a schematic view of an example of a planar configuration of a unit pixel of a photodetector according to a modification example 7 of the present disclosure.

FIG. 24 is a schematic cross-sectional view of an example of a configuration of the photodetector taken along a line VII-VII′ illustrated in FIG. 23.

FIG. 25 is a schematic view of an example of a planar configuration of a unit pixel of a photodetector according to a modification example 8 of the present disclosure.

FIG. 26 is a schematic cross-sectional view of an example of a configuration of the photodetector taken along a line VIII-VIII′ illustrated in FIG. 25.

FIG. 27 is a schematic cross-sectional view of another example of the configuration of the photodetector taken along a line VIII-VIII′ illustrated in FIG. 25.

FIG. 28 is a schematic view of an example of a planar configuration of a unit pixel of a photodetector according to a modification example 9 of the present disclosure.

FIG. 29 is a schematic cross-sectional view of an example of a configuration of the photodetector taken along a line IX-IX′ illustrated in FIG. 28.

FIG. 30 is an example of an equivalent circuit diagram of a photodetector according to a modification example 10 of the present disclosure.

FIG. 31 is another example of the equivalent circuit diagram of the photodetector according to the modification example 10 of the present disclosure.

FIG. 32 is a schematic view of an example of a planar configuration of the photodetector including an equivalent circuit illustrated in FIG. 31.

FIG. 33 is a schematic cross-sectional view of an example of a configuration of the photodetector taken along a line X-X′ illustrated in FIG. 31.

FIG. 34 is a schematic view of an example of a planar configuration of a photodetector according to a third embodiment of the present disclosure.

FIG. 35 is a schematic cross-sectional view of an example of a configuration of the photodetector taken along a line XI-XI′ illustrated in FIG. 34.

FIG. 36 is a schematic view of another example of the planar configuration of the photodetector according to the third embodiment of the present disclosure.

FIG. 37 is a schematic view of another example of the planar configuration of the photodetector according to the third embodiment of the present disclosure.

FIG. 38 is a schematic view of another example of the planar configuration of the photodetector according to the third embodiment of the present disclosure.

FIG. 39 is a schematic view of another example of the planar configuration of the photodetector according to the third embodiment of the present disclosure.

FIG. 40 is a schematic view of another example of the planar configuration of the photodetector according to the third embodiment of the present disclosure.

FIG. 41 is a schematic view of another example of the planar configuration of the photodetector according to the third embodiment of the present disclosure.

FIG. 42 is a schematic view of an example of a planar configuration of a photodetector according to a modification example 11 of the present disclosure.

FIG. 43 is a schematic cross-sectional view of an example of a configuration of the photodetector taken along a line XII-XII′ illustrated in FIG. 42.

FIG. 44 is a schematic view of another example of the planar configuration of the photodetector according to the modification example 11 of the present disclosure.

FIG. 45 is a schematic view of another example of the planar configuration of the photodetector according to the modification example 11 of the present disclosure.

FIG. 46 is a schematic view of another example of the planar configuration of the photodetector according to the modification example 11 of the present disclosure.

FIG. 47 is a schematic view of another example of the planar configuration of the photodetector according to the modification example 11 of the present disclosure.

FIG. 48 is a schematic view of another example of the planar configuration of the photodetector according to the modification example 11 of the present disclosure.

FIG. 49 is a schematic view of an example of a planar configuration of a photodetector according to a modification example 12 of the present disclosure.

FIG. 50 is an example of an equivalent circuit diagram of the photodetector illustrated in FIG. 49.

FIG. 51 is a schematic cross-sectional view of an example of a configuration of the photodetector taken along a line XIII-XIII′ illustrated in FIG. 49.

FIG. 52 is a schematic cross-sectional view of an example of the configuration of the photodetector taken along a line XIV-XIV′ illustrated in FIG. 49.

FIG. 53 is a schematic view of another example of a planar configuration of a unit pixel of the photodetector according to the modification example 12 of the present disclosure.

FIG. 54 is a schematic view of another example of the planar configuration of the unit pixel of the photodetector according to the modification example 12 of the present disclosure.

FIG. 55 is a schematic view of another example of the planar configuration of the unit pixel of the photodetector according to the modification example 12 of the present disclosure.

FIG. 56 is a schematic view of an example of a planar configuration of a unit pixel of a photodetector according to a modification example 13 of the present disclosure.

FIG. 57 is a schematic cross-sectional view of an example of a configuration of the photodetector taken along a line XV-XV′ illustrated in FIG. 56.

FIG. 58 is a schematic view of an example of a planar configuration of a unit pixel of a photodetector according to a modification example 14 of the present disclosure.

FIG. 59 is a schematic cross-sectional view of an example of a configuration of the photodetector taken along a line XVI-XVI′ illustrated in FIG. 58.

FIG. 60A is a schematic cross-sectional view of an example of a configuration of the photodetector according to the modification example 14.

FIG. 60B is a schematic cross-sectional view of another example of the configuration of the photodetector according to the modification example 14.

FIG. 60C is a schematic cross-sectional view of another example of the configuration of the photodetector according to the modification example 14.

FIG. 60D is a schematic cross-sectional view of another example of the configuration of the photodetector according to the modification example 14.

FIG. 60E is a schematic cross-sectional view of another example of the configuration of the photodetector according to the modification example 14.

FIG. 61 is a schematic view of another example of a planar configuration of a unit pixel of a photodetector according to a fourth embodiment of the present disclosure.

FIG. 62 is a schematic view of an example of the planar configuration of the unit pixel of the photodetector illustrated in FIG. 61.

FIG. 63A is a schematic cross-sectional view for describing a method of manufacturing the photodetector illustrated in FIG. 61.

FIG. 63B is a cross-sectional view of a process subsequent to FIG. 63A.

FIG. 63C is a cross-sectional view of a process subsequent to FIG. 63B.

FIG. 63D is a cross-sectional view of a process subsequent to FIG. 63C.

FIG. 63E is a cross-sectional view of a process subsequent to FIG. 63D.

FIG. 63F is a cross-sectional view of a process subsequent to FIG. 63E.

FIG. 63G is a cross-sectional view of a process subsequent to FIG. 63F.

FIG. 64 is a schematic view of an example of a cross-sectional configuration of a unit pixel of a photodetector according to a modification example 15 of the present disclosure.

FIG. 65 is a schematic view of an example of a cross-sectional configuration of a unit pixel of a photodetector according to a modification example 16 of the present disclosure.

FIG. 66 is a schematic view of an example of a cross-sectional configuration of a unit pixel of a photodetector according to a modification example 17 of the present disclosure.

FIG. 67 is a schematic view of an example of a planar configuration of a photodetector according to a modification example 18 of the present disclosure.

FIG. 68 is a schematic view of an example of a cross-sectional configuration of the photodetector taken along a line XVIII-ZVIII illustrated in FIG. 67.

FIG. 69 is a schematic view of an example of a cross-sectional configuration of a photodetector according to a modification example 19 of the present disclosure.

FIG. 70 is a schematic view of another example of the cross-sectional configuration of the photodetector according to the modification example 19 of the present disclosure.

FIG. 71A is a schematic cross-sectional view for describing a method of manufacturing the photodetector illustrated in FIG. 70.

FIG. 71B is a cross-sectional view of a process subsequent to FIG. 71A.

FIG. 71C is a cross-sectional view of a process subsequent to FIG. 71B.

FIG. 71D is a cross-sectional view of a process subsequent to FIG. 71C.

FIG. 71E is a cross-sectional view of a process subsequent to FIG. 71D.

FIG. 72 is a block diagram illustrating an example of a configuration of an electronic apparatus using the photodetector illustrated in FIG. 2.

FIG. 73A is a schematic view of an example of an entire configuration of a photodetection system using the photodetector illustrated in FIG. 2.

FIG. 73B is a diagram illustrating an example of a circuit configuration of the photodetection system illustrated in FIG. 73A.

FIG. 74 is a view depicting an example of a schematic configuration of an endoscopic surgery system.

FIG. 75 is a block diagram depicting an example of a functional configuration of a camera head and a camera control unit (CCU).

FIG. 76 is a block diagram depicting an example of schematic configuration of a vehicle control system.

FIG. 77 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. The following description is a specific example of the present disclosure, and the present disclosure is not limited to the following embodiments. In addition, the present disclosure is not limited to arrangements, dimensions, dimension ratios, etc. of respective components illustrated in each drawing. It is to be noted that description is given in the following order.
1. First Embodiment (An example of a photodetector in which an FDTI and an STI formed between pixels adjacent to each other are self-alignedly formed)
2. Modification Examples
2-1. Modification Example 1 (Another example of a configuration of the FDTI)
2-2. Modification Example 2 (Another example of the configuration of the FDTI)
2-3. Modification Example 3 (Another example of the configuration of the FDTI)
2-4. Modification Example 4 (Another example of the configuration of the FDTI)
2-5. Modification Example 5 (Another Example of a manufacturing method)
3. Second Embodiment (An example of a photodetector in which the FDTI and the STI are provided to be spaced apart from each other)
4. Modification Examples
4-1. Modification Example 6 (Another example of layout)
4-2. Modification Example 7 (Another example of layout)
4-3. Modification Example 8 (Another example of layout)
4-4. Modification Example 9 (Another example of layout)
4-5. Modification Example 10 (Another example of layout)
5. Third Embodiment (An example of a photodetector in which a well contact is provided in a semiconductor substrate)
6. Modification Examples
6-1. Modification Example 11 (Another example of layout)
6-2. Modification Example 12 (Another example of layout)
6-3. Modification Example 13 (Another example of layout)
6-4. Modification Example 14 (Another example of layout)
7. Fourth Embodiment (An example of a photodetector including an STI having different depths between pixels and within a pixel)
8. Modification Examples
8-1. Modification Example 15 (Another example of layout)
8-2. Modification Example 16 (Another example of layout)
8-3. Modification Example 17 (Another example of layout)
8-4. Modification Example 18 (Another example of layout)
8-5. Modification Example 19 (Another example of layout)
9. Application Examples
10. Practical Application Examples

### 1. FIRST EMBODIMENT

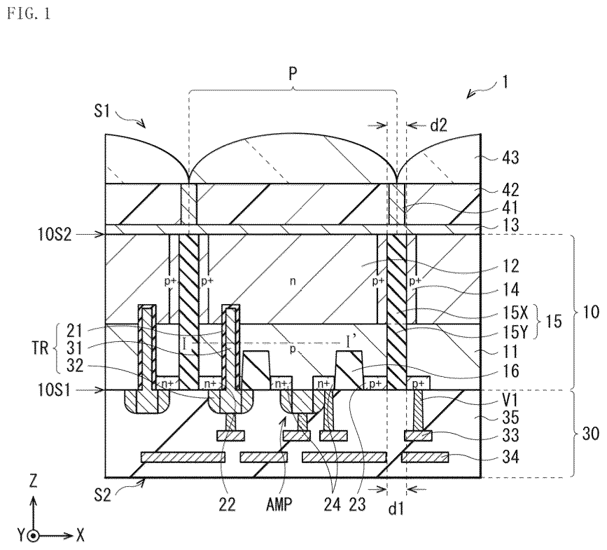

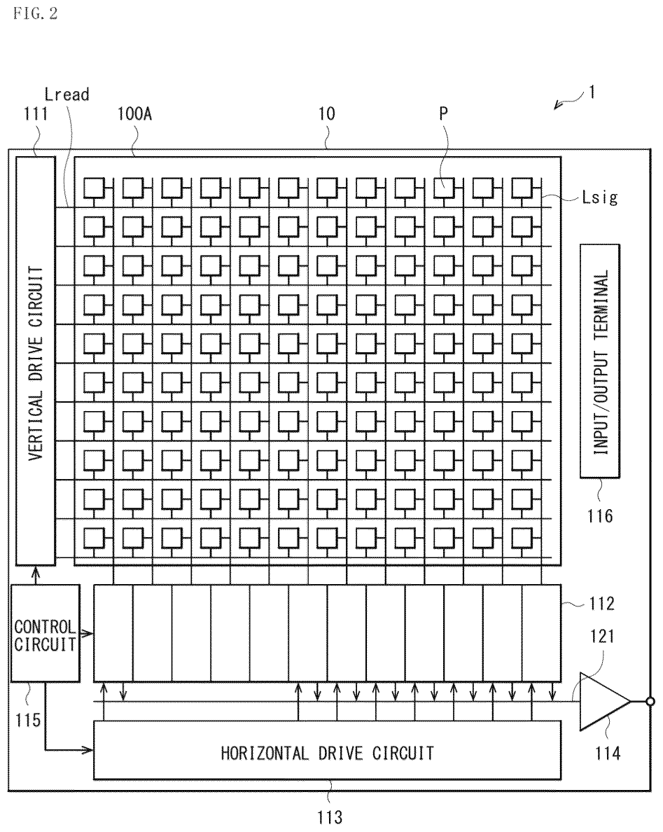

FIG. 1 schematically illustrates an example of a cross-sectional configuration of a photodetector (a photodetector 1) according to a first embodiment of the present disclosure. FIG. 2 illustrates an example of an entire configuration of the photodetector 1 illustrated in FIG. 1. The photodetector 1 is, for example, a CMOS (Complementary Metal Oxide Semiconductor) image sensor or the like used in an electronic apparatus such as a digital still camera or a video camera, and includes, as an imaging region, a pixel section (a pixel section 100A) including a plurality of pixels (unit pixels P) two-dimensionally arranged in a matrix. The photodetector 1 is, for example, what is called a back-illuminated photodetector in the CMOS image sensor or the like.

The photodetector 1 includes the pixel section 100A including the plurality of unit pixels P arranged in an array, and the unit pixels P adjacent to each other in the pixel section 100A are isolated from each other by an isolator 15 that extends between a pair of surfaces (a front surface (a surface 10S1) and a back surface (a surface 10S2)) opposed to each other of a semiconductor substrate 10. In each of the unit pixels P isolated from each other by the isolator 15, for example, one or a plurality of transistors (e.g., a transfer transistor TR and an amplification transistor AMP) and a p-type impurity region 23 are provided on the surface 10S1 of the semiconductor substrate 10. The p-type impurity region 23 forms a well contact region. In the present embodiment, a source region and a drain region (e.g., a source region 24S and a drain region 24D) of the one or plurality of transistors (e.g., the transfer transistor TR and the amplification transistor AMP) are provided in contact with the isolator 15 in a plan view.

### [Schematic Configuration of Photodetector]

FIG. 2 illustrates an example of an entire configuration of the photodetector 1.

The photodetector 1 is, for example, a CMOS image sensor, and takes in incident light (image light) from a subject through an optical lens system (not illustrated), converts the light amount of the incident light of which an image is formed on an imaging plane into an electric signal on a pixel-by-pixel basis, and outputs the electric signal as a pixel signal. The photodetector 1 includes the pixel section 100A as the imaging region on the semiconductor substrate 10, and includes, for example, a vertical drive circuit 111, a column signal processing circuit 112, a horizontal drive circuit 113, an output circuit 114, a control circuit 115, and an input/output terminal 116 in a peripheral region of the pixel section 100A.

The pixel section 100A includes, for example, the plurality of unit pixels P two-dimensionally arranged in a matrix. For example, the unit pixels P are wired to a pixel drive line Lread (specifically, a row selection line and a reset control line) for each pixel row, and are wired to a vertical signal line Lsig for each pixel column. The pixel drive line Lread transmits a drive signal for signal reading from a pixel. The pixel drive line Lread has one end coupled to an output end corresponding to each row of the vertical drive circuit 111.

The vertical drive circuit 111 includes a shift register, an address decoder, and the like, and is a pixel driving section that drives the respective unit pixels P in the pixel section 100A in row units, for example. A signal outputted from each of the unit pixels P in a pixel row selected and scanned by the vertical drive circuit 111 is supplied to the column signal processing circuit 112 through a corresponding one of the vertical signal lines Lsig. The column signal processing circuit 112 includes an amplifier, a horizontal selection switch, and the like provided for each of the vertical signal lines Lsig.

The horizontal drive circuit 113 includes a shift register, an address decoder, and the like, and drives respective horizontal selection switches of the column signal processing circuits 112 in sequence while scanning the horizontal selection switches. Such selective scanning by the horizontal drive circuit 113 causes the signals of respective pixels transmitted through respective vertical signal lines Lsig to be outputted in sequence to a horizontal signal line 121 and be transmitted to outside of the semiconductor substrate 10 through the horizontal signal line 121.

The output circuit 114 performs signal processing on the signals supplied in sequence from the respective column signal processing circuits 112 through the horizontal signal line 121, and outputs the processed signals. The output circuit 114 may perform, for example, only buffering, or may perform black level adjustment, column variation correction, various types of digital signal processing, and the like.

Circuit components including the vertical drive circuit 111, the column signal processing circuit 112, the horizontal drive circuit 113, the horizontal signal line 121, and the output circuit 114 may be formed directly on the semiconductor substrate 10, or may be provided in an external control IC. Alternatively, these circuit components may be formed on another substrate coupled by a cable or the like.

The control circuit 115 receives a clock given from the outside of the semiconductor substrate 10, or data or the like that gives an instruction as to an operation mode, and also outputs data such as internal information about the photodetector 1. The control circuit 115 further includes a timing generator that generates various timing signals, and controls driving of peripheral circuits such as the vertical drive circuit 111, the column signal processing circuit 112, and the horizontal drive circuit 113, on the basis of the various timing signals generated by the timing generator.

The input/output terminal 116 exchanges signals with the outside.

### [Circuit Configuration of Unit Pixel]

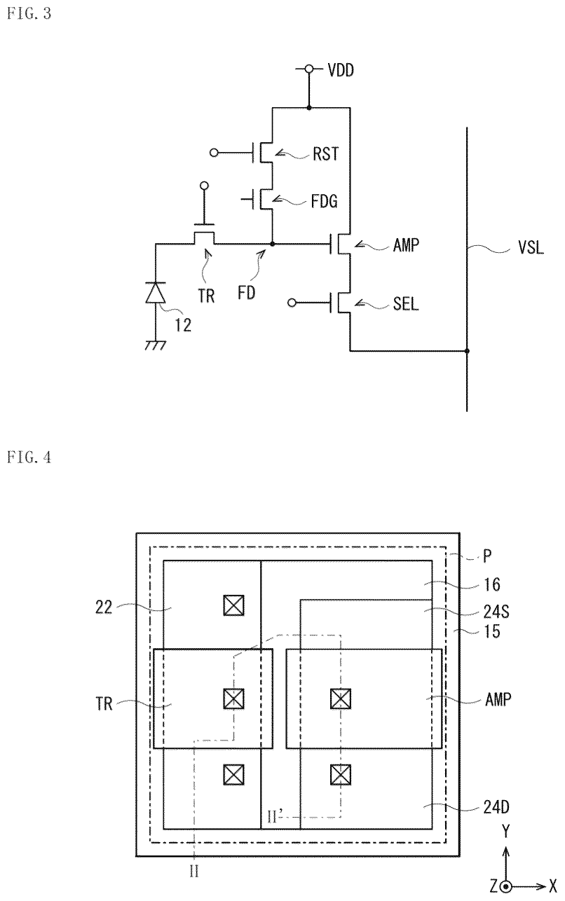

FIG. 3 illustrates an example of a readout circuit of the unit pixel P of the photodetector 1 illustrated in FIG. 1.

In the pixel section 100A, as described above, the plurality of unit pixels P is two-dimensionally arranged in a matrix. The respective unit pixels P include mutually common components.

The unit pixel P includes, for example, a light-receiving section 12, the transfer transistor TR, and a floating diffusion FD. The light-receiving section 12 includes a photodiode PD. The transfer transistor TR is electrically coupled to the light-receiving section 12. The floating diffusion FD temporarily holds electric charge outputted from the light-receiving section 12 through the transfer transistor TR. The light-receiving section 12 performs photoelectric conversion to generate electric charge corresponding to the amount of received light. A cathode of the light-receiving section 12 is electrically coupled to a source of the transfer transistor TR, and an anode of the light-receiving section 12 is electrically coupled to a reference potential line (e.g., a ground). A drain of the transfer transistor TR is electrically coupled to the floating diffusion FD, and a gate of the transfer transistor TR is electrically coupled to the pixel drive line Lread. The transfer transistor TR is, for example, a CMOS (Complementary Metal Oxide Semiconductor) transistor.

The floating diffusion FD is electrically coupled to an input end of the readout circuit. The readout circuit includes, for example, a reset transistor RST, a selection transistor SEL, and the amplification transistor AMP. It is to be noted that the selection transistor SEL may be omitted as necessary. A source of the reset transistor RST (the input end of the readout circuit) is electrically coupled to the floating diffusion FD, and a drain of the reset transistor RST is electrically coupled to a power supply line VDD and a drain of the amplification transistor AMP. A gate of the reset transistor RST is electrically coupled to the pixel drive line Lread. A source of the amplification transistor AMP is electrically coupled to a drain of the selection transistor SEL, and a gate of the amplification transistor AMP is electrically coupled to a source of the reset transistor RST. A source of the selection transistor SEL (an output end of the readout circuit) is electrically coupled to the vertical signal line Lsig, and a gate of the selection transistor SEL is electrically coupled to the pixel drive line Lread.

When the transfer transistor TR is turned on, the transfer transistor TR transfers electric charge of the light-receiving section 12 to the floating diffusion FD. The gate of the transfer transistor TR includes, for example, a vertical transfer gate 31 as illustrated in FIG. 1, and is formed on the front surface (the surface 10S1) of the semiconductor substrate 10. The reset transistor RST resets a potential of the floating diffusion FD to a predetermined potential. When the reset transistor RST is turned on, the potential of the floating diffusion FD is reset to a potential of the power supply line VDD. The selection transistor SEL controls an output timing of a pixel signal from the readout circuit. The amplification transistor AMP generates, as a pixel signal, a signal of a voltage corresponding to the level of electric charge held by the floating diffusion FD. The amplification transistor AMP configures a source-follower amplifier, and outputs a pixel signal of a voltage corresponding to the level of electric charge generated by the light-receiving section 12. When the selection transistor SEL is turned on, the amplification transistor AMP amplifies the potential of the floating diffusion FD, and outputs a voltage corresponding to the amplified potential to the column signal processing circuit 112 through the vertical signal line Lsig. The reset transistor RST, the amplification transistor AMP, and the selection transistor SEL are, for example, CMOS transistors.

It is to be noted that the readout circuit may include, for example, an FD transfer transistor FDG. The FD transfer transistor FDG is provided between the source of the reset transistor RST and the gate of the amplification transistor AMP, for example, as illustrated in FIG. 3.

### [Configuration of Unit Pixel]

FIG. 4 schematically illustrates an example of a planar configuration of the unit pixel P of the photodetector 1 illustrated in FIG. 1. It is to be noted that FIG. 1 illustrates a cross-sectional configuration taken along a line II-II′ illustrated in FIG. 4, and FIG. 4 illustrates a planar configuration taken along a line I-I′ illustrated in FIG. 1.

A case where the unit pixel P described below is of a back-illuminated type is described as an example; however, the present technology is also applicable to the unit pixel P of a front-illuminated type.

It is to be noted that, in the drawings, “+ (plus)” attached to “p” and “n” indicates a high p-type or n-type impurity concentration, and “++” indicates a higher p-type or n-type impurity concentration than “+”. Further, “− (minus)” attached to “p” and “n” indicates a low p-type or n-type impurity concentration. This applies to second to fourth embodiments and modification examples 1 to 19 to be described below.

The unit pixel P includes, as the light-receiving section 12, the photodiode PD that is formed to be embedded in the semiconductor substrate 10 having the pair of surfaces (the surface 10S1 and the surface 10S2) opposed to each other. For example, a fixed electric charge layer 13 is formed on light incident side S1 of the light-receiving section 12 (on side of the back surface (the surface 10S2) of the semiconductor substrate 10), and a p-well 11 is formed as an active region on side opposite to the light incident side S1 (on side of the front surface (the surface 10S1) of the semiconductor substrate 10). The p-well 11 is provided with, for example, an n-type impurity region 22, the p-type impurity region 23, and an n-type impurity region 24. The n-type impurity region 22 forms the floating diffusion FD. The p-type impurity region 23 forms the well contact region. The n-type impurity region 24 forms source regions and drain regions of the transfer transistor TR, and pixel transistors (e.g., the reset transistor RST, the selection transistor SEL, and the amplification transistor AMP) included in the readout circuit. The p-type impurity region 23 corresponds to a specific example of a “first p-type impurity region” in an embodiment of the present disclosure, and the transfer transistor TR, the reset transistor RST, the selection transistor SEL, and the amplification transistor AMP correspond to a specific example of “one or a plurality of transistors” in the present disclosure. The unit pixel P further includes an isolator 16 having an STI (Shallow Trench Isolation) structure, and the isolator 16 is provided between the n-type impurity regions 22 and 24 and the p-type impurity region 23 adjacent to each other in the unit pixel P.

The isolator 15 is provided between the unit pixels P adjacent to each other. The isolator 15 corresponds to a specific example of a “first isolation trench” in an embodiment of the present disclosure. As described above, the isolator 15 isolates the unit pixels P adjacent to each other in the pixel section 100A including the plurality of unit pixels P arranged in an array, and is provided in a lattice form, for example, so as to surround an outer periphery of each of the unit pixels P.

The isolator 15 has an FTI structure that penetrates between the surface 10S1 and the surface 10S2 of the semiconductor substrate 10. Specifically, the isolator 15 includes, for example, a first isolator 15X having an FDTI (Front Deep Trench Isolation) structure and a second isolator 15Y having an STI structure. The FDTI structure extends between the surface 10S1 and the surface10S2 of the semiconductor substrate 10, for example, from side of the surface 10S1 to the surface 10S2. The STI structure extends from side of the surface 10S1 to the surface 10S2, and has a bottom inside the semiconductor substrate 10.

The first isolator 15X corresponds to a specific example of a “first isolator” in an embodiment of the present disclosure. The first isolator 15X is formed on side of the surface 10S2 of the semiconductor substrate 10 so as to isolate the light-receiving sections 12 from each other. The light-receiving sections are formed for respective unit pixels P to be embedded on side of the surface 10S2 of the semiconductor substrate 10. For example, a p-type impurity region 14 having an impurity concentration higher than that of the p-well 11 is formed on a side surface of the first isolator 15X. The p-type impurity region 14 corresponds to a specific example of a “second p-type impurity region” in an embodiment of the present disclosure. The p-type impurity region 14 prevents generation of a dark current on a side surface of the isolator 15 opposed to the light-receiving section 12.

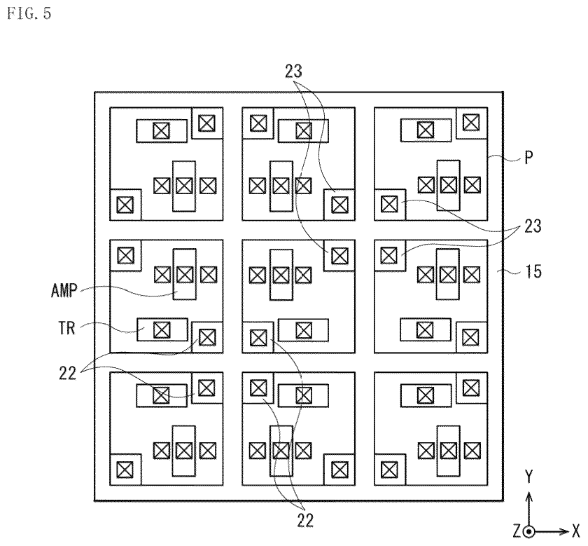

The second isolator 15Y corresponds to a specific example of a “second isolator” in an embodiment of the present disclosure. FIG. 6 schematically illustrates a cross-sectional configuration of the photodetector 1 taken along a line II-II illustrated in FIG. 4. As illustrated in FIG. 1 and FIG. 6, the second isolator 15Y is in contact with, for example, the n-type impurity region 22 that forms the floating diffusion FD, the p-type impurity region 23 that forms the well contact region, and the n-type impurity region 24 that forms, for example, the source region and the drain region of the amplification transistor AMP.

FIG. 5 schematically illustrates an example of layout in the pixel section 100A including the unit pixels P illustrated in FIG. 4. The isolator 15 isolates the unit pixels P adjacent to each other, and isolates adjacent transistors in the unit pixels P adjacent to each other.

The first isolator 15X and the second isolator 15Y are self-alignedly and integrally formed, and have isolation widths that are substantially the same as each other (d1=d2). That is, the isolator 15 extends with a substantially uniform isolation width between the surface 10S1 and the surface 10S2 of the semiconductor substrate 10, and penetrates the semiconductor substrate 10, for example. In other words, the isolator 15 has a substantially rectangular cross-section having a substantially vertical angle between a side surface of the isolator 15 and the surface 10S1. A groove that forms the isolator 15 is filled with, for example, an insulating film such as a silicon oxide (SiOₓ) film.

The isolator 16 corresponds to a specific example of a “second isolation trench” in an embodiment of the present disclosure. The isolator 16 isolates active elements such as transistors adjacent to each other in the unit pixel P. Specifically, as described above, the isolator 16 isolates the n-type impurity region 22, the p-type impurity region 23, and the n-type impurity region 24 that are provided on the surface 10S1 of the semiconductor substrate 10 in the unit pixel P. The n-type impurity region 22 forms the floating diffusion FD. The p-type impurity region 23 forms the well contact region. The n-type impurity region 24 forms the source regions and the drain regions of the transfer transistor TR, and pixel transistors (e.g., the reset transistor RST, the selection transistor SEL, and the amplification transistor AMP) included in the readout circuit.

The isolator 16 has an STI structure that extends from the surface 10S1 to the surface 10S2 of the semiconductor substrate 10 and has a bottom inside the semiconductor substrate 10. The isolator 16 has an isolation width on the light incident side S1 smaller than an isolation width on side of a wiring layer S2. In other words, the isolator 15 has a forward-tapered cross-section having an angle of less than 90° between the side surface of the isolator 15 and the surface 10S1. In addition, an isolation width of the isolator 16 exposed to the surface 10S1 is larger than the isolation width of the isolator 15. A groove that forms the isolator 16 is filled with, for example, an insulating film such as silicon oxide (SiOₓ) film.

The unit pixel P includes a light-shielding film 41, a color filter 42, and an on-chip lens 43. The light-shielding film 41 is provided between the unit pixels P adjacent to each other on the light incident side S1 (on side of the surface 10S2 of the semiconductor substrate 10). A multilayer wiring layer 30 is provided on the surface 10S1 of the semiconductor substrate 10 opposite to the light incident side S1 of the unit pixel P.

The light-shielding film 41 prevents leakage of light to the adjacent unit pixels P, and is provided between the unit pixels P adjacent to each other, specifically, at a boundary position between the color filters 42 that allow light of colors different from each other to pass therethrough. Examples of a material included in the light-shielding film 41 include an electrically conductive material having a light-shielding property. Specific examples of the material include tungsten (W), silver (Ag), copper (Cu), aluminum (Al), an alloy of Al and Cu, and the like.

The color filter 42 includes, for example, a red filter 42R, a green filter 42G, and a blue filter 42B. The red filter 42R allows red light (R) to selectively pass therethrough. The green filter 42G allows green light (G) to selectively pass therethrough. The blue filter 42B allows blue light (B) to selectively pass therethrough. Regarding the respective color filters 42R, 42G, and 42B, for example, in each unit cell U, for example, four green filters 42G are provided on a diagonal line, and one red filter 42R and one blue filter 42B are provided on an orthogonal diagonal line. Each of the unit cells U provided with the respective color filters 42R, 42G, and 42B detects, for example, corresponding color light in a plurality of light-receiving sections 12 in the unit cell U. That is, in the pixel section 100A, the unit cells U that each detect a corresponding one of the red light (R), the green light (G), and the blue light (B) are arranged in a Bayer pattern.

The on-chip lens 43 condenses incident light onto the light-receiving section 12, and is provided for each unit pixel P, for example, as illustrated in FIG. 1. It is possible to form the on-chip lens 43 using, for example, an inorganic material such as silicon oxide (SiOₓ) or silicon nitride (SiNₓ). In addition, the on-chip lens 43 may be formed using an organic material having a high refractive index such as an episulfide-based resin, a thietane compound, or a resin thereof.

The multilayer wiring layer 30 includes, for example, the transfer transistor TR, and pixel transistors included in the readout circuit. Specifically, for example, the vertical transfer gate 31 of the transfer transistor TR is provided to extend from the surface 10S1 of the semiconductor substrate 10 to a depth reaching the light-receiving section 12. For example, a sidewall 32 is provided around the transfer gate 31 provided on the surface 10S1 of the semiconductor substrate 10, and a sidewall and a bottom surface of the transfer gate 31 extending inside the semiconductor substrate 10 are covered with an insulating film 21. The surface 10S1 of the semiconductor substrate 10 is further provided with, for example, gates of the reset transistor RST having a planar structure, the selection transistor SEL, the amplification transistor AMP, and the like. In the multilayer wiring layer 30, a plurality of wiring layers 33 and 34 is further stacked with an interlayer insulating layer 35 interposed therebetween, and, for example, the wiring layer 33 and an FD 19 are electrically coupled to each other through a via V1. In addition to the readout circuit described above, for example, the vertical drive circuit 111, the column signal processing circuit 112, the horizontal drive circuit 113, the output circuit 114, the control circuit 115, the input/output terminal 116, and the like are formed in the multilayer wiring layer 30.

### [Method of Manufacturing Photodetector]

It is possible to form the photodetector 1 as follows, for example.

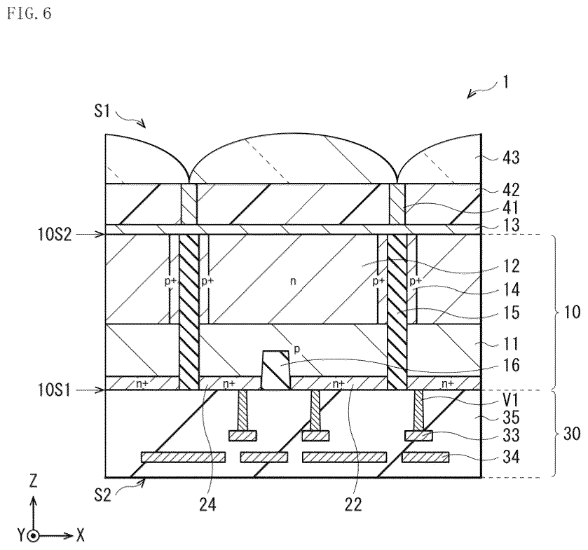

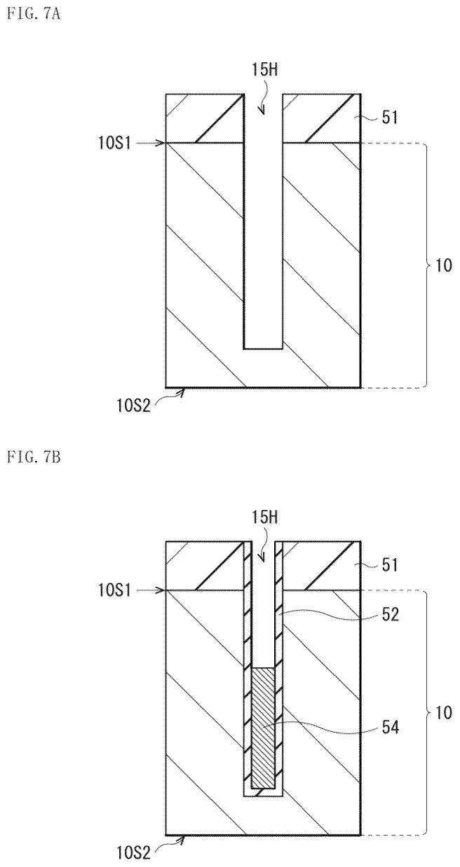

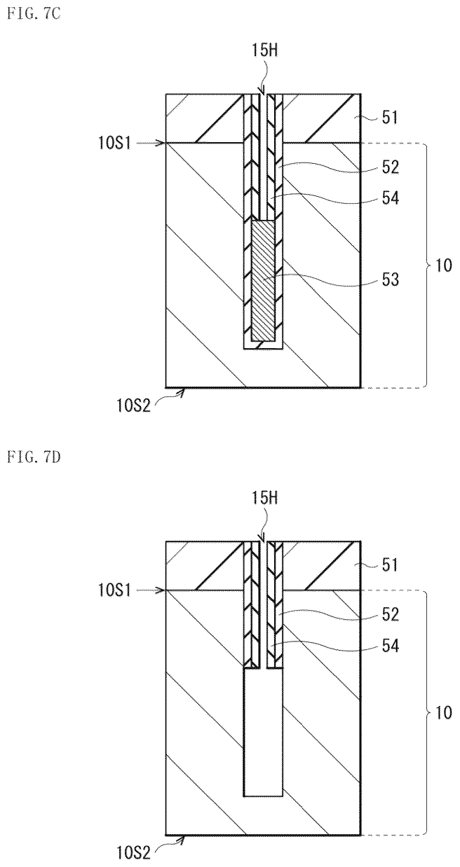

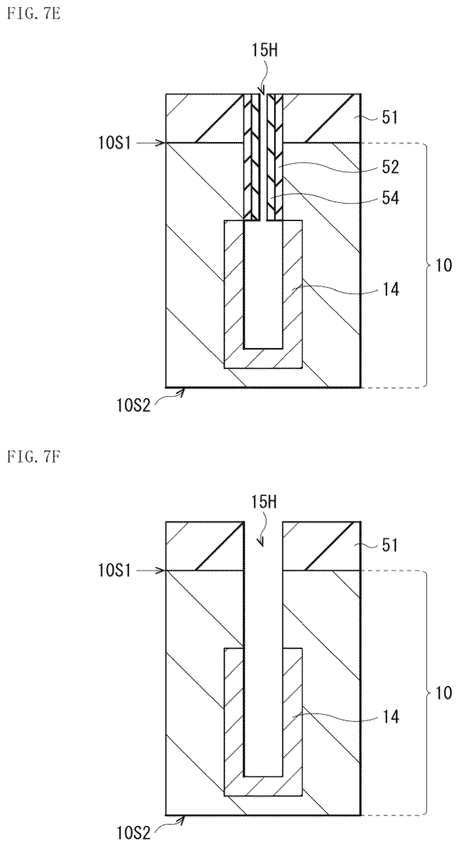

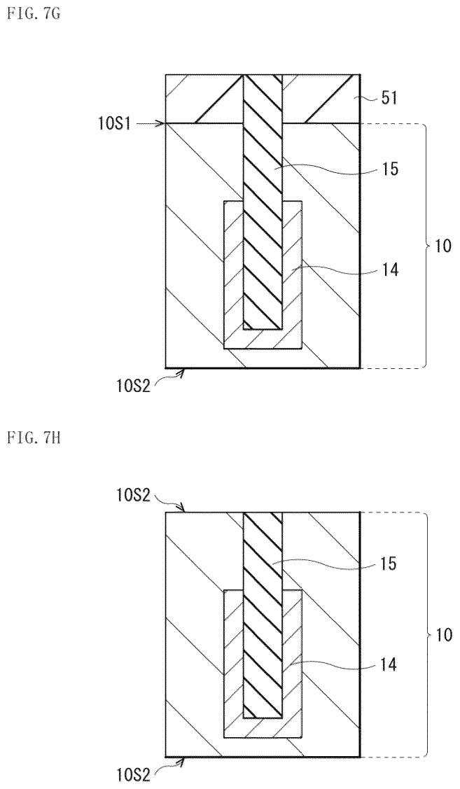

First, as illustrated in FIG. 7A, a mask 51 is formed on the surface 10S1 of the semiconductor substrate 10, and a groove 15H is formed with use of a photolithography method and a RIE (Reactive Ion Etching) method. Next, as illustrated in FIG. 7B, for example, an oxide film 52 is formed on a side surface and a bottom surface inside the groove 15H. Subsequently, as illustrated in FIG. 7B, a polysilicon film 53 is deposited in the groove 15H, and thereafter, etching back is performed to thereby form the polysilicon film 53 in a lower portion of the groove 15H.

Subsequently, as illustrated in FIG. 7C, an oxide film having such a thickness that the groove 15H is not filled with the oxide film is formed on the polysilicon film 53 with use of, for example, a CVD (Chemical Vapor Deposition) method, and thereafter, etching back is performed to thereby form an oxide film 54 in an upper portion of the groove 15H. At this time, a thickness of the oxide film 54 is thicker than the thickness of the oxide film 52.

Next, as illustrated in FIG. 7D, the polysilicon film 53, and the oxide film 52 in the lower portion of the groove 15H are removed by etching to expose the semiconductor substrate 10. At this time, the thickness of the oxide film 54 is thicker than the thickness of the oxide film 52; therefore, the upper portion of the groove 15H remains covered with the oxide film 54. Subsequently, as illustrated in FIG. 7E, the semiconductor substrate 10 exposed in the groove 15H is doped with, for example, boron (B) with use of, for example, a plasma doping method, a solid phase diffusion method, or the like to form the p-type impurity region 14. Thereafter, as illustrated in FIG. 7F, the oxide films 52 and 54 in the upper portion of the groove 15H are removed.

Subsequently, as illustrated in FIG. 7G, an insulating film such as silicon oxide (SiOₓ) film is embedded in the groove 15H to form the isolator 15, and thereafter, as illustrated in FIG. 7H, the mask 51 formed on the surface 10S1 of the semiconductor substrate 10, and the surface10S1 of the semiconductor substrate 10 are ground by, for example, CMP (Chemical Mechanical Polishing) to planarize the surface. Thus, the isolator 15 including the first isolator 15X and the second isolator 15Y that are self-alignedly formed is completed. The first isolator 15X has a side surface on which the p-type impurity region 14 is formed, and the second isolator 15Y has an isolation width that is substantially the same as that of the first isolator 15X (d1=d2).

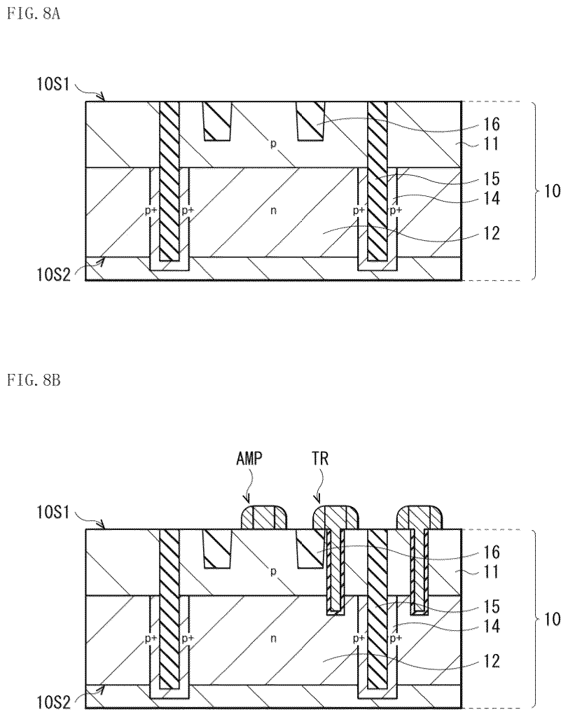

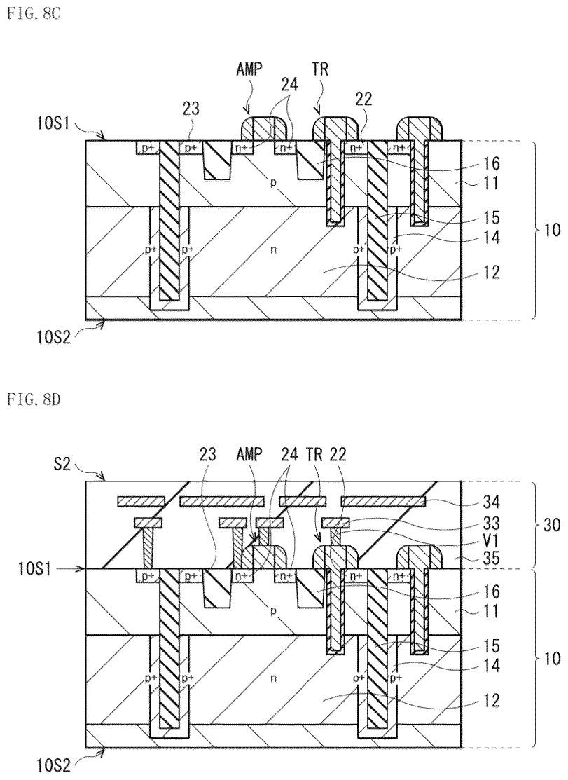

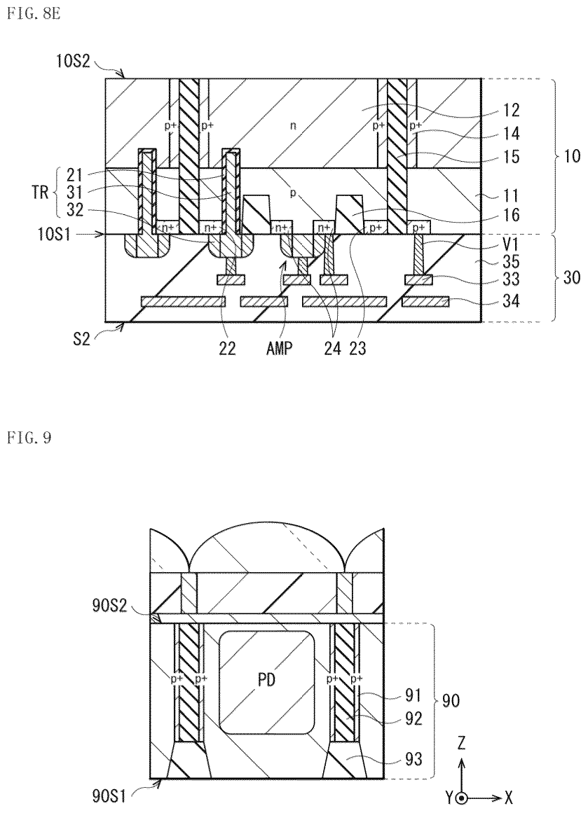

Next, as illustrated in 8A, the light-receiving section 12 and the p-well 11 are formed in the semiconductor substrate 10, and thereafter, the isolator 16 is formed on the surface 10S1 of the semiconductor substrate 10. Subsequently, as illustrated in FIG. 8B, the gates of the transfer transistor TR and the amplification transistor AMP are formed. Next, as illustrated in FIG. 8C, the n-type impurity regions 22 and 24, and the p-type impurity region 23 are formed on the surface 10S1 of the semiconductor substrate 10.

Subsequently, as illustrated in FIG. 8D, the multilayer wiring layer 30 including the via V1, the wiring layers 33 and 34, and the interlayer insulating layer 35 is formed on the surface 10S1 of the semiconductor substrate 10. Next, although not illustrated, another substrate is bonded to side of the wiring layer S2, and thereafter, as illustrated in FIG. 8E, the surface 10S2 of the semiconductor substrate 10 is ground by, for example, CMP until the isolator 15 is exposed to planarize the surface. Thereafter, the fixed electric charge layer 13, the light-shielding film 41, the color filter 42, and the on-chip lens 43 are formed. Thus, the photodetector 1 illustrated in FIG. 1 is completed.

### Workings and Effects

In the photodetector 1 according to the present embodiment, a plurality of transistors (e.g., the transfer transistor TR and the amplification transistor AMP) formed on the front surface (the surface 10S1) of the semiconductor substrate 10 is isolated with use of the isolator 15 that isolates the unit pixels P adjacent from each other. This reduces an isolation distance between a plurality of active elements formed on the surface 10S1 of the semiconductor substrate. This is described below.

A solid-state imaging element (a CMOS image sensor) is a semiconductor device that photoelectrically converts incident light with a photodiode and amplifies a minute signal with an amplification transistor. It is known that sizes of the photodiode and the amplification transistor greatly affect image quality performance.

In recent years, a pixel size has been reduced with an increase in resolution of the CMOS image sensor. As a result, it has become difficult to maintain image quality performance. Various ideas have been proposed as measures against such difficulty, and of the ideas, a method of performing electrical and optical isolation between photodiodes with use of an FDTI has been reported.

FIG. 9 schematically illustrates a configuration of the solid-state imaging element described above. An FDTI 91 for isolating pixels is formed in a Si substrate 90, and a P+ layer 92 for pinning is formed on a side surface of the FDTI 91. An STI 93 for isolating devices such as an amplification transistor and a floating diffusion that are formed on a surface of the Si substrate 90, and a P+ diffusion layer for well bias is formed above the FDTI 91. In such a solid-state imaging element, an isolation distance between devices depends on a width of the STI.

In general, the STI is larger than an isolation width of the FDTI as illustrated in FIG. 9; therefore, in a case where sizes of devices provided in each pixel are maintained, it is not possible to reduce the pixel size. Alternatively, an issue arises that it is not possible to maintain the sizes of the devices and necessary performance is not obtained.

In contrast, in the present embodiment, a plurality of transistors formed on the front surface (the surface 10S1) of the semiconductor substrate 10 is isolated with use of the isolator 15 that isolates the unit pixels P adjacent from each other. This reduces an isolation distance between the transistors accordingly, as compared with a typical solid-state imaging element in which a plurality of transistors formed on the front surface of the semiconductor substrate 10 is isolated with use of the STI.

As described above, in the photodetector 1 according to the present embodiment, it is possible to reduce the pixel size. In addition, it is possible to maintain performance of active elements such as transistors or improve the performance, which makes it possible to improve performance of the photodetector 1.

Next, description is given of the second to fourth embodiments and the modification examples 1 to 19 of the present disclosure. Hereinafter, components similar to those in the first embodiment described above are denoted by the same reference numerals, and description thereof is omitted as appropriate.

### 2. MODIFICATION EXAMPLES

### 2-1. Modification Example 1

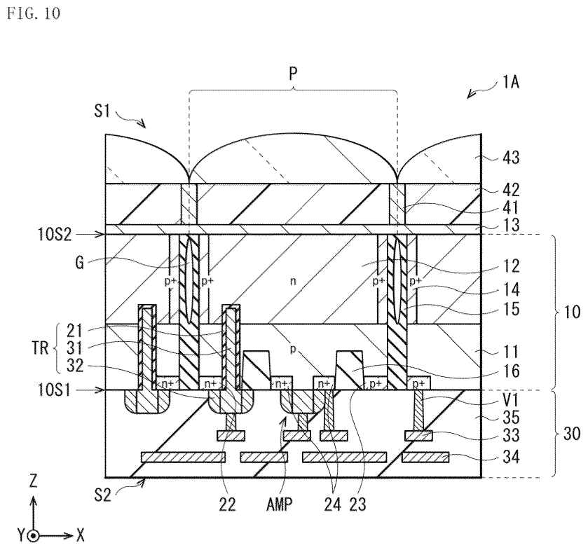

FIG. 10 schematically illustrates an example of a cross-sectional configuration of a photodetector (a photodetector 1A) according to the modification example 1 of the present disclosure. The photodetector 1A is, for example, a CMOS image sensor or the like used in an electronic apparatus such as a digital still camera or a video camera, and is, for example, a back-illuminated photodetector, as with the first embodiment described above.

In the first embodiment described above, the isolator 15 is filled with an insulating film. In contrast, in the photodetector 1A according to the present modification example, an air gap G is formed in the first isolator 15X of the isolator 15. Except for this point, the photodetector 1A has a configuration substantially similar to that of the photodetector 1.

It is possible to form the air gap G in the first isolator 15X as follows, for example. For example, as illustrated in FIG. 7E, the semiconductor substrate 10 exposed in the groove 15H is doped with, for example, boron (B) to form the p-type impurity region 14, and thereafter, an insulating film is embedded in the groove 15H without removing the oxide films 52 and 54. Thus, an opening width of the upper portion of the groove 15H is narrower than the lower portion of the groove 15H; therefore, an opening of the upper portion of the groove 15H is closed before the lower section of the groove 15H is filled with the insulating film, thereby forming the air gap G in the lower section of the groove 15H.

Thus, in the present modification example, the air gap G is formed in the first isolator 15X, which makes it possible to strengthen optical isolation between the unit pixels P adjacent to each other, in addition to the effects of the first embodiment described above. Accordingly, it is possible to further suppress color mixture.

### 2-2. Modification Example 2

FIG. 11 schematically illustrates an example of a cross-sectional configuration of a photodetector (a photodetector 1B) according to the modification example 2 of the present disclosure. The photodetector 1B is, for example, a CMOS image sensor or the like used in an electronic apparatus such as a digital still camera or a video camera, and is, for example, a back-illuminated photodetector, as with the first embodiment described above.

In the first embodiment described above, the isolator 15 is filled with an insulating film. In contrast, in the photodetector 1B according to the present modification example, an insulating film 15A is embedded in the isolator 15, and, for example, an electrically conductive film 15B such as a polysilicon film is further embedded at a position corresponding to the first isolator 15X. Except for this point, the photodetector 1B has a configuration substantially similar to that of the photodetector 1.

It is possible to form the isolator 15 according to the present modification example as follows, for example. For example, as illustrated in FIG. 7E, the semiconductor substrate 10 exposed in the groove 15H is doped with, for example, boron (B) to form the p-type impurity region 14, and thereafter, as illustrated in FIG. 7F, the oxide films 52 and 54 in the upper portion of the groove 15H are removed. Next, the insulating film 15A is formed on the side surface and the bottom surface of the groove 15H, and thereafter, a polysilicon film is deposited in the groove 15H, and etching back is performed to thereby form the electrically conductive film 15B including the polysilicon film in the lower portion of the groove 15H. Thereafter, the insulating film 15A is further deposited on the electrically conductive film 15B in the groove 15H to embed the groove 15H with the insulating film 15A. Thus, the isolator 15 in which the electrically conductive film 15B is embedded in the first isolator 15X is formed.

Thus, in the present modification example, the electrically conductive film 15B is embedded in the first isolator 15X of the isolator 15, which makes it possible to apply, for example, a negative bias to the electrically conductive film 15B and enhance pinning. Accordingly, it is possible to suppress a dark current, in addition to the effects of the first embodiment described above.

### 2-3. Modification Example 3

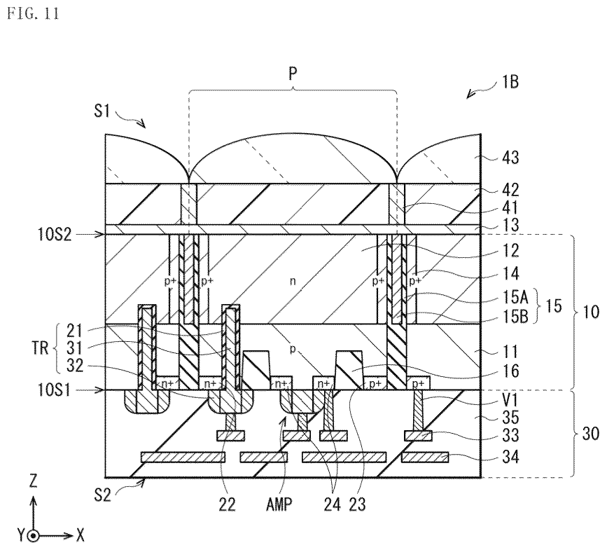

FIG. 12 schematically illustrates an example of a cross-sectional configuration of a photodetector (a photodetector 1C) according to the modification example 3 of the present disclosure. The photodetector 1C is, for example, a CMOS image sensor or the like used in an electronic apparatus such as a digital still camera or a video camera, and is, for example, a back-illuminated photodetector, as with the first embodiment described above.

In the first embodiment described above, the isolator 15 is filled with an insulating film. In contrast, in the photodetector 1C according to the present modification example, the insulating film 15A is embedded in the isolator 15, and, for example, the electrically conductive film 15B such as a polysilicon film is further embedded and the air gap G is formed at a position corresponding to the first isolator 15X. Except for this point, the photodetector 1C has a configuration substantially similar to that of the photodetector 1.

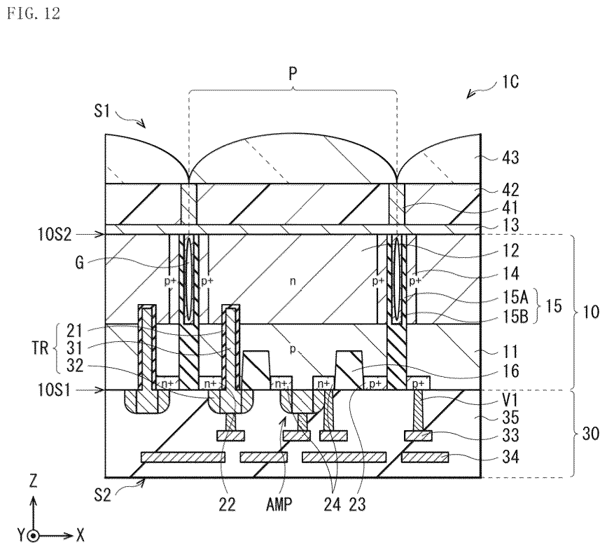

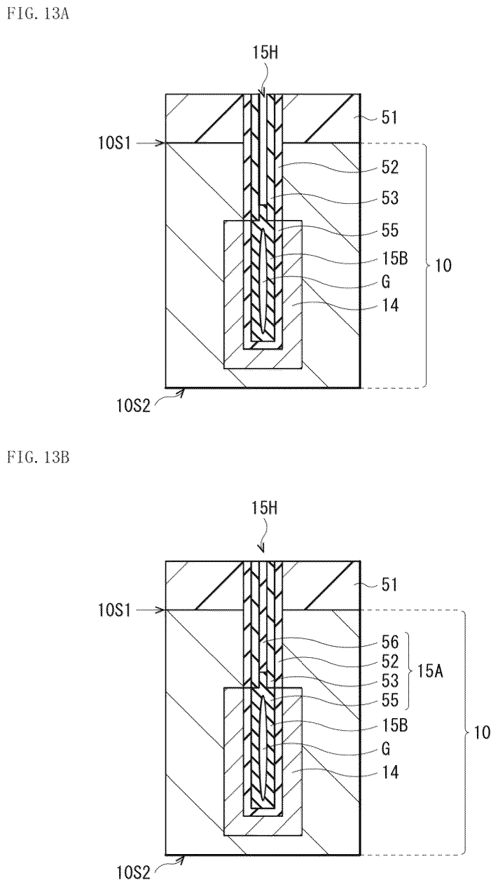

It is possible to form the isolator 15 according to the present modification example as follows, for example. For example, as illustrated in FIG. 7E, the semiconductor substrate 10 exposed in the groove 15H is doped with, for example, boron (B) to form the p-type impurity region 14, and thereafter, as illustrated in FIG. 13A, an insulating film 55 is formed in the groove 15H without removing the oxide films 52 and 54. Next, as illustrated in FIG. 13A, the electrically conductive film 15B including the polysilicon film is embedded in the groove 15H. Thus, the opening width of the upper portion of the groove 15H is narrower than the lower portion of the groove 15H; therefore, the opening of the upper portion of the groove 15H is closed before the lower portion of the groove 15H is filled with the insulating film, thereby forming the air gap G in the lower portion of the groove 15H. Thereafter, as illustrated in FIG. 13B, an insulating film 56 is embedded in the upper portion of the groove 15H. Thus, the isolator 15 is completed in which in the first isolator 15X, the electrically conductive film 15B is embedded and the air gap G is formed.

Thus, in the present modification example, the electrically conductive film 15B is embedded and the air gap G is formed in the first isolator 15X of the isolator 15, which makes it possible to strengthen optical isolation between the unit pixels P adjacent to each other, in addition to the effects of the first embodiment described above. Accordingly, it is possible to further suppress color mixture. Furthermore, as with the modification example 2 described above, it is possible to apply, for example, a negative bias to the electrically conductive film 15B and enhance pinning, which makes it possible to suppress a dark current.

### 2-4. Modification Example 4

FIG. 14 schematically illustrates an example of a cross-sectional configuration of a photodetector (a photodetector 1D) according to the modification example 4 of the present disclosure. The photodetector 1D is, for example, a CMOS image sensor or the like used in an electronic apparatus such as a digital still camera or a video camera, and is, for example, a back-illuminated photodetector, as with the first embodiment described above.

In the first embodiment described above, the isolator 15 is formed in which the first isolator 15X and the second isolator 15Y have isolation widths that are substantially the same as each other (d1=d2). In contrast, in the photodetector 1D according to the present modification example, the isolator 15 is formed in which the isolation width (d1) of the second isolator 15Y is smaller than the isolation width (d2) of the first isolator 15X (d1<d2). Except for this point, the photodetector 1D has a configuration substantially similar to that of the photodetector 1.

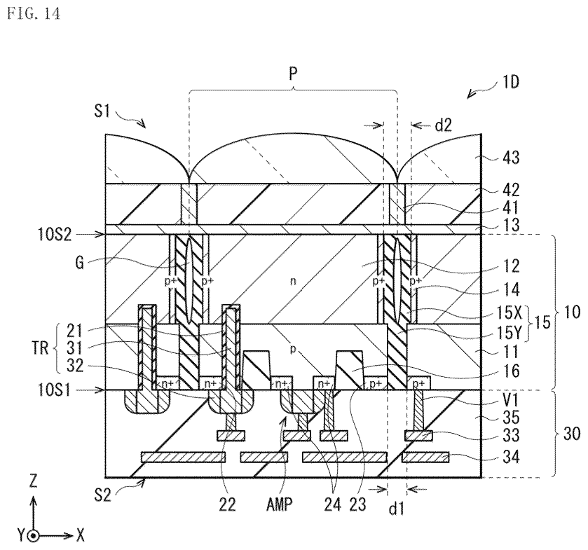

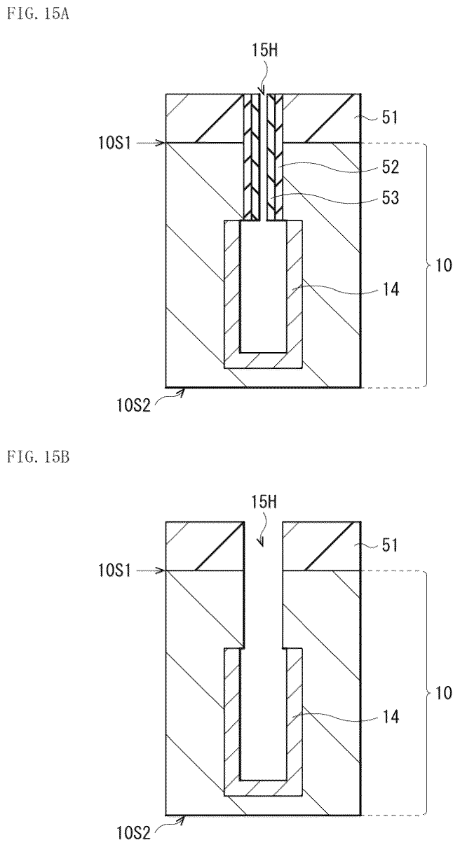

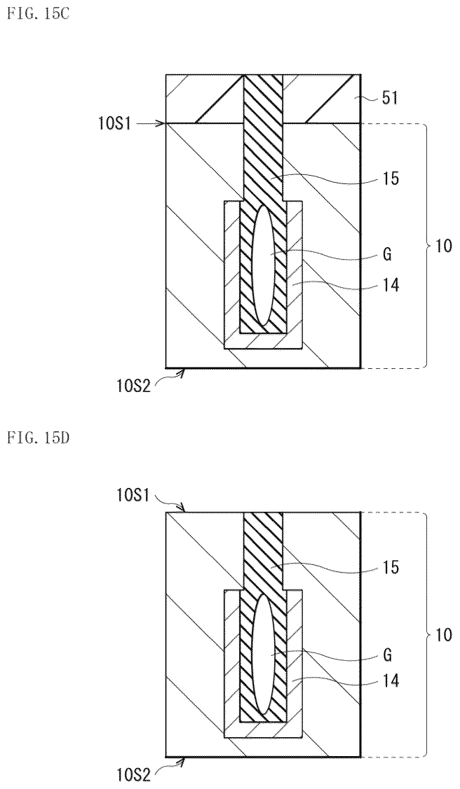

It is possible to form the isolator 15 according to the present modification example as follows, for example. As illustrated in FIG. 7E, the semiconductor substrate 10 exposed in the groove 15H is doped with, for example, boron (B) to form the p-type impurity region 14, and thereafter, as illustrated in FIG. 15A, a surface of the semiconductor substrate 10 exposed in the groove 15H is etched by a certain amount. This removes contamination during doping and damage to the surface. Next, as illustrated in FIG. 15B, the oxide films 52 and 54 in the upper portion of the groove 15H are removed.

Subsequently, as illustrated in FIG. 15C, the groove 15H is filled with an insulating film to form the isolator 15. At this time, the opening width of the upper portion of the groove 15H is narrower than the lower portion of the groove 15H; therefore, the opening of the upper portion of the groove 15H is closed before the lower portion of the groove 15H is filled with the insulating film, thereby forming the air gap G in the lower portion (the first isolator 15X) of the groove 15H. Thereafter, as illustrated in FIG. 15D, the mask 51 formed on the surface 10S1 of the semiconductor substrate 10 and the surface 10S1 of the semiconductor substrate 10 are ground by, for example, CMP to planarize the surface. Thus, the isolator 15 is completed in which the isolation width (d1) of the second isolator 15Y is smaller than the isolation width (d2) of the first isolator 15X (d1<d2).

In the present modification example, the isolator 15 is formed in which the isolation width (d1) of the second isolator 15Y is smaller than the isolation width (d2) of the first isolator 15X (d1<d2), which makes it possible to make an isolation distance in a plan view smaller than an actual isolation distance between the unit pixels P adjacent to each other. Accordingly, it is possible to further reduce the pixel size, in addition to the effects of the first embodiment described above.

### 2-5. Modification Example 5

FIG. 16A and FIG. 16B are each a schematic cross-sectional view for describing a method of manufacturing a photodetector according to the modification example 5 of the present disclosure. It is possible to form the photodetector 1 also as follows, for example.

First, as with the first embodiment described above, the isolator 15 is formed. Next, as illustrated in FIG. 8A, the light-receiving section 12 and the p-well 11 are formed in the semiconductor substrate 10, and thereafter, as illustrated in FIG. 16A, the gates of the transfer transistor TR and the amplification transistor AMP are formed.

Subsequently, as illustrated in FIG. 16B, the n-type impurity region 22 that forms the floating diffusion FD, the p-type impurity region 23 that forms the well contact region, and the p-type impurity region 24 that forms the source regions and the drain regions of the transfer transistor TR and the amplification transistor AMP are formed on the surface 10S1 of the semiconductor substrate 10.

Next, as with the first embodiment described above, the multilayer wiring layer 30 including the via V1, the wiring layers 33 and 34, and the interlayer insulating layer 35 is formed on the surface 10S1 of the semiconductor substrate 10. Next, although not illustrated, another substrate is bonded to side of the wiring layer S2, and thereafter, the surface 10S2 of the semiconductor substrate 10 is ground by, for example, CMP until the isolator 15 is exposed to planarize the surface. Thereafter, the fixed electric charge layer 13, the light-shielding film 41, the color filter 42, and the on-chip lens 43 are formed. Thus, the photodetector 1 illustrated in FIG. 1 is completed.

### 3. SECOND EMBODIMENT

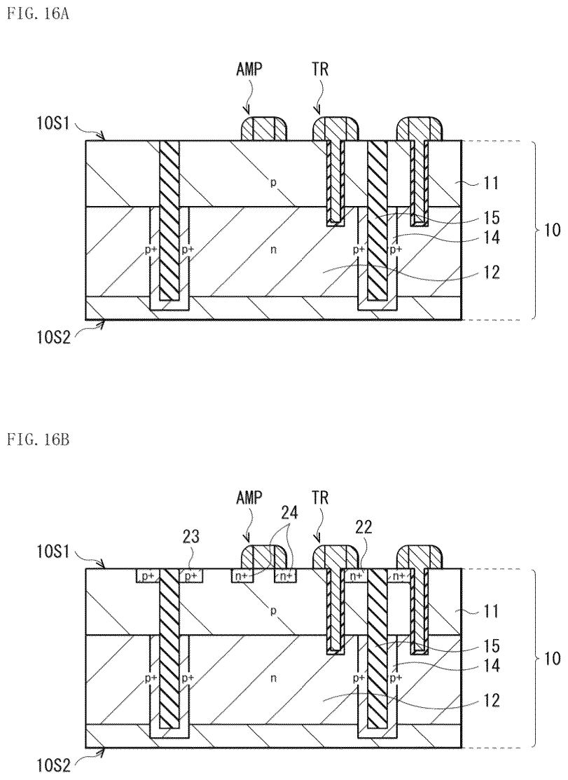

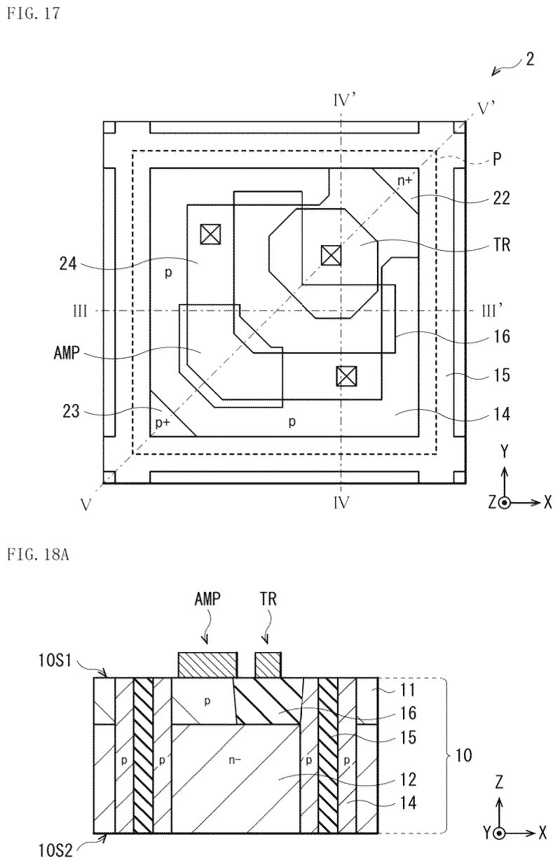

FIG. 17 schematically illustrates an example of a planar configuration of the unit pixel P of a photodetector (a photodetector 2) according to the second embodiment of the present disclosure. FIG. 18A schematically illustrates an example of a cross-sectional configuration of the photodetector 2 taken along a line III-III′ illustrated in FIG. 17. FIG. 18B schematically illustrates an example of a cross-sectional configuration of the photodetector 2 taken along a line IV-IV′ illustrated in FIG. 17. The photodetector 2 is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 2 is, for example, what is called a back-illuminated photodetector in the CMOS image sensor or the like.

### [Configuration of Unit Pixel]

As with the first embodiment described above, the photodetector 2 includes the pixel section 100A including the plurality of unit pixels P arranged in an array (see FIG. 2). The unit pixels P adjacent to each other in the pixel section 100A are isolated from each other by the isolator 15 that penetrates between the pair of surfaces (the front surface (the surface 10S1) and the back surface (the surface 10S2)) opposed to each other of the semiconductor substrate 10. In each of the unit pixels P isolated from each other by the isolator 15, a plurality of active elements (e.g., the transfer transistor TR and the amplification transistor AMP) is provided on the surface 10S1 of the semiconductor substrate 10, and the plurality of active elements is isolated, for example, by the isolator 16 that extends from the surface 10S1 to the surface 10S2 of the semiconductor substrate 10 and has a bottom inside the semiconductor substrate 10. In the present embodiment, the isolator 15 that isolates the unit pixels P adjacent from each other and the isolator 16 that isolates the plurality of active elements provided in the unit pixel P are provided to be spaced apart from each other.

The unit pixel P includes, as the light-receiving section 12, the photodiode PD that is formed to be embedded in the semiconductor substrate 10 having the pair of surfaces (the surface 10S1 and the surface 10S2) opposed to each other. The p-well 11 is formed as an active region on side opposite to the light incident side S1 of the light-receiving section 12 (on side of the front surface (the surface 10S1) of the semiconductor substrate 10). The p-well 11 is provided with, for example, the n-type impurity region 22, the p-type impurity region 23, and the n-type impurity region 24. The n-type impurity region 22 forms the floating diffusion FD. The p-type impurity region 23 forms the well contact region. The n-type impurity region 24 forms the source regions and the drain regions of the transfer transistor TR, and pixel transistors (e.g., the reset transistor RST, the selection transistor SEL, and the amplification transistor AMP) included in the readout circuit. The unit pixel P further includes the isolator 16 having an STI structure, and the transistor TR and the pixel transistor (e.g., the amplification transistor AMP) that are provided in the unit pixel P are isolated from each other by the isolator 16.

The isolator 15 is provided between the unit pixels P adjacent to each other. The isolator 15 corresponds to a specific example of a “first isolation trench” in an embodiment of the present disclosure. As described above, the isolator 15 isolates the unit pixels P adjacent to each other in the pixel section 100A including the plurality of unit pixels P arranged in an array, and is provided in a lattice form, for example, so as to surround an outer periphery of each of the unit pixels P.

The isolator 15 has an FTI structure that penetrates between the surface 10S1 and the surface 10S2 of the semiconductor substrate 10. Specifically, the isolator 15 has an FFTI (Front Full Trench Isolation) structure that penetrates between the surface 10S1 and the surface 10S2 of the semiconductor substrate 10, for example, from side of the surface 10S1 to the surface 10S2.

The isolator 15 has substantially the same isolation width between the surface 10S1 and the surface 10S2. In other words, the isolator 15 has a substantially rectangular cross-section having a substantially vertical angle between the side surface of the isolator 15 and the surface 10S1. A groove that forms the isolator 15 is filled with, for example, an insulating film such as a silicon oxide (SiOₓ) film.

For example, the p-type impurity region 14 having an impurity concentration higher than that of the p-well 11 is self-alignedly formed on the side surface of the isolator 15. The p-type impurity region 14 corresponds to a specific example of a “third p-type impurity region” in an embodiment of the present disclosure. Specifically, the p-type impurity region 14 is formed continuously along the side surface except for a part of the isolator 15 so as to surround the transfer transistor TR and the pixel transistor (e.g., the amplification transistor AMP) that are provided in the unit pixel. As with the isolator 15, the p-type impurity region 14 is formed continuously between the surface 10S1 and the surface 10S2 of the semiconductor substrate 10 so as to penetrate the semiconductor substrate 10.

In the unit pixel P, the n-type impurity region 22 and the p-type impurity region 23 are provided on the surface 10S1 of the semiconductor substrate 10. The n-type impurity region 22 forms the floating diffusion FD, and the p-type impurity region 23 forms the well contact region. The well contact region applies a reference potential to the semiconductor substrate 10. The n-type impurity region 22 and the p-type impurity region 23 are formed along the side surface of the isolator 15 at corners on a diagonal line of the unit pixel P having a rectangular shape, for example. The n-type impurity region 22 and the p-type impurity region 23 each correspond to the part, on which the p-type impurity region 14 described above is not formed, of the side surface of the isolator 15.

The isolator 16 corresponds to a specific example of a “second isolation trench” in an embodiment of the present disclosure. As described above, the isolator 16 isolates a plurality of active elements provided in the unit pixel P. The isolator 16 has an STI structure that extends from the surface 10S1 to the surface 10S2 of the semiconductor substrate 10, and has a bottom inside the semiconductor substrate 10. The isolator 16 has an isolation width on the light incident side S1 smaller than an isolation width on side of the wiring layer S2. In other words, the isolator 15 has a forward-tapered cross-section having an angle of less than 90° between the side surface of the isolator 15 and the surface 10S1. Note that the cross-sectional shape of the isolator 16 is not limited to a forward-tapered shape. FIG. 18A illustrates an example in which a width of the isolator 16 exposed to the surface 10S1 is larger than the isolation width of the isolator 15, but this is not limitative. The width of the isolator 16 exposed to the surface 10S1 may be smaller than the isolation width of the isolator 15. A groove that forms the isolator 16 is filled with, for example, an insulating film such as a silicon oxide (SiOₓ) film.

In the present embodiment, the isolator 16 is provided to be spaced apart from the isolator 15. In other words, as illustrated in FIG. 17, the isolator 15 and the isolator 16 are formed at positions not overlapping each other in a plan view. Specifically, the isolator 16 is selectively provided between the transfer transistor TR and the pixel transistor (e.g., the amplification transistor AMP) that are provided in the unit pixel P surrounded by the isolator 15. This makes it possible to independently control the depth of the isolator 16. Specifically, making the depth of the isolator 16 formed above the light-receiving section 12 shallower makes it possible to enlarge the light-receiving section 12 toward side of the surface 10S1 of the semiconductor substrate 10.

A part of the side surface of the isolator 16 is in contact with the p-type impurity region 14 formed along the side surface of the isolator 15, as illustrated in FIG. 17 and FIG. 18A. This makes it possible to prevent a dark current, a white spot, and the like generated on the side surface of the isolator 16.

It is to be noted that, in a case where the isolator 16 does not reach the p-type impurity region 14, as illustrated in FIG. 19, a p-type diffusion layer 25 may be separately formed between the p-type impurity region 14 and the isolator 16 on the surface 10S1 of the semiconductor substrate 10 by, for example, ion implantation or the like. This makes it possible to prevent a dark current, a white spot, and the like generated on the side surface of the isolator 16 also in a case where the isolator 16 and the p-type impurity region 14 are separated.

In the present embodiment, the semiconductor substrate at and in proximity to the surface 10S1 in the unit pixel P is continuous without being isolated by the isolator 16. In addition, the plurality of active elements provided in the unit pixel P is surrounded by the p-type impurity region 14 and the isolator 16 that are formed along the side surface of the isolator 15. Specifically, for example, a channel of the transfer transistor TR is sandwiched between the n-type impurity region 22 that forms the floating diffusion FD, and the isolator 16. A channel and the source/drain of the amplification transistor AMP are surrounded by the p-type impurity region 14 and the isolator 16.

### [Method of Manufacturing Photodetector]

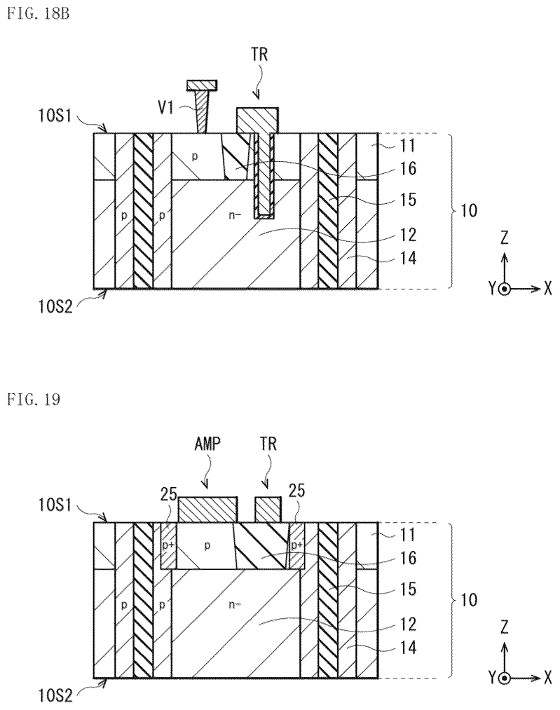

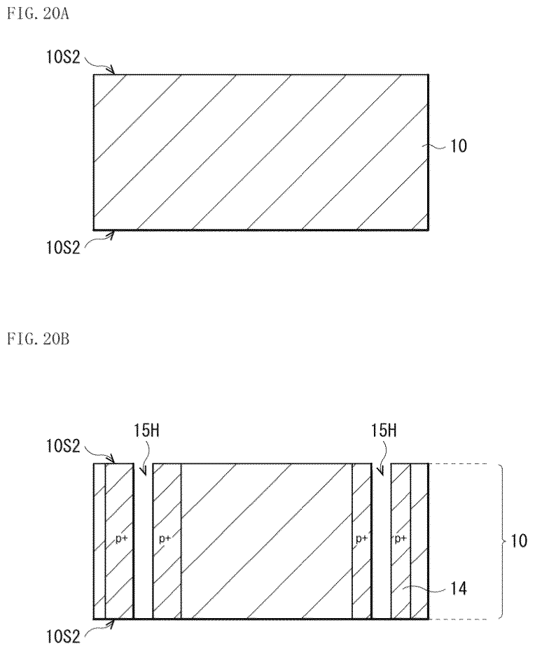

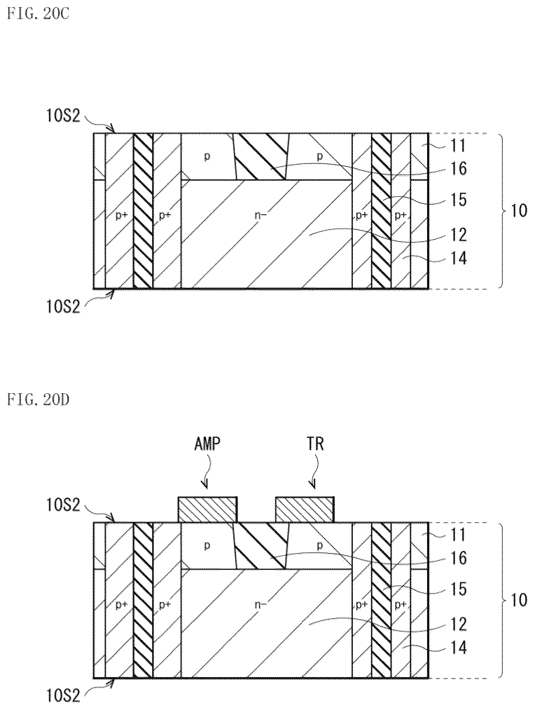

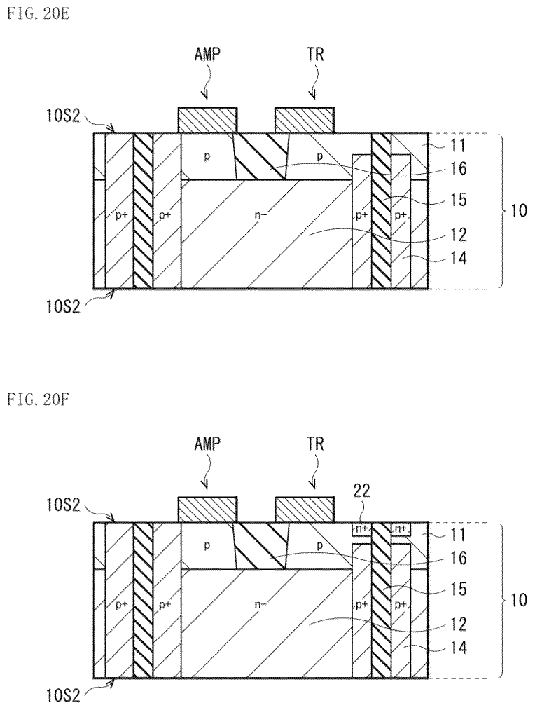

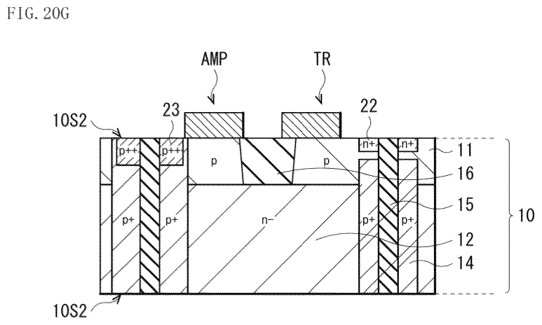

It is possible to form the photodetector 2 as follows, for example. It is to be noted that FIGS. 20A to 20E each schematically illustrate a cross-section taken along a line V-V′ illustrated in FIG. 17.

FIG. 20A illustrates a state of the semiconductor substrate 10 before processing. First, as with the first embodiment described above, as illustrated in FIG. 20B, the groove 15H is formed with use of a photolithography method and a RIE (Reactive Ion Etching) method. Next, as illustrated in FIG. 20B, the semiconductor substrate 10 exposed in the groove 15H is doped with, for example, boron (B) with use of, for example, a plasma doping method, a solid phase diffusion method, or the like to form the p-type impurity region 14.

Subsequently, as illustrated in FIG. 20C, a polysilicon film or the like is deposited in the groove 15H, and thereafter, an insulating film is further deposited in the groove 15H to embed the groove 15H. Thereafter, the insulating film formed on the surface 10S1 of the semiconductor substrate 10 and the surface 10S1 of the semiconductor substrate 10 are ground by, for example, CMP to planarize the surface. Next, as illustrated in FIG. 20C, the light-receiving section 12 and the p-well 11 are formed in the semiconductor substrate 10 with use of ion implantation or the like, and thereafter, a groove having a predetermined depth is formed on the surface 10S1 of the semiconductor substrate 10. Thereafter, an insulating film is embedded in the groove to form the isolator 16. Thereafter, the insulating film formed on the surface 10S1 of the semiconductor substrate 10 and the surface 10S1 of the semiconductor substrate 10 are ground by, for example, CMP to planarize the surface.

Subsequently, as illustrated in FIG. 20D, gates of the transfer transistor TR and the pixel transistor such as the amplification transistor AMP are formed. Next, as illustrated in FIG. 20E, n-type ions are implanted into the surface 10S1 of the semiconductor substrate 10 in proximity to the side surface of the isolator 15 by, for example, ion implantation or the like to decrease an effective p-type impurity concentration in proximity to the side surface of the isolator 15.

Subsequently, as illustrated in FIG. 20F, for example, n-type ions such as P (phosphorus) or As (arsenic) are implanted in a region having a decreased p-type impurity concentration by, for example, ion implantation or the like to form the n-type impurity region 22 that becomes the floating diffusion FD. Likewise, as illustrated in FIG. 20G, for example, p-type ions such as boron (B) are implanted in the p-type impurity region 14 in proximity to the side surface of the isolator 15 to form the p-type impurity region 23 that becomes the well contact region.

Thereafter, various kinds of wirings such as the via V1 are formed on the surface 10S1 of the semiconductor substrate 10. Thus, the photodetector 2 illustrated in FIG. 17 is completed.

### Workings and Effects

In the photodetector 2 according to the present embodiment, the isolator 15 that isolates the unit pixels P adjacent to each other, and the isolator 16 that isolates the plurality of active elements provided in the unit pixel P are provided to be spaced apart from each other. This makes it possible to independently control the depth of the second isolator 15Y that is included in the isolator 15 and has an STI structure, and the depth of the isolator 16 that similarly has an STI structure. This is described below.

As described above, the pixel size has been reduced with an increase in resolution of the CMOS image sensor. In a typical CMOS image sensor, electrical and optical isolation between photodiodes is performed with use of an FDTI, and a transfer transistor and a transistor included in a readout circuit are isolated by an STI.

Typically, the STI has an isolation width wider than that of the FDTI. Accordingly, in a case where the STI is formed on the FDTI, a level difference is formed by a difference between the isolation widths. The difference between the isolation widths is for forming an upper end position of a p-type impurity region formed on a side surface of the FDTI self-alignedly with respect to a depth of a bottom of the STI. In addition, at this time, in many cases, the bottom of the STI formed on the FDTI and the bottom of STI that isolates transistors are formed at the same depth. A reason for this is that the STI formed on the FDTI and the STI that isolates transistors are formed by the same process, which makes it possible to reduce manufacturing cost.

Such a CMOS image sensor has the following issues. That is, in a case where the STI is formed on the FDTI, a crystal defect may occur by a stress or the like that is locally applied to an Si substrate due to formation of a level difference in a contact section therebetween. In a case where the crystal defect occurs, an image defect such as a white spot defect occurs in a pixel in which the crystal defect has occurred, which decreases image quality of a reproduced image. In addition, the STI on the FDTI and the STI that isolates transistors are formed by the same process; therefore, it is not possible to independently control respective depths.

In contrast, in the present embodiment, the isolator 15 that isolates the unit pixels P adjacent to each other, and the isolator 16 that isolates the plurality of active elements provided in the unit pixel P are provided to be spaced apart from each other. This makes it possible to independently control the depth of the isolator 16. Specifically, for example, making the depth of the isolator 16 formed above the light-receiving section 12 shallower makes it possible to enlarge the light-receiving section 12 toward side of the surface 10S1 of the semiconductor substrate 10. Thus, in the photodetector 2 according to the present embodiment, it is possible to increase the number of saturated electrons in the light-receiving section 12, which makes it possible to obtain an image having a wide dynamic range also in a case where the pixel size is reduced. That is, it is possible to improve image quality in imaging.

In addition, in the photodetector 2 according to the present embodiment, an area of the STI occupying the front surface (the surface 10S1) of the semiconductor substrate 10 in the unit pixel P is reduced, which makes it possible to reduce the pixel size. In addition, it is possible to maintain performance of active elements such as transistors or improve the performance, which makes it possible to improve performance of the photodetector 1.

Furthermore, in the photodetector 2 according to the present embodiment, the isolator 15 is formed with a substantially uniform width. This makes it possible to reduce a stress to be locally applied to the semiconductor substrate 10, which makes it possible to occurrence of a crystal defect. Thus, it is possible to improve reliability.

### 4. MODIFICATION EXAMPLES

### 4-1. Modification Example 6

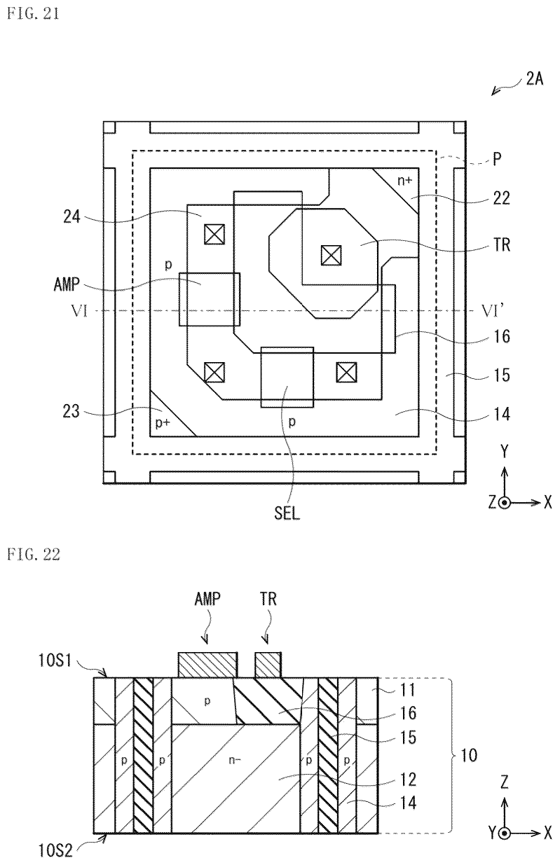

FIG. 21 schematically illustrates an example of a planar configuration of the unit pixel P of a photodetector (a photodetector 2A) according to the modification example 6 of the present disclosure. FIG. 22 schematically illustrates an example of a cross-sectional configuration of the photodetector 2A taken along a line VI-VI′ illustrated in FIG. 21. The photodetector 2A is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 2A is, for example, what is called a back-illuminated photodetector in the CMOS image sensor or the like.

In the second embodiment described above, two transistors (the transfer transistor TR and the amplification transistor AMP) are formed in the unit pixel P. In contrast, in the photodetector 2A according to the present modification example, for example, the selection transistor SEL is provided together with the transfer transistor TR and the amplification transistor AMP in the unit pixel P, and the source/drain is shared by the amplification transistor AMP and the selection transistor SEL. Except for this point, the photodetector 2A has a configuration substantially similar to that of the photodetector 2.

As described above, two or more transistors may be formed in a region surrounded by the p-type impurity region 14 and the isolator 16. Also in such a configuration, it is possible to achieve effects similar to the effects of the second embodiment described above.

It is to be noted that FIG. 21 illustrates an example in which a contact is provided in the source/drain shared by the amplification transistor AMP and the selection transistor SEL, but this is not limitative. For example, a contact provided in the source/drain shared by the amplification transistor AMP and the selection transistor SEL may be eliminated, and two transistors may be coupled in series to each other.

### 4-2. Modification Example 7

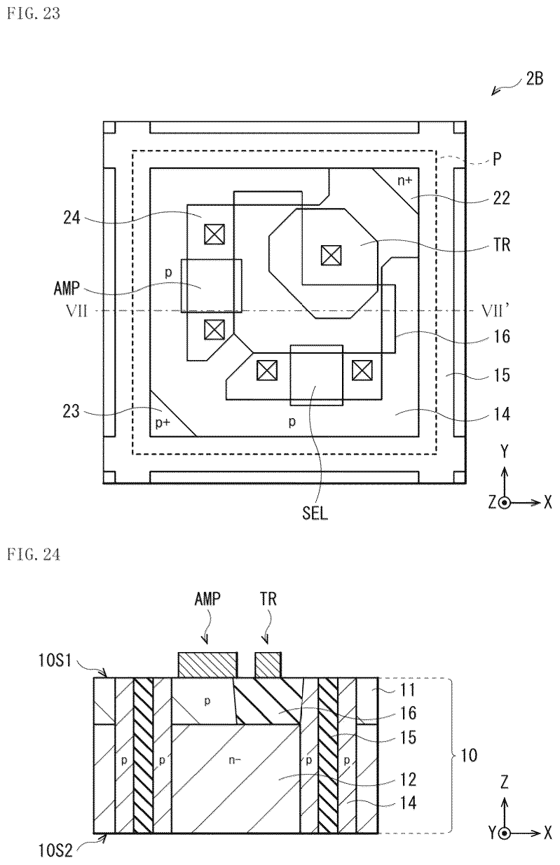

FIG. 23 schematically illustrates an example of a planar configuration of the unit pixel P of a photodetector (a photodetector 2B) according to the modification example 7 of the present disclosure. FIG. 24 schematically illustrates an example of a cross-sectional configuration of the photodetector 2B taken along a line VII-VII′ illustrated in FIG. 23. The photodetector 2B is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 2B is, for example, what is called a back-illuminated photodetector in the CMOS image sensor or the like.

In the modification example 6 described above, an example has been described in which the source/drain is shared by the amplification transistor AMP and the selection transistor SEL. In contrast, in the photodetector 2B according to the present modification example, the source/drain is not shared by the amplification transistor AMP and the selection transistor SEL, and is isolated by the p-type impurity region 14. Except for this point, the photodetector 2B has a configuration substantially similar to that of the photodetector 2A.

As described above, a plurality of regions surrounded by the p-type impurity region 14 and the isolator 16 may be provided in the unit pixel P, and a transistor may be formed in each of the regions. Also in such a configuration, it is possible to achieve effects similar to the effects of the second embodiment described above.

### 4-3. Modification Example 8

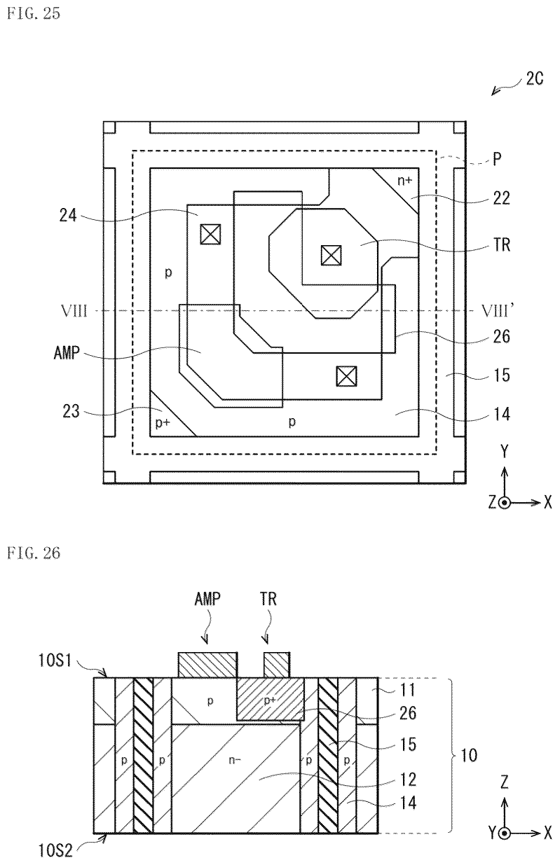

FIG. 25 schematically illustrates an example of a planar configuration of the unit pixel P of a photodetector (a photodetector 2C) according to the modification example 8 of the present disclosure. FIG. 26 schematically illustrates an example of a cross-sectional configuration of the photodetector 2C taken along a line VIII-VIII′ illustrated in FIG. 25. The photodetector 2C is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 2C is, for example, what is called a back-illuminated photodetector in the CMOS image sensor or the like.

In the second embodiment described above, the transfer transistor TR and the amplification transistor AMP are isolated by the isolator 16. In contrast, in the photodetector 2C according to the present modification example, the transfer transistor TR and the amplification transistor AMP are isolated by a p-type diffusion layer 26. Except for this point, the photodetector 2C has a configuration substantially similar to that of the photodetector 2.

The p-type diffusion layer 26 corresponds to a specific example of a “fourth p-type impurity region” in an embodiment of the present disclosure. The p-type diffusion layer 26 differs from the p-type impurity region 14 that is self-alignedly formed on the side surface of the isolator 15, and is formed to be spaced apart from the side surface of the isolator 15, as with the isolator 16. It is possible to form the p-type diffusion layer 26 by implanting, for example, p-type ions such as boron (B) by, for example, ion implantation or the like.

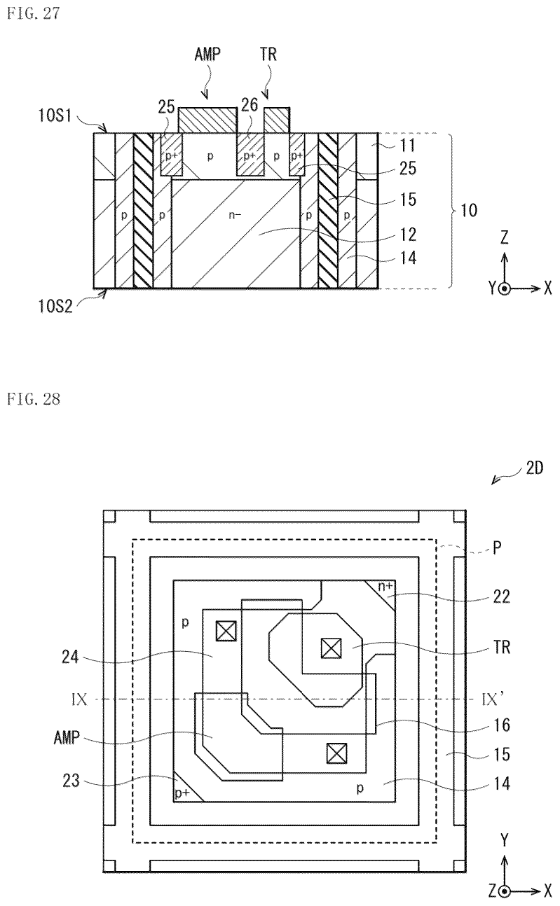

It is to be noted that, in a case where the p-type diffusion layer 26 and the p-type impurity region 14 are spaced apart from each other, as with the second embodiment described above, for example, as illustrated in FIG. 27, the p-type diffusion layer 25 may be separately formed between the p-type impurity region 14 and the p-type diffusion layer 26 on the surface 10S1 of the semiconductor substrate 10 by ion implantation or the like.

Thus, in the present modification example, the transfer transistor TR and the amplification transistor AMP are isolated by the p-type diffusion layer 26. Also in such a configuration, it is possible to achieve effects similar to the effects of the second embodiment described above.

### 4-4. Modification Example 9

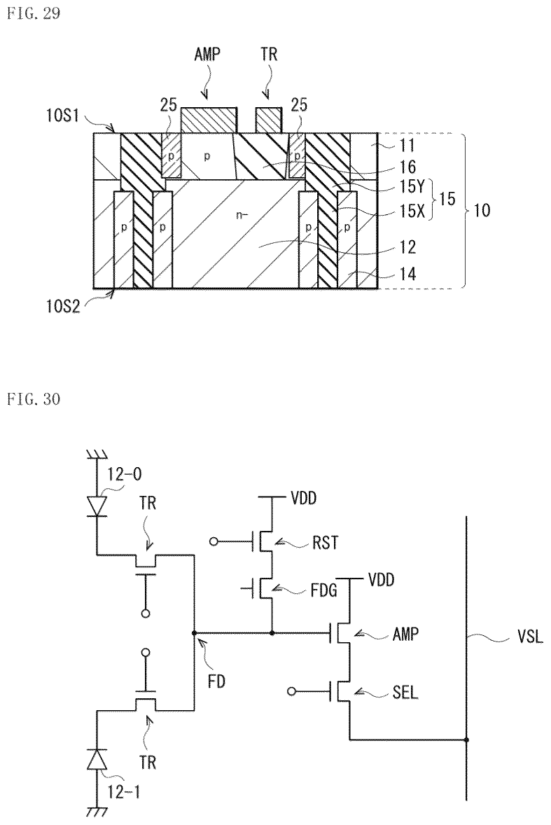

FIG. 28 schematically illustrates an example of a planar configuration of the unit pixel P of a photodetector (a photodetector 2D) according to the modification example 9 of the present disclosure. FIG. 29 schematically illustrates an example of a cross-sectional configuration of the photodetector 2D taken along a line IX-IX′ illustrated in FIG. 28. The photodetector 2D is, for example, a CMOS image sensor or the like used in an electronic apparatus such as a digital still camera or a video camera, and includes, as an imaging region, a pixel section (a pixel section 100A) including a plurality of pixels (unit pixels P) two-dimensionally arranged in a matrix. The photodetector 2D is, for example, what is called a back-illuminated photodetector in the CMOS image sensor or the like.

In the second embodiment described above, an example has been described in which the isolator 15 has an FFTI structure that penetrates from side of the surface 10S1 to the surface 10S2 and has substantially the same isolation width between side of the surface 10S1 and the surface 10S2. In contrast, in the photodetector 2D according to the present modification example, the isolator 15 includes the first isolator 15X having an FDTI structure and the second isolator 15Y having an STI structure. The FDTI structure extends between the surface 10S1 and the surface 10S2 of the semiconductor substrate 10, for example, from side of the surface 10S1 to the surface 10S2. The STI structure extends from side of the surface 10S1 to the surface 10S2, and has a bottom inside the semiconductor substrate 10. The first isolator 15X corresponds to a specific example of a “first isolator” in an embodiment of the present disclosure, and corresponds to a specific example of a “second isolator” in an embodiment of the present disclosure. The width of the second isolator 15Y is larger than the isolation width of the first isolator 15X, and the p-type impurity region 14 formed along the side surface of the isolator 15 has an upper end at a bottom of the wide second isolator 15Y, and is formed along the side surface of the first isolator 15X. In addition, the p-type diffusion layer 25 is formed on the side surface of the second isolator 15Y. Except for these points, the photodetector 2D has a configuration substantially similar to that of the photodetector 2.

Thus, in the present modification example, the isolator 15 is formed including the first isolator 15X having the FDTI structure and the second isolator 15Y having the STI structure. Also in such a configuration, forming the second isolator 15Y and the isolator 15 by different processes makes it possible to independently control the depth of the second isolator 15Y and the depth of the isolator 16. Specifically, for example, making the depth of the isolator 16 formed above the light-receiving section 12 shallower makes it possible to enlarge the light-receiving section 12 toward side of the surface 10S1 of the semiconductor substrate 10. Thus, as with the second embodiment described above, it is possible to increase the number of saturated electrons in the light-receiving section 12, which makes it possible to obtain an image having a wide dynamic range also in a case where the pixel size is reduced. That is, it is possible to improve image quality in imaging. In addition, it is possible to form the isolator 16 shallow, which makes it possible to reduce the area of the isolator 16 on the surface 10S1 of the semiconductor substrate 10 accordingly. Thus, even if the pixel size is reduced, it is possible to dispose the isolator 16 without impairing the size of the transistor.

### 4-5. Modification Example 10

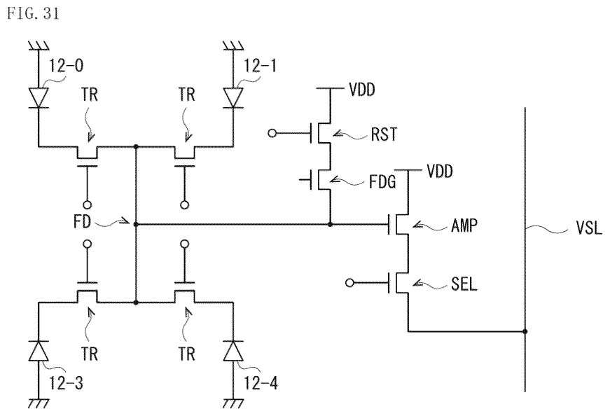

FIG. 30 illustrates an example of a readout circuit of a photodetector according to the modification example 10 of the present disclosure. FIG. 31 illustrates another example of the readout circuit of the photodetector according to the modification example 10 of the present disclosure.

In the pixel section 100A, as described above, a plurality of unit pixels P is two-dimensionally arranged in a matrix. Of the plurality of unit pixels P, unit cells each including a plurality of unit pixels adjacent to each other may be repeatedly arranged as repeating units in an array.

Specifically, for example, each of the unit cells may include two unit pixels adjacent to each other in a row direction or a column direction. For example, as illustrated in FIG. 30, in two unit pixels P included in the unit cell, two light-receiving sections 12 (light-receiving sections 12-0 and 12-1) and the transfer transistors TR share one floating diffusion FD and one readout circuit. Alternatively, each of the unit cells may include four unit pixels adjacent to each other, for example, in two rows and two columns, for example, in the row direction and the column direction. For example, as illustrated in FIG. 31, in the four unit pixels P included in the unit cell, four light-receiving sections 12 (light-receiving sections 12-0, 12-1, 12-2, and 12-3) and the transfer transistors TR share one floating diffusion FD and one readout circuit. Herein, “share” indicates that outputs of two or four unit pixels P are inputted to a common floating diffusion and a common readout circuit.

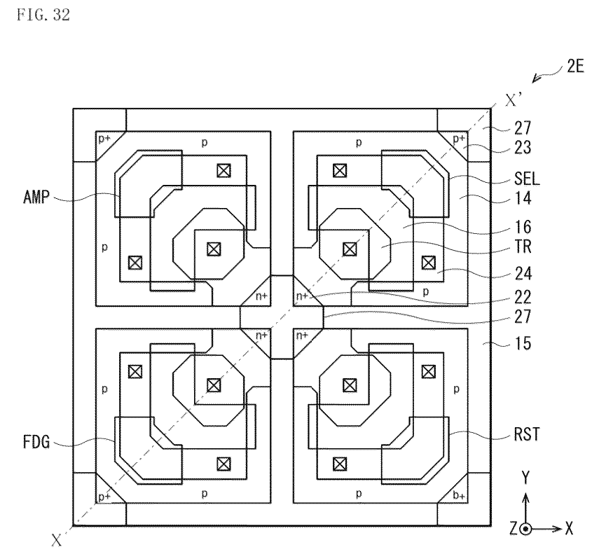

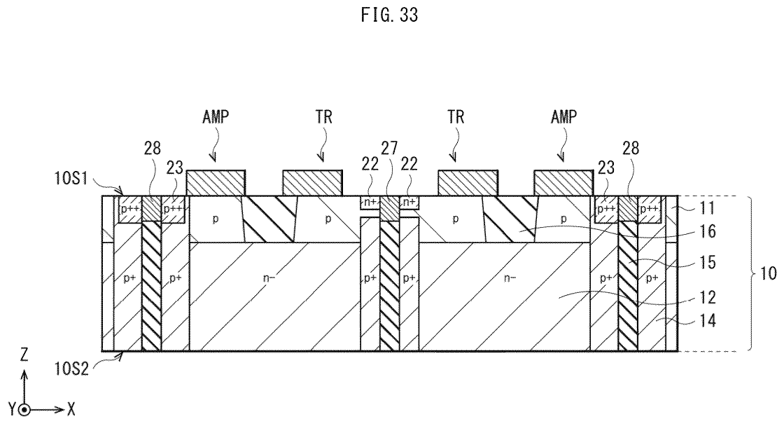

FIG. 32 schematically illustrates an example of a planar configuration of a photodetector 2E in which four unit pixels adjacent to each other in two rows and two columns illustrated in FIG. 31 share one floating diffusion FD and one readout circuit. FIG. 33 schematically illustrates an example of a cross-sectional configuration of the photodetector 2E taken along a line X-X′ illustrated in FIG. 32.

As illustrated in FIG. 31, in a case where four light-receiving sections 12 (the light-receiving sections 12-0, 12-1, 12-2, and 12-3) and the transfer transistors TR share one floating diffusion FD and one readout circuit, a polysilicon film 27 that is n-type doped by, for example, ion implantation or the like is embedded in the isolator 15 that is positioned at an intersection of four unit pixels P arranged, for example, in two rows and two columns, and is thermally diffused, which makes it possible to form the n-type impurity region 22 that becomes the floating diffusion FD on the surface 10S1 of the semiconductor substrate 10 around the polysilicon film 27. In addition, a polysilicon film 28 that is p-type doped by, for example, ion implantation or the like is embedded in the isolator 15 on a diagonal line of the isolator 15 in which the polysilicon film 27 is embedded, and is thermally diffused, which makes it possible to form the p-type impurity region 23 that becomes the well contact region on the surface 10S1 of the semiconductor substrate 10 around the polysilicon film 28.

### 5. THIRD EMBODIMENT

FIG. 34 schematically illustrates an example of a planar configuration of a photodetector (a photodetector 3) according to the third embodiment of the present disclosure. FIG. 35 schematically illustrates an example of a cross-sectional configuration of the photodetector 3 taken along a line XI-XI′ illustrated in FIG. 34. The photodetector 3 is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 3 is, for example, what is called a back-illuminated photodetector in the CMOS image sensor or the like.

### [Configuration of Unit Pixel]

As with the first embodiment described above, the photodetector 3 includes the pixel section 100A including the plurality of unit pixels P arranged in an array (see FIG. 2). The unit pixels P adjacent to each other in the pixel section 100A are isolated from each other by an isolator 17 that extends between the pair of surfaces (the front surface (the surface 10S1) and the back surface (the surface 10S2)) opposed to each other of the semiconductor substrate 10. Each of the unit pixels P isolated from each other by the isolator 17 is provided with the n-type impurity region 22 and a p-type impurity region 62. The n-type impurity region 22 forms the floating diffusion FD, and the p-type impurity region 62 forms the well contact region. In the present embodiment, the p-type impurity region 62 is formed inside the semiconductor substrate 10.

The unit pixel P includes, as the light-receiving section 12, the photodiode PD that is formed to be embedded in the semiconductor substrate 10 having the pair of surfaces (the surface 10S1 and the surface 10S2) opposed to each other. The p-well 11 is formed as an active region on side opposite to the light incident side S1 of the light-receiving section 12 (on side of the front surface (the surface 10S1) of the semiconductor substrate 10). The p-well 11 of the light-receiving section 12 is provided with, for example, the n-type impurity region 22, the p-type impurity region 62, and the n-type impurity region 24. The n-type impurity region 22 forms the floating diffusion FD. The p-type impurity region 62 forms the well contact region. The n-type impurity region 24 forms the source regions and the drain regions of the transfer transistor TR, and pixel transistors (e.g., the reset transistor RST, the selection transistor SEL, and the amplification transistor AMP) included in the readout circuit. The unit pixel P further includes the isolator 16 having an STI structure, and the transistor TR and the pixel transistor (e.g., the amplification transistor AMP) that are provided in the unit pixel P are isolated from each other by the isolator 16.

The isolator 16 corresponds to a specific example of a “second isolation trench” in an embodiment of the present disclosure. As described above, the isolator 16 isolates the transfer transistor TR and the pixel transistor (e.g., the amplification transistor AMP) that are provided in the unit pixel P. The isolator 16 has an STI structure that extends from the surface 10S1 to the surface 10S2 of the semiconductor substrate 10 and has a bottom inside the semiconductor substrate 10. The isolator 16 has an isolation width on the light incident side S1 smaller than the isolation width on side of the wiring layer S2. In other words, the isolator 16 has a forward-tapered cross-section having an angle of less than 90° between the side surface of the isolator 16 and the surface 10S1. In addition, the isolation width of the isolator 16 exposed to the surface 10S1 is larger than an isolation width of the isolator 17. A groove that forms the isolator 16 is filled with, for example, an insulating film such as a silicon oxide (SiOₓ) film.

The isolator 17 is provided between the unit pixels P adjacent to each other. The isolator 17 corresponds to a specific example of a “first isolation trench” in an embodiment of the present disclosure. As described above, the isolator 17 isolates the unit pixels P adjacent to each other in the pixel section 100A including the plurality of unit pixels P arranged in an array, and is provided in a lattice form, for example, so as to surround an outer periphery of each of the unit pixels P.

The isolator 17 has an FTI structure that penetrates between the surface 10S1 and the surface 10S2 of the semiconductor substrate 10. Specifically, the isolator 17 includes a first isolator 17X having an FDTI structure and a second isolator 17Y having an STI structure. The FDTI structure extends between the surface 10S1 and the surface 10S2 of the semiconductor substrate 10, for example, from side of the surface 10S1 to the surface 10S2. The STI structure extends from side of the surface 10S1 to the surface 10S2, and has a bottom inside the semiconductor substrate 10. The first isolator 17X has a substantially rectangular cross-section having a substantially vertical angle between a side surface of the isolator 17X and the surface 10S1. The second isolator 17Y has a forward-tapered cross-section having an angle of less than 90° between a side surface of the isolator 17Y and the surface 10S1. An isolation width of a bottom of the isolator 17Y is larger than an isolation width of the isolator 17X. A groove that forms the isolator 17 is filled with, for example, an insulating film such as a silicon oxide (SiOₓ) film.

Two electrical conductors 61 and 63 are embedded in the isolator 17. Specifically, for example, as illustrated in FIG. 34, the electrical conductor 61 is embedded in a cross shape in the intersecting second isolator 17Y in a plan view. The electrical conductor 61 is, for example, a polysilicon film doped with a p-type impurity at an impurity concentration (e.g., 1E18 cm⁻³ to 1E21 cm⁻³) higher than those of the p-type impurity region 14 and the p-type impurity regions 23 and 62, and is in contact with the semiconductor substrate 10 inside the semiconductor substrate 10. The p-type impurity region 14 has, for example, an impurity concentration of 1E17 cm⁻³ to 1E20 cm⁻³, and the p-type impurity regions 23 and 62 have, for example, an impurity concentration of 1E16 cm⁻³ to 1E19 cm⁻³. The p-type impurity region 62 that becomes a well contact region is formed inside the semiconductor substrate 10 by thermally diffusing the electrical conductor 61. The well contact region applies a reference potential to the semiconductor substrate 10. Specifically, the p-type impurity region 62 is formed on side lower than a bottom (h1) of the isolator 16 (on side of the surface 10S2). This makes it possible to reduce the area of the p-type impurity region formed on the surface 10S1 of the semiconductor substrate 10 and increase an area where transistors can be disposed.

It is to be noted that a position where the electrical conductor 61 is embedded is preferably apart from the n-type impurity region (e.g., the source/drain of the amplification transistor or the like, and the n-type impurity region 22 that forms the floating diffusion FD) formed on the surface 10S1 of the semiconductor substrate 10. A reason for this is as follows. The depth of the isolator 16 is reduced together with reduction in the pixel size; therefore, in a case where they are close to each other, even if there is a certain distance in a thickness direction (a Z-axis direction) of the semiconductor substrate 10, the p-type impurity region 62 and the n-type impurity region (e.g., the n-type impurity region 22) approach each other, thereby increasing a junction electric field to cause noise by a leakage current.

The electrical conductor 63 corresponds to a specific example of an “electrical conductor” in an embodiment of the present disclosure. The electrical conductor 63 is embedded in the first isolator 17X. The electrical conductor 63 is, for example, a polysilicon film doped with a p-type impurity, and is electrically insulated from the semiconductor substrate 10. In addition, an upper end (h3) of the electrical conductor 63 is formed on side lower than an lower end (h2) of the electrical conductor 61 (on side of the surface 10S2). That is, the electrical conductor 63 is electrically insulated also from the electrical conductor 61. A voltage lower than the reference potential is applied to the electrical conductor 63. This reduces a dark current generated at an interface of the first isolator 17X.

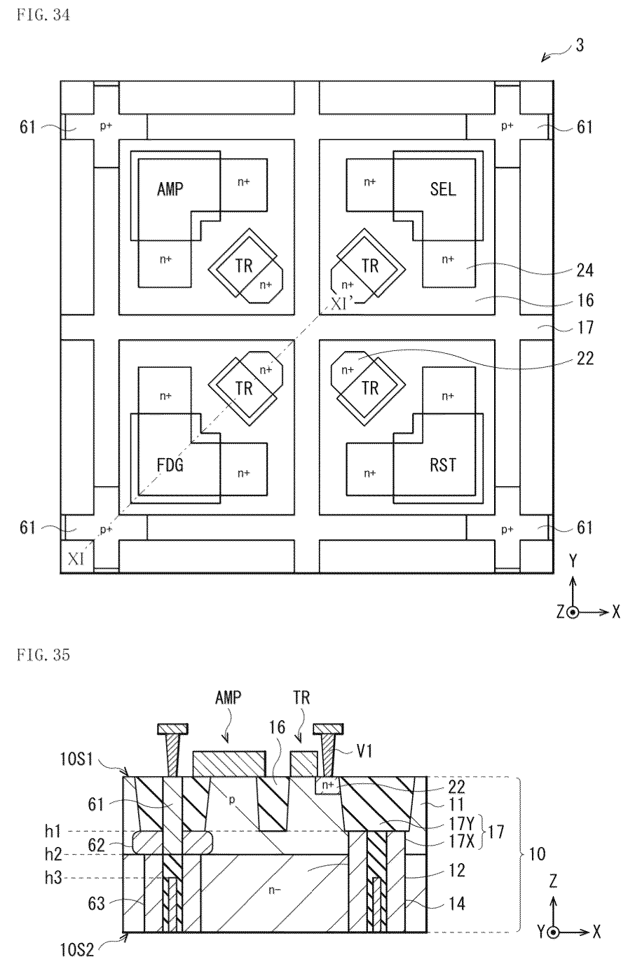

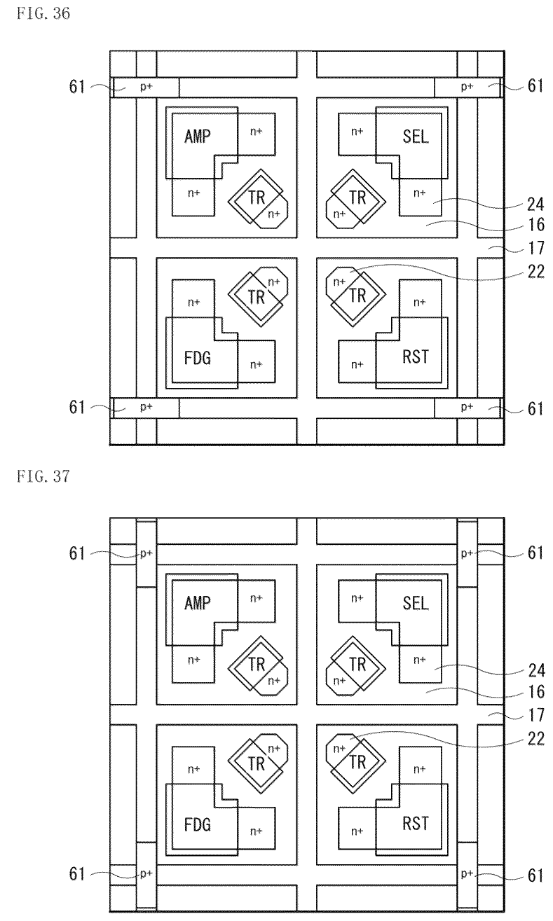

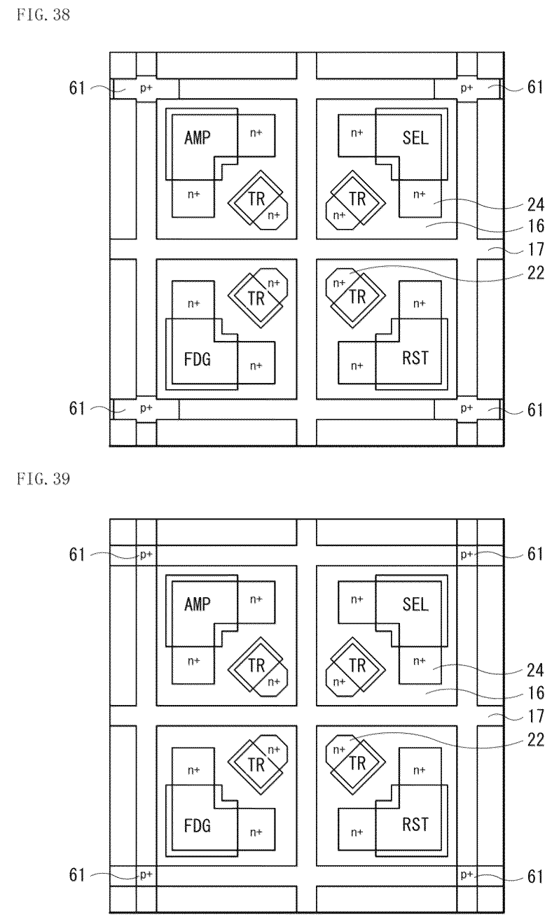

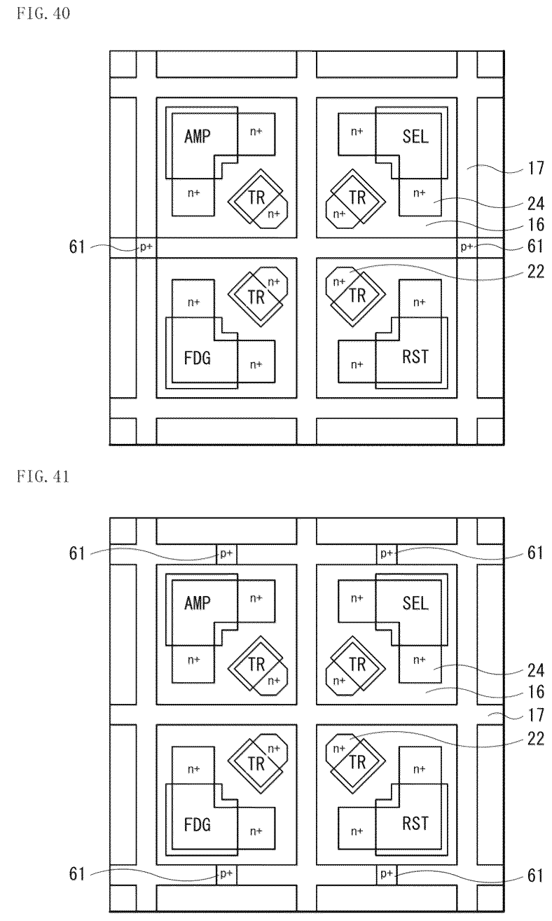

FIGS. 36 to 41 each schematically illustrate another example of the planar configuration of the photodetector 3. FIG. 34 illustrates an example in which the electrical conductor 61 is embedded in a cross shape in the intersecting isolator 17 in a plan view, but this is not limitative. For example, as illustrated in FIG. 36 and FIG. 37, the electrical conductor 61 that extends in the row direction or the column direction may be embedded in the isolator 17. Alternatively, as illustrated in FIG. 38, the electrical conductor 61 that extends unequally in the row direction and the column direction may be embedded in the isolator 17. Alternatively, as illustrated in FIG. 39, for example, the electrical conductor 61 may be selectively embedded only in an intersecting portion of the isolator 17 in proximity to the gate of the amplification transistor AMP. Alternatively, in a case where there is a certain or larger distance from the n-type impurity region, as illustrated in FIG. 40, the electrical conductor 61 may be embedded in an intersecting portion of the isolator 17 other than an intersecting portion in proximity to the gate. Alternatively, as illustrated in FIG. 41, the electrical conductor 61 may be embedded in the isolator 17 other than intersecting portions.

### Workings and Effects

In the photodetector 3 according to the present embodiment, the p-type impurity region 62 that forms the well contact region is formed inside the semiconductor substrate 10. This reduces the area of the isolator 16 having an STI structure formed on the front surface (the surface 10S1) of the semiconductor substrate 10. This is described below.

As described above, the pixel size has been reduced with an increase in resolution of the CMOS image sensor. In a typical CMOS image sensor, electrical and optical isolation between photodiodes is performed with use of an FDTI, and a transfer transistor and a transistor included in a readout circuit are isolated by an STI.

Such a CMOS image sensor has the following issues. For example, a plurality of active elements is formed on a surface of a Si substrate. Specifically, for example, n-type impurity regions and a p-type impurity region for applying the reference potential to the Si substrate are formed. The n-type impurity regions become sources/drains of one or a plurality of transistors included in a readout circuit and a transfer transistor that reads a photoelectron from a light-receiving section, and the floating diffusion FD. In recent years, in order to obtain a high-resolution image, the pixel size tends to be reduced; however, in a case where the pixel size is reduced, an area where the active elements descried above can be disposed is reduced, which causes thermal noise and 1/f noise generated in a channel of the transistor to be larger. This leads to a decrease in image quality of a reproduced image.

In addition, in a case where the pixel size is reduced, the floating diffusion FD including the n-type impurity region and the gate (the transfer gate) of the transfer transistor are disposed close to each other; therefore, for example, when the transfer gate is turned off, a dark current caused by application of a large electric field is generated on the surface of the Si substrate on which the transfer gate and the floating diffusion FD are close to each other, which causes noise. This leads to a decrease in image quality of a reproduced image.

In contrast, in the present embodiment, the p-type impurity region 62 that forms the well contact region is formed inside the semiconductor substrate 10. This reduces the area of the STI occupying the front surface (the surface 10S1) of the semiconductor substrate 10 in the unit pixel P. In addition, it is possible to three-dimensionally secure a distance between the p-type impurity region 62 and the n-type impurity region (e.g., the n-type impurity region 22 that becomes the floating diffusion FD) formed on the surface 10S1 of the semiconductor substrate 10.

Thus, in the photodetector 3 according to the present embodiment, it is possible to reduce the pixel size without decreasing image quality of a reproduced image, for example.

In addition, in the photodetector 3 according to the present embodiment, it is possible to increase a formation area of the transistor such as the amplification transistor AMP by reduction in the area of the p-type impurity region formed on the surface 10S1 of the semiconductor substrate 10 in the semiconductor substrate 10.

Furthermore, in the photodetector 3 according to the present embodiment, a dark current generated at an interface of the first isolator 17X is reduced by applying a voltage lower than the reference potential to the electrical conductor 63 embedded in the first isolator 17X. This makes it possible to improve an S/N ratio.

### 6. MODIFICATION EXAMPLES

### 6-1. Modification Example 11

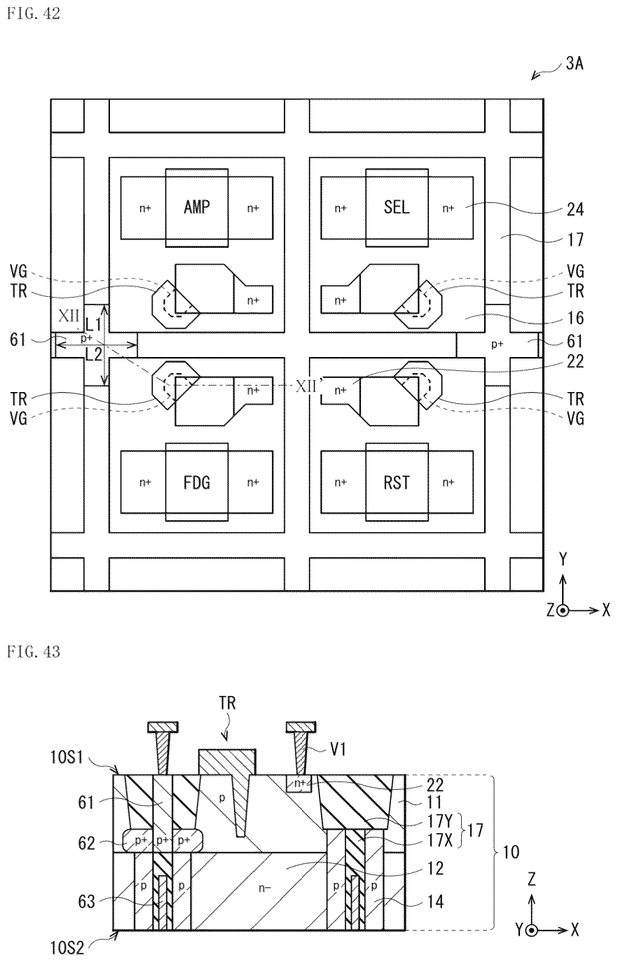

FIG. 42 schematically illustrates an example of a planar configuration of a photodetector (a photodetector 3A) according to the modification example 11 of the present disclosure. FIG. 43 schematically illustrates an example of a cross-sectional configuration of the photodetector 3A taken along a line XII-XII illustrated in FIG. 42. The photodetector 3A is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 3A is, for example, what is called a back-illuminated photodetector in the CMOS image sensor or the like.

In the third embodiment described above, the transfer transistor TR having a vertical gate (a transfer gate VG) is provided, and the cross-shaped electrical conductor 61 is embedded in the intersecting isolator 17 in a plan view. In contrast, in the photodetector 3A according to the present modification example, the transfer transistor TR having the vertical gate (the transfer gate VG) is provided, and the electrical conductor 61 that extends short (L1) in an X-axis direction close to the transfer gate VG and extends long (L2) in a Y-axis direction far from the transfer gate VG in a plan view is embedded in the intersecting isolator 17. Except for this point, the photodetector 3A has a configuration substantially similar to that of the photodetector 3.

In general, the transfer gate VG extends as long as the second isolator 17Y having an STI structure, or extends to slightly below the second isolator 17Y (on side of the surface 10S2). In a case where a lower end of the transfer gate VG and the p-type impurity region 62 are close to each other, when the transfer gate VG is turned on, a large electric field is generated between the transfer gate VG and the p-type impurity region 62, which causes noise.

In contrast, in the present modification example, the electrical conductor 61 that extends short (L1) in the X-axis direction close to the transfer gate VG and extends long (L2) in the Y-axis direction far from the transfer gate VG is embedded in the intersecting isolator 17, which makes it possible to reduce noise also in a case where the vertical transfer transistor TR is used and provided. This makes it possible to improve image quality in imaging similarly to the third embodiment described above.

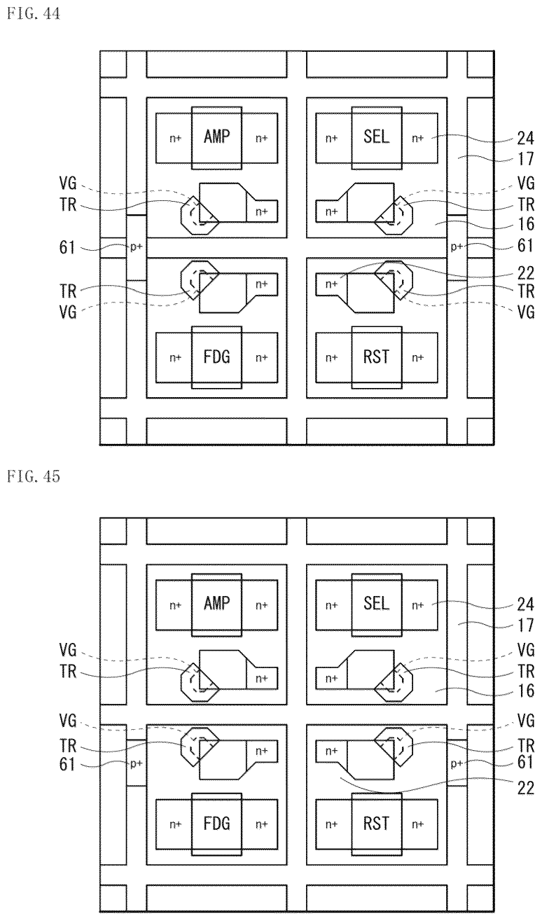

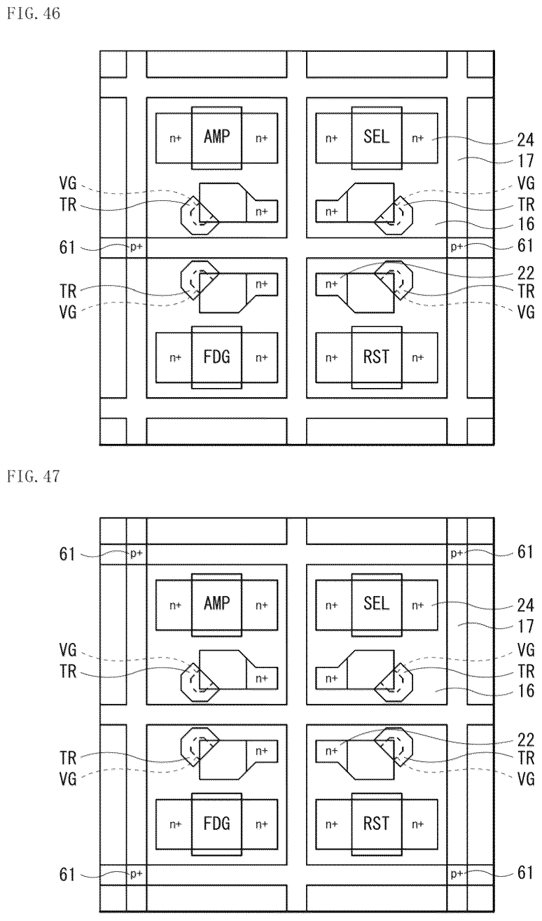

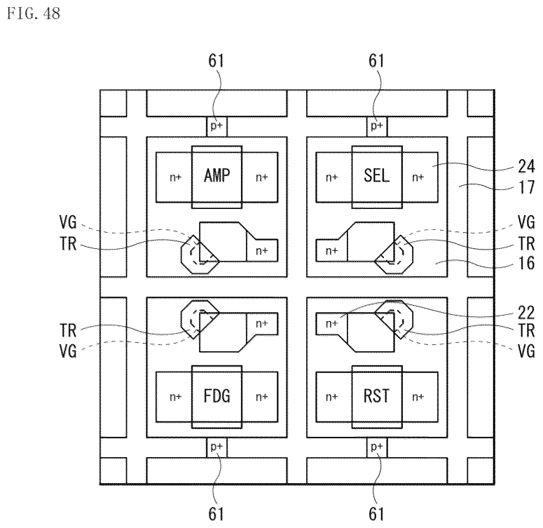

FIGS. 44 to 48 each schematically illustrate another example of the planar configuration of the photodetector 3A. The pattern of the electrical conductor 61 embedded in the isolator 17 may extend only in the column direction far from the transfer gate VG as illustrated in FIG. 44, for example. In addition, as illustrated in FIG. 45, the electrical conductor 61 may be embedded in the isolator 17 other than intersecting portions. Alternatively, as illustrated n FIGS. 46 and 47, the electrical conductor 61 may be selectively embedded only in an intersecting portion far from the transfer gate VD. Alternatively, as illustrated in FIG. 48, the electrical conductor 61 may be embedded in the isolator 17 close to the gate of the amplification transistor AMP, for example.

### 6-2. Modification Example 12

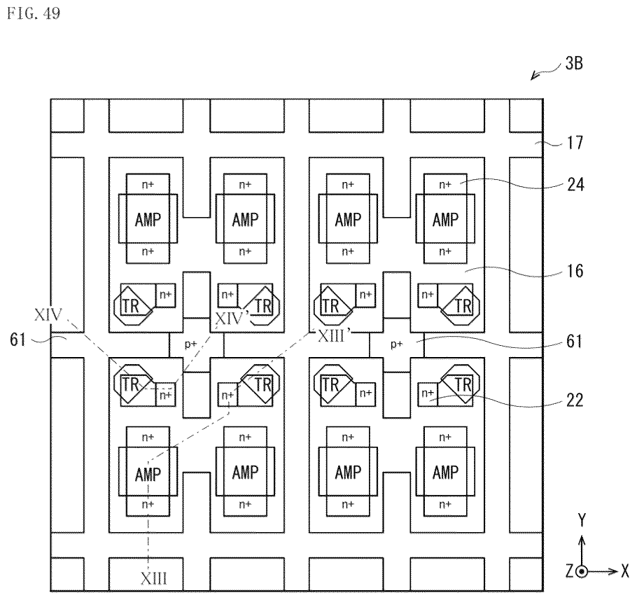

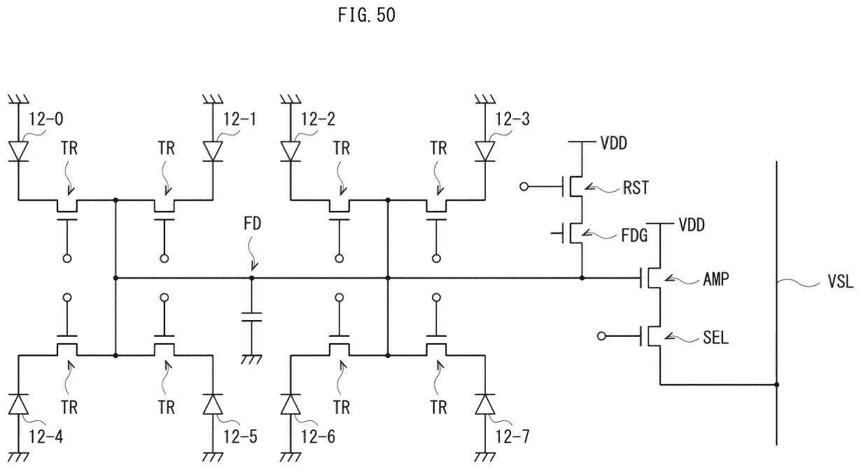

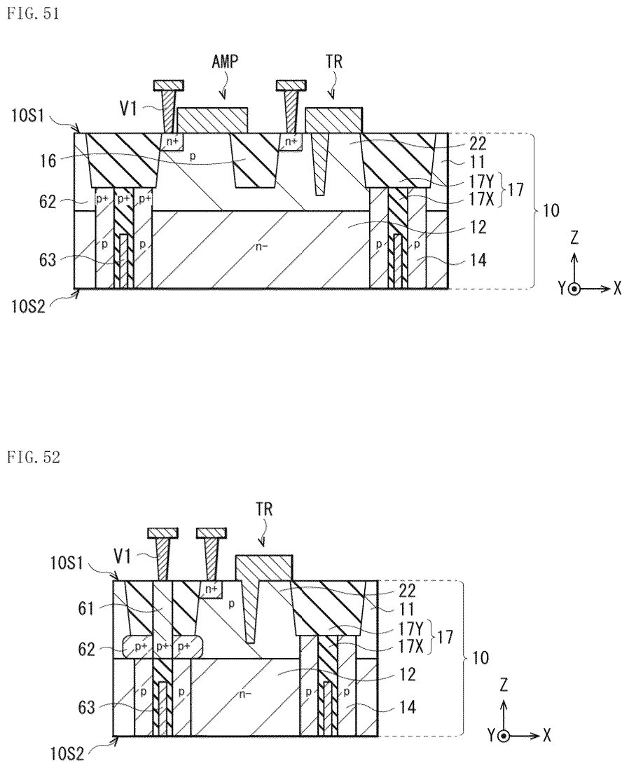

FIG. 49 schematically illustrates an example of a planar configuration of a photodetector (a photodetector 3B) according to the modification example 12 of the present disclosure. FIG. 50 illustrates an example of a readout circuit of the photodetector 3B illustrated in FIG. 49. FIG. 51 schematically illustrates an example of a cross-sectional configuration of the photodetector 3B taken along a line XI11-XI11′ illustrated in FIG. 49. FIG. 52 schematically illustrates an example of a cross-sectional configuration of the photodetector 3B taken along a line XIV-XIV′ illustrated in FIG. 49. The photodetector 3B is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 3B is, for example, what is called a back-illuminated photodetector in the CMOS image sensor or the like.

The photodetector 3B according to the present modification example includes a plurality of unit pixels P arranged in an array. The plurality of unit pixels P serves both as an imaging pixels and image plane phase difference pixels. The imaging pixel photoelectrically converts a subject image formed by an imaging lens in the light-receiving section 12 to generate a signal for image generation. The image plane phase difference pixel divides a pupil region of the imaging lens, and photoelectrically converts a subject image from a divided pupil region to generate a signal for phase difference detection.

In the present modification example, as with the third embodiment described above, the p-type impurity region 62 that forms the well contact region is formed inside the semiconductor substrate 10. This makes it possible to increase the formation area of the transistor such as the amplification transistor AMP by reduction in the area of the p-type impurity region formed on the surface 10S1 of the semiconductor substrate 10 in the semiconductor substrate 10. Furthermore, it is possible to three-dimensionally secure a distance between the n-type impurity region 22 that becomes the floating diffusion FD and the p-type impurity region 62 that forms the well contact region, which makes it possible to reduce noise by generation of a dark current caused by application of an electric field. Accordingly, it is to improve image quality in imaging.

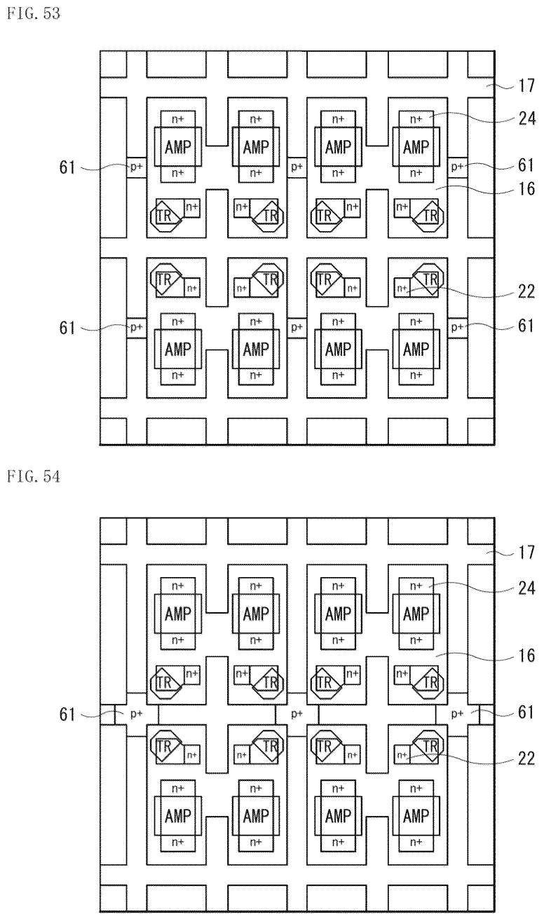

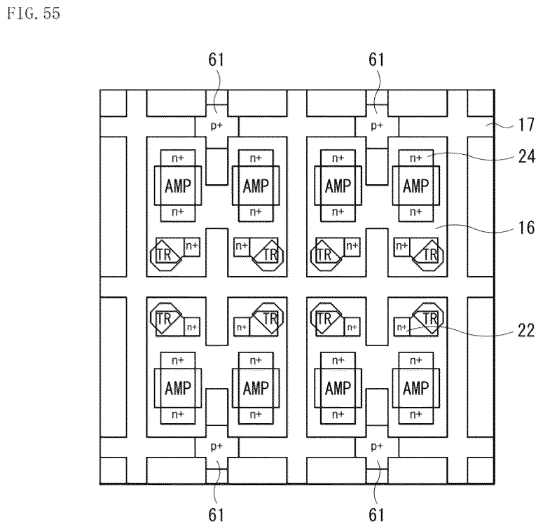

FIGS. 53 to 55 each schematically illustrate another example of the planar configuration of the photodetector B. The pattern of the electrical conductor 61 embedded in the isolator 17 may be embedded in the isolator 17 close to the gate of the amplification transistor AMP as illustrated in FIG. 53, for example. Alternatively, as illustrated in FIG. 54, the electrical conductor 61 may be embedded in an intersecting portion of the isolator 17. The intersecting portion of the isolator 17 is located at a position relatively close to the transfer gate VG, and the isolator 16 is formed between the intersecting portion of the isolator 17 and the transfer gate VG. Alternatively, as illustrated in FIG. 55, the electrical conductor 61 may be embedded in an intersecting portion of the isolator 17 that isolates the light-receiving sections 12 adjacent to each other in the unit pixel P.

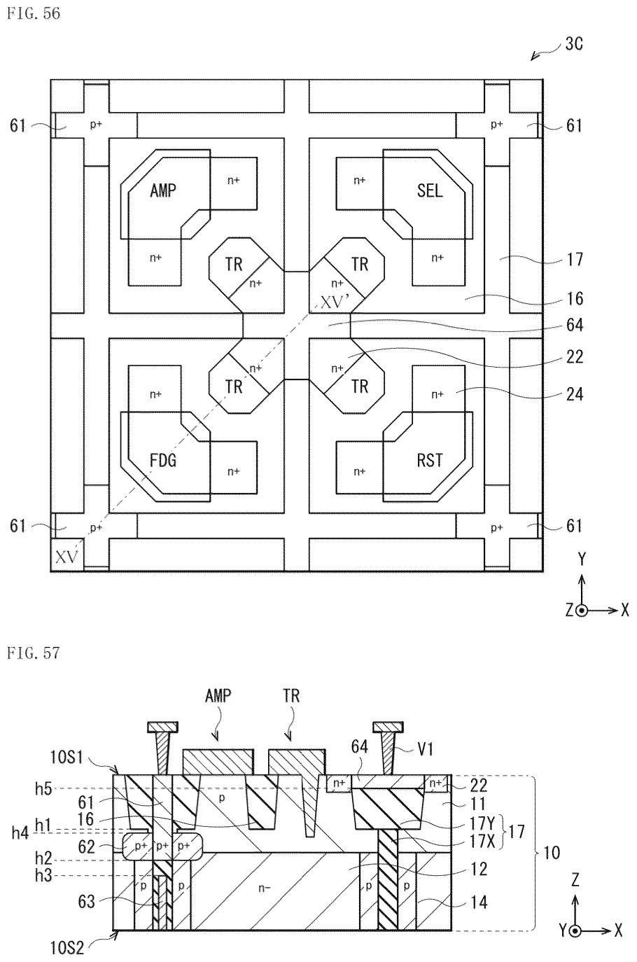

FIG. 56 schematically illustrates an example of a planar configuration of a photodetector (a photodetector 3C) according to the modification example 13 of the present disclosure. FIG. 57 schematically illustrates an example of a cross-sectional configuration of the photodetector 3C taken along a line XV-XV′ illustrated in FIG. 56. The photodetector 3C is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 3C is, for example, what is called a back-illuminated photodetector in the CMOS image sensor or the like.

In the photodetector 3C according to the present modification example, for example, as illustrated in FIG. 31, four light-receiving sections 12 (the light-receiving sections 12-0, 12-1, 12-2, and 12-3) and the transfer transistors TR share one floating diffusion FD and one readout circuit. In the photodetector 3C, an electrical conductor 64 is embedded in an upper portion of the intersecting isolator 17, and the n-type impurity region 22 is formed around the electrical conductor 64. The electrical conductor 64 is, for example, a polysilicon film doped with an n-type impurity at a high concentration (e.g., 1E18 cm⁻³ to 1E21 cm⁻³), and has a side surface in contact with the semiconductor substrate 10. The n-type impurity region 22 is formed on the surface 10S1 of the semiconductor substrate 10 by thermally diffusing the electrical conductor 64.

It is to be noted that the electrical conductor 64 embedded in the upper portion of the intersecting isolator 17 is preferably embedded substantially equally in the X-axis direction and the Y-axis direction. Thus, the n-type impurity regions 22 having a substantially equal area are formed in four unit pixels P adjacent to an intersecting portion in which the electrical conductor 64 is embedded.

As described above, in the photodetector 3C according to the present modification example, the electrical conductor 64 is embedded in the upper portion of the intersecting isolator 17, is thermally diffused, thereby forming the n-type impurity region 22 on the surface 10S1 of the semiconductor substrate 10. This makes it possible to increase the formation area of the transistor such as the amplification transistor AMP by reduction in the area of the n-type impurity region 22 formed on the surface 10S1 of the semiconductor substrate 10, as compared with the photodetector 3 according to the third embodiment described above. Accordingly, it is possible to further improve image quality in imaging, in addition to the effects of the third embodiment described above.

In addition, in the photodetector 3C according to the present modification example, a volume of the n-type impurity region 22 that becomes the floating diffusion FD formed on and in proximity to the surface 10S1 of the semiconductor substrate 10 is reduced. This reduces junction capacitance of the floating diffusion FD, which makes it possible to improve conversion efficiency of the floating diffusion FD. Accordingly, it is possible to reduce an influence of noise after a pixel, which makes it possible to further improve an S/N ratio.

### 6-4. Modification Example 14

FIG. 58 schematically illustrates an example of a planar configuration of a photodetector (a photodetector 3D) according to the modification example 14 of the present disclosure. FIG. 59 schematically illustrates an example of a cross-sectional configuration of the photodetector 3D taken along a line XVI-XVI′ illustrated in FIG. 58. The photodetector 3D is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 3D is, for example, what is called a back-illuminated photodetector in the CMOS image sensor or the like.

In the photodetector 3C according to the present modification example, for example, as illustrated in FIG. 31, four light-receiving sections 12 (the light-receiving sections 12-0, 12-1, 12-2, and 12-3) and the transfer transistors TR share one floating diffusion FD and one readout circuit. In the third embodiment described above, the isolator 17 is provided in a lattice form, for example, so as to surround an outer periphery of each of the unit pixels P. In contrast, in the photodetector 3D according to the present modification example, the isolator 17 is divided before an intersecting portion of four unit pixels P that are arranged in two rows and two columns and share one floating diffusion FD and one readout circuit. In the intersecting portion of the four unit pixels P where the isolator 17 is divided, the p-type impurity region 14 extends, and the n-type impurity region 22 that becomes the floating diffusion FD is formed on the surface 10S1 of the semiconductor substrate 10. Except for this point, the photodetector 3C has a configuration substantially similar to that of the photodetector 3.

Thus, in the photodetector 3D according to the present modification example, it is possible to serve a region where the isolator 17 is formed as the n-type impurity region 22, which makes it possible to reduce the area of the n-type impurity region 22 occupying the front surface (the surface 10S1) of the semiconductor substrate 10 in the unit pixel P. This makes it possible to increase the formation area of the transistor such as the amplification transistor AMP by reduction in the area of the n-type impurity region 22 formed on the surface 10S1 of the semiconductor substrate 10 in the unit pixel P, as compared with the photodetector 3 according to the third embodiment described above. Accordingly, it is possible to further improve image quality in imaging, in addition to the effects of the third embodiment described above.

### OTHER MODIFICATION EXAMPLES

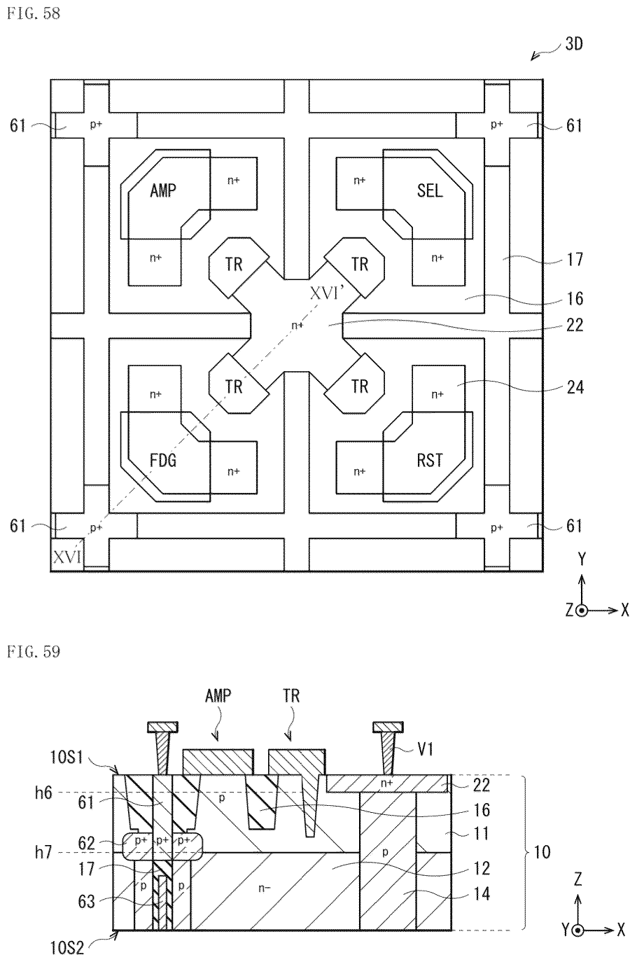

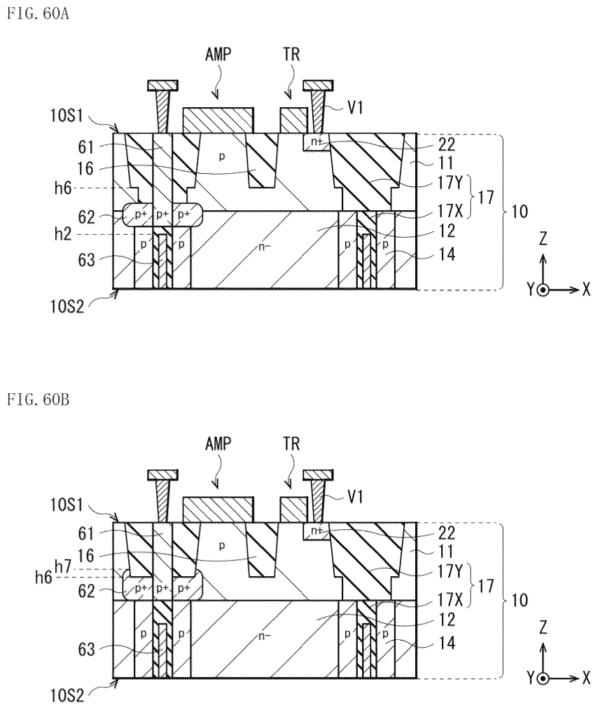

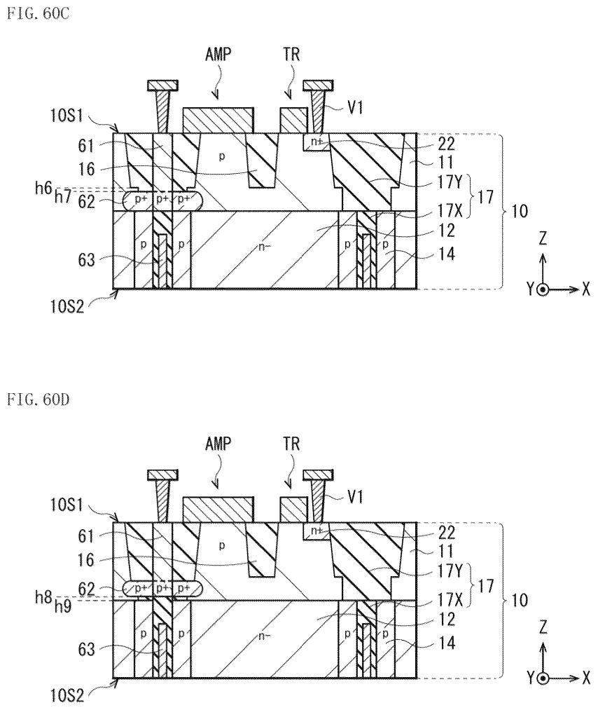

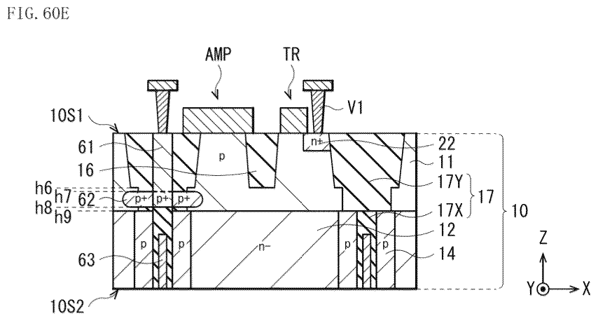

FIGS. 60A to 60E each schematically illustrate a mode of the p-type impurity region 62 formed inside the semiconductor substrate 10. For example, as illustrated in FIG. 60A, the p-type impurity region 62 formed inside the semiconductor substrate 10 may be diffused, for example, from a side surface of the first isolator 17X to inside of the semiconductor substrate 10 between a lower end h6 of the second isolator 17Y and an upper end h2 of the electrical conductor 63 embedded in the first isolator 17X. For example, as illustrated in FIG. 60B, an upper end h7 of the p-type impurity region 62 formed inside the semiconductor substrate 10 may be formed on side higher than the lower end h6 of the second isolator 17Y (on side of the surface 10S1). Alternatively, for example, as illustrated in FIG. 60C, the upper end h7 of the p-type impurity region 62 formed inside the semiconductor substrate 10 may be formed on side lower than the lower end h6 of the second isolator 17Y (on side of the surface 10S2). Alternatively, for example, as illustrated in FIG. 60D, a lower end h8 of the p-type impurity region 62 formed inside the semiconductor substrate 10 may be formed on side higher than an upper end h9 of the p-type impurity region 14 (on side of the surface 10S1). Alternatively, for example, as illustrated in FIG. 60E, the upper end h7 of the p-type impurity region 62 formed inside the semiconductor substrate 10 may be formed on side lower than the lower end h6 of he second isolator 17Y (on side of the surface 10S2), and the lower end h8 of the p-type impurity region 62 formed inside the semiconductor substrate 10 may be formed on side higher than the upper end h9 of the p-type impurity region 14 (on side the surface 10S1).

### 7. FOURTH EMBODIMENT

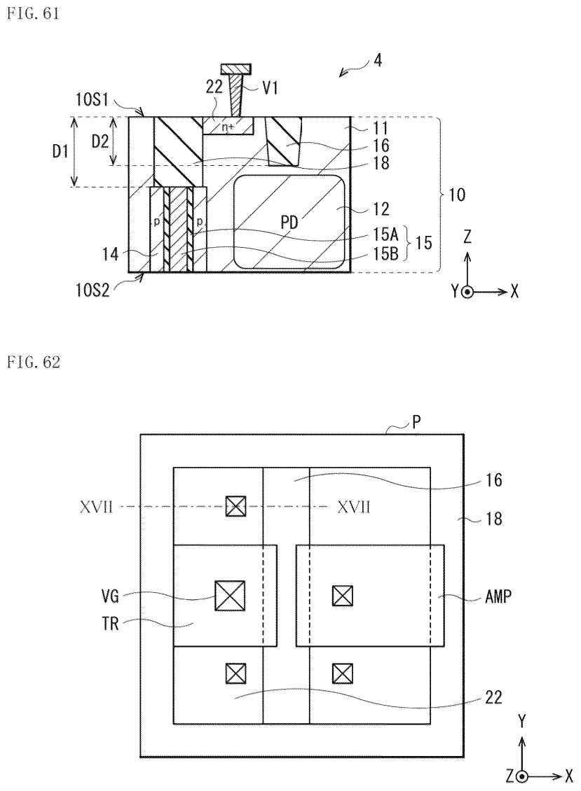

FIG. 61 schematically illustrates an example of a cross-sectional configuration of a photodetector (a photodetector 4) according to the fourth embodiment of the present disclosure. FIG. 62 schematically illustrates an example of a planar configuration of the unit pixel P of the photodetector 4 illustrated in FIG. 61, and FIG. 61 is taken along a line XVII-XVII illustrated in FIG. 62. The photodetector 4 is, for example, a CMOS image sensor or the like used in an electronic apparatus such as a digital still camera or a video camera, and includes, as an imaging region, a pixel section (the pixel section 100A) including a plurality of pixels (unit pixels P) two-dimensionally arranged in a matrix. The photodetector 4 is, for example, what is called a back-illuminated photodetector in the CMOS image sensor or the like.

### [Configuration of Unit Pixel]

The photodetector 4 includes the pixel section 100A including the plurality of unit pixels P arranged in an array. The unit pixels P adjacent to each other in the pixel section 100A are isolated from each other by the isolator 15 that extends between the pair of surfaces (the front surface (the surface 10S1) and the back surface (the surface 10S2)) opposed to each other of the semiconductor substrate 10. In each of the unit pixels P isolated from each other by the isolator 15, a plurality of active elements (e.g., the transfer transistor TR and the amplification transistor AMP) is provided on the surface 10S1 of the semiconductor substrate 10, and the plurality of active elements is isolated, for example, by the isolator 16 that extends from the surface 10S1 to the surface 10S2 of the semiconductor substrate 10 and has a bottom inside the semiconductor substrate 10. In the present embodiment, an isolator 18 is stacked on the isolator 15 on side of the surface 10S1. The isolator 18 extends from the surface 10S1 to the surface 10S2 of the semiconductor substrate 10, and has a bottom closer to the surface 10S2 of the semiconductor substrate 10 than the isolator 16.

The unit pixel P includes, as the light-receiving section 12, the photodiode PD that is formed to be embedded in the semiconductor substrate 10 having the pair of surfaces (the surface 10S1 and the surface 10S2) opposed to each other. The p-well 11 is formed as an active region on side opposite to the light incident side S1 of the light-receiving section 12 (on side of the front surface (the surface 10S1) of the semiconductor substrate 10). The p-well 11 is provided with, for example, the n-type impurity region 22, the p-type impurity region 23, and the n-type impurity region 24. The n-type impurity region 22 forms the floating diffusion FD. The p-type impurity region 23 forms the well contact region. The n-type impurity region 24 forms the source regions and the drain regions of the transfer transistor TR, and pixel transistors (e.g., the reset transistor RST, the selection transistor SEL, and the amplification transistor AMP) included in the readout circuit. The unit pixel P further includes the isolator 16 having an STI structure, and the transistor TR and the pixel transistor (e.g., the amplification transistor AMP) that are provided in the unit pixel are isolated from each other by the isolator 16.

The isolator 15 is provided between the unit pixels P adjacent to each other. The isolator 15 corresponds to a specific example of a “first isolation trench” in an embodiment of the present disclosure. As described above, the isolator 15 isolates the unit pixels P adjacent to each other in the pixel section 100A including the plurality of unit pixels P arranged in an array, and is provided in a lattice form, for example, so as to surround an outer periphery of each of the unit pixels P.

The isolator 15 has an FDTI structure that extends between the surface 10S1 and the surface 10S2 of the semiconductor substrate 10, for example, from side of the surface 10S1 to the surface 10S2. The isolator 15 has substantially the same isolation width on the light incident side S1 and the wiring layer side S2. That is, the isolator 15 extends with a substantially uniform width between the surface 10S1 and the surface 10S2 of the semiconductor substrate 10. In other words, the isolator 15 has a substantially rectangular cross-section having a substantially vertical angle between the side surface of the isolator 15 and the surface 10S1. A groove that forms the isolator 15 is filled with, for example, the insulating film 15A such as a silicon oxide (SiOₓ) film and the electrically conductive film 15B.

For example, the p-type impurity region 14 having an impurity concentration higher than that of the p-well 11 is formed on the side surface of the isolator 15. The p-type impurity region 14 corresponds to a specific example of a “fifth p-type impurity region” in an embodiment of the present disclosure.

The isolator 16 corresponds to a specific example of a “second isolation trench” in an embodiment of the present disclosure. The isolator 16 isolates active elements such as transistors provided in the unit pixel P. Specifically, as described above, the isolator 16 isolates the n-type impurity region 22, the p-type impurity region 23, and the n-type impurity region 24 that are provided on the surface 10S1 of the semiconductor substrate 10 in the unit pixel P. The n-type impurity region 22 forms the floating diffusion FD. The p-type impurity region 23 forms the well contact region. The n-type impurity region 24 forms the source regions and the drain regions of the transfer transistor TR, and pixel transistors (e.g., the reset transistor RST, the selection transistor SEL, and the amplification transistor AMP) included in the readout circuit.

As described above, the isolator 16 has an STI structure that extends from the surface 10S1 to the surface 10S2 of the semiconductor substrate 10 and has a bottom inside the semiconductor substrate 10. The isolator 16 has an isolation width on the light incident side S1 smaller than an isolation width on side of a wiring layer S2. In other words, the isolator 15 has a forward-tapered cross-section having an angle of less than 90°, e.g., about 88° between the side surface of the isolator 15 and the surface 10S1. In addition, the width of the isolator 16 exposed to the surface 10S1 is larger than the isolation width of the isolator 15. A groove that forms the isolator 16 is filled with, for example, an insulating film such as a silicon oxide (SiOₓ) film.

The isolator 18 corresponds to a specific example of a “third isolation trench” in an embodiment of the present disclosure. The isolator 18 isolates the unit pixels P adjacent to each other together with the isolator 15. The isolator 18 is formed above the isolator 15 (on side of the surface 10S1), and extends from the surface 10S1 to the surface 10S2 of the semiconductor substrate 10. The isolator 18 is in contact with the isolator 15.

As with the isolator 16, the isolator 18 has an STI structure that extends from the surface 10S1 to the surface 10S2 of the semiconductor substrate 10 and has a bottom inside the semiconductor substrate 10. The isolator 18 has substantially the same isolation width on the light incident side S1 and the wiring layer side S2. That is, the isolator 18 extends with a substantially uniform width between the surface 10S1 and the surface 10S2 of the semiconductor substrate 10. In other words, the isolator 18 has a substantially rectangular cross-section having an angle of about 90°+1° between a side surface of the isolator 18 and the surface 10S1. A groove that forms the isolator 18 is filled with, for example, an insulating film such as a silicon oxide (SiOₓ) film.

The isolator 18 has a bottom closer to the surface 10S2 of the semiconductor substrate 10 than the isolator 16. For example, while the isolator 16 has a depth of about 100 nm to about 200 nm, the isolator 18 has a depth of about 300 nm to about 500 nm. In addition, an isolation width of the isolator 18 is larger than the isolation width of the isolator 15, and the isolator 18 defines an upper end of the p-type impurity region 14 formed along the side surface of the isolator 15. The upper end of the p-type impurity region 14 is formed, for example, on side lower than an upper end of the light-receiving section 12 (on side of the surface 10S2).

### [Method of Manufacturing Photodetector]

It is possible to form the photodetector 4 as follows, for example.

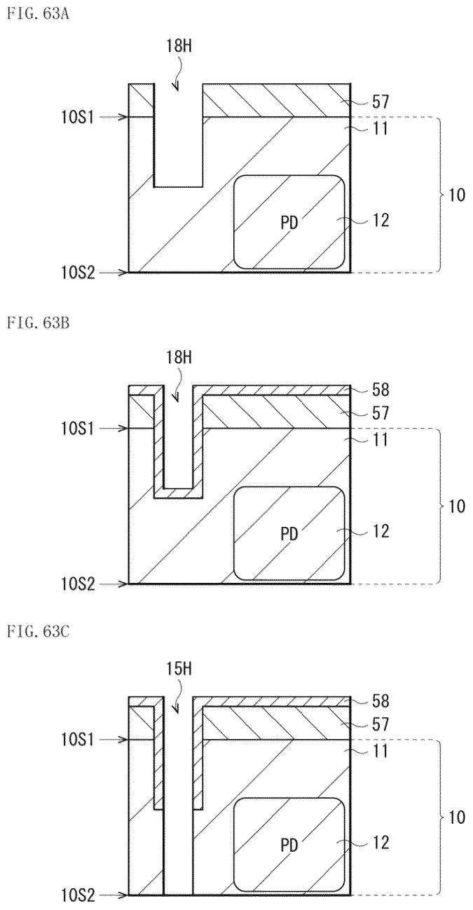

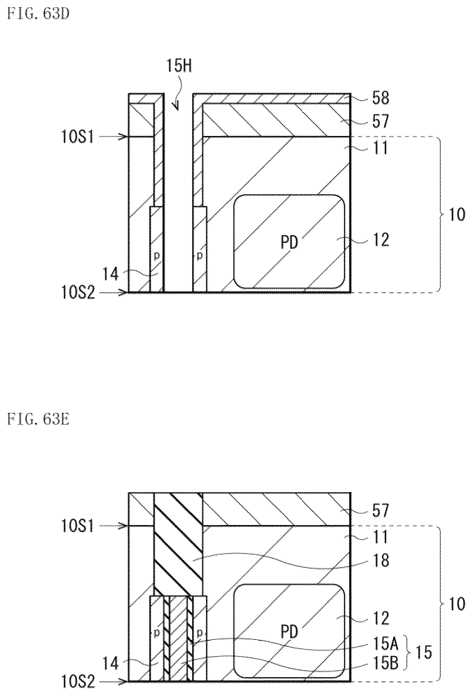

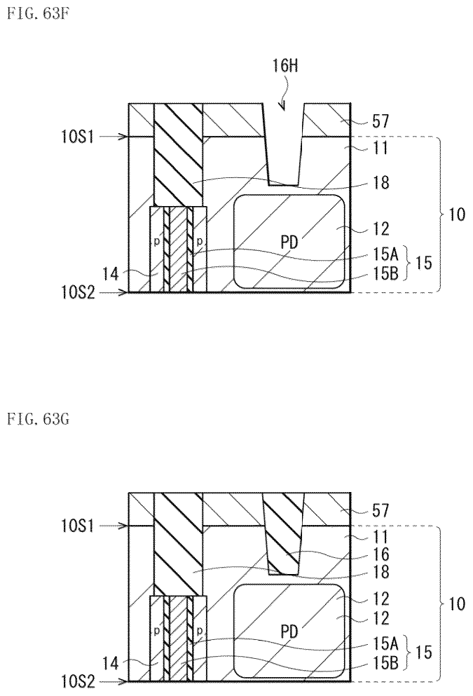

First, as illustrated in FIG. 63A, a hard mask 57 is formed on the surface 10S1 of the semiconductor substrate 10 in which the light-receiving section 12 and the p-well 11 are formed, and thereafter, for example, a groove 18H having a depth of 300 nm to 500 nm is formed with use of a photolithography method and a RIE method. Next, as illustrated in FIG. 63B, a diffusion prevention film 58 is formed on a side surface and a bottom surface of the groove 18H.

Next, as illustrated in FIG. 63C, the groove 15H that penetrates the semiconductor substrate 10 is formed with use of a photolithography method and a RIE method. Next, as illustrated in FIG. 63D, the semiconductor substrate 10 exposed inside the groove 15H is doped with, for example, boron (B) with use of, for example, a plasma doping method, a solid phase diffusion method, or the like to form the p-type impurity region 14. Subsequently, as with the first embodiment described above, as illustrated in FIG. 63E, the insulating film 15A and the electrically conductive film 15B are embedded in a lower portion of the groove 15H to form the isolator 15, and thereafter, an insulating film is embedded in an upper portion of the groove 15H (above the isolator 15) to form the isolator 18.

Next, as illustrated in FIG. 63F, for example, a groove 16H having a depth of 100 nm to 200 nm is formed with use of a photolithography method and a RIE method. Subsequently, as illustrated in FIG. 63G, an insulating film is embedded in the groove 16H, and thereafter, the hard mask 57 formed on the surface 10S1 of the semiconductor substrate 10 and the surface 10S1 of the semiconductor substrate 10 are ground by, for example, CMP to planarize the surface.

Thereafter, various kinds of wirings such as the via V1 are formed on the surface 10S1 of the semiconductor substrate 10. Thus, the photodetector 4 illustrated in FIG. 62 is completed.

### Workings and Effects

In the photodetector 4 according to the present embodiment, the isolator 18 is provided above the isolator 15 (on side of the surface 10S1). The isolator 15 isolates the unit pixels P adjacent to each other. The isolator 18 has the bottom closer to the surface 10S2 of the semiconductor substrate than the bottom of the isolator 15 that isolates active elements (e.g., the transfer transistor TR and the amplification transistor AMP) adjacent to each other in the unit pixel P. This increases a distance between the p-type impurity region 14 and the n-type impurity region 22. The p-type impurity region 14 is formed along the side surface of the isolator 15. The n-type impurity region 22 becomes the floating diffusion FD formed on the surface 10S1 of the semiconductor substrate 10. This is described below.

As described above, the pixel size has been reduced with an increase in resolution of the CMOS image sensor. In a typical CMOS image sensor, electrical and optical isolation between photodiodes is performed with use of an FTI, and a transfer transistor and a transistor included in a readout circuit are isolated by an STI. A p-type impurity region formed by doping with boron (B) with use of conformal doping technology is formed on a sidewall of the FTI.

In the typical CMOS image sensor, an STI is formed above the FTI so as to prevent a p-type impurity region formed on the sidewall of the FTI from being formed to a surface of a Si substrate. That is, an upper end of the p-type impurity region formed on the sidewall of the FTI is defined by the STI.

Incidentally, making the STI shallow to enlarge a region of the photodiode PD is considered as one technique of increasing a saturation electric charge amount (Qs) in a finer pixel. However, in a case where the STI is made shallow in the typical CMOS image sensor, an issue arises that a distance between the floating diffusion FD including the n-type impurity region formed on the surface of the Si substrate, and the p-type impurity region formed on the sidewall of the FTI is decreased and an FD electric field is increased to cause an image defect such as a white spot.

In contrast, in the present embodiment, the isolator 18 is provided above the isolator 15 (on side of the surface 10S1). The isolator 15 isolates the unit pixels P adjacent to each other. The isolator 18 has the bottom closer to the surface 10S2 of the semiconductor substrate than the bottom of the isolator 15 that isolates a plurality of active elements (e.g., the transfer transistor TR and the amplification transistor AMP) provided in the unit pixel P. This makes it possible to control the upper end of the p-type impurity region 14 formed along the side surface of the isolator 15 independently of the depth of the isolator 16. Specifically, it is possible to increase a distance between the p-type impurity region 14 and the n-type impurity region 22 that becomes the floating diffusion formed on the surface 10S1 of the semiconductor substrate 10.

Thus, in the photodetector 4 according to the present embodiment, it is possible to increase Qs without causing an image defect such as a white spot.

### 8. MODIFICATION EXAMPLES

### 8-1. Modification Example 15

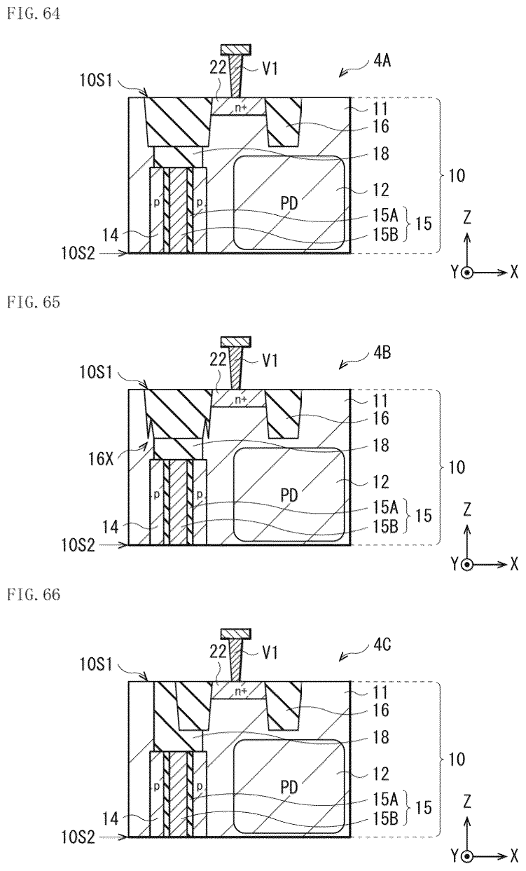

FIG. 64 schematically illustrates an example of a cross-sectional configuration of a photodetector (a photodetector 4A) according to the modification example 15 of the present disclosure. As illustrated in FIG. 64, the isolator 16 may be formed to overlap the isolator 18 that is provided on an extension line of the isolator 15.

### 8-2. Modification Example 16

FIG. 65 schematically illustrates a cross-sectional configuration of a photodetector (a photodetector 4B) according to the modification example 16 of the present disclosure. As illustrated in FIG. 65, a projected portion 16X may be formed at the bottom of the isolator 16 that is provided to overlap the isolator 18.

### 8-3. Modification Example 17

FIG. 66 schematically illustrates an example of a cross-sectional configuration of a photodetector (a photodetector 4C) according to the modification example 17 of the present disclosure. As illustrated in FIG. 66, the isolator 16 may be formed to partially overlap the isolator 18 that is provided on an extension line of the isolator 15.

### 8-4. Modification Example 18

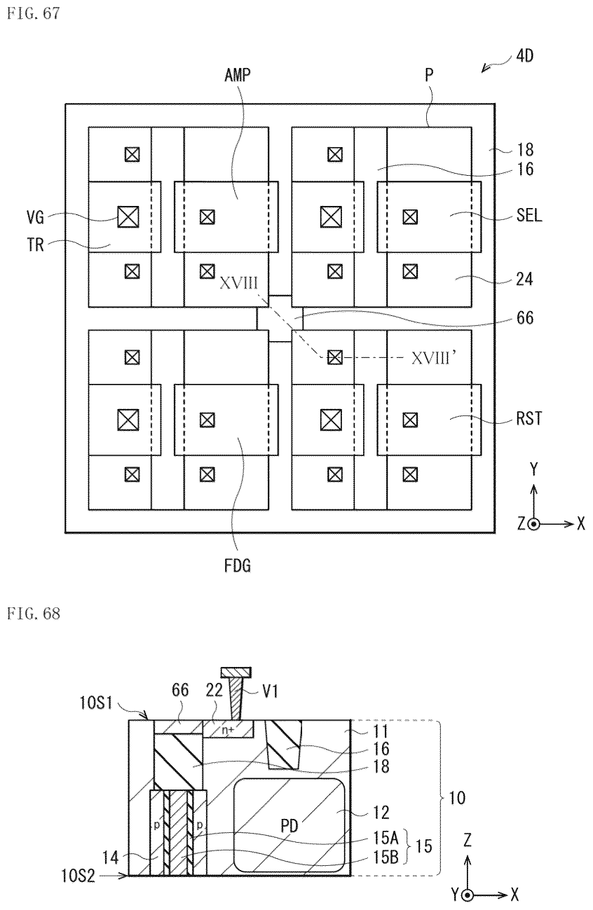

FIG. 67 schematically illustrates an example of a planar configuration of a photodetector (a photodetector 4D) according to the modification example 18 of the present disclosure. FIG. 68 schematically illustrates an example of a cross-sectional configuration of the photodetector 4D taken along a line XVIII-XVIII illustrated in FIG. 67. The photodetector 4D is, for example, a CMOS image sensor or the like used in an electronic apparatus such as a digital still camera or a video camera, and is, for example, a back-illuminated photodetector, as with the fourth embodiment described above.

In the photodetector 4D according to the present modification example, a contact section 66 is formed in an upper portion of the isolator 18. Thus, for example, as illustrated in FIG. 31, it is possible to share one floating diffusion FD and one readout circuit by four light-receiving sections 12 (the light-receiving sections 12-0, 12-1, 12-2, and 12-3) and the transfer transistors TR.

### 8-5. Modification Example 19

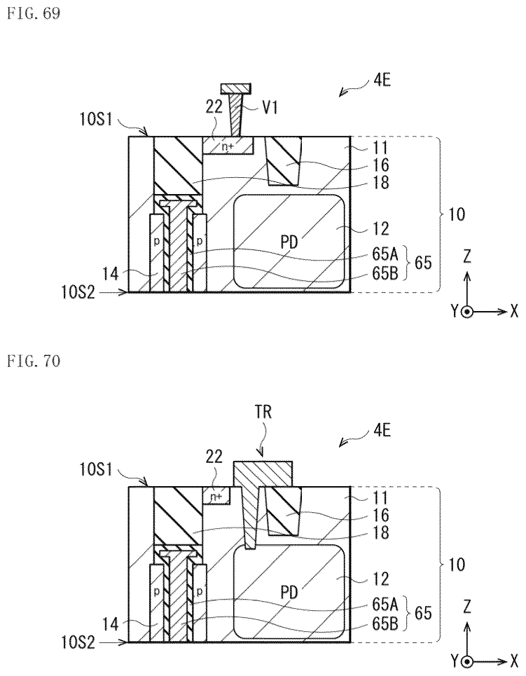

FIG. 69 schematically illustrates an example of a cross-sectional configuration of a photodetector (a photodetector 4E) according to the modification example 19 of the present disclosure. The photodetector 4E is, for example, a CMOS image sensor or the like used in an electronic apparatus such as a digital still camera or a video camera, and is, for example, a back-illuminated photodetector, as with the first embodiment described above.

In the fourth embodiment described above, the insulating film 15A and the electrically conductive film 15B are embedded in the isolator 15 that isolates the unit pixels P adjacent to each other. In contrast, in the photodetector 4E according to the present modification example, a fixed electric charge film 65B and, for example, an insulating film 65A are embedded in an isolator 65 that isolates the unit pixels P adjacent to each other. Except for this point, the photodetector 4E has a configuration substantially similar to that of the photodetector 4.

The isolator 65 isolates the unit pixels P adjacent to each other, and the fixed electric charge film 65B and the insulating film 65A are embedded in the isolator 65, as described above. Specifically, as illustrated in FIG. 69, the fixed electric charge film 65B is formed on a side surface and a bottom surface of a groove that forms the isolator 65, and the insulating film 65A is embedded inside the fixed electric charge film 65B.

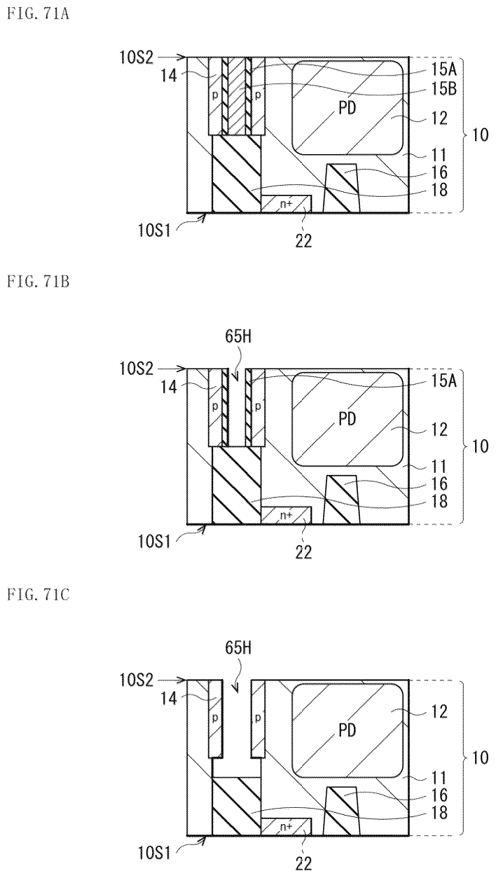

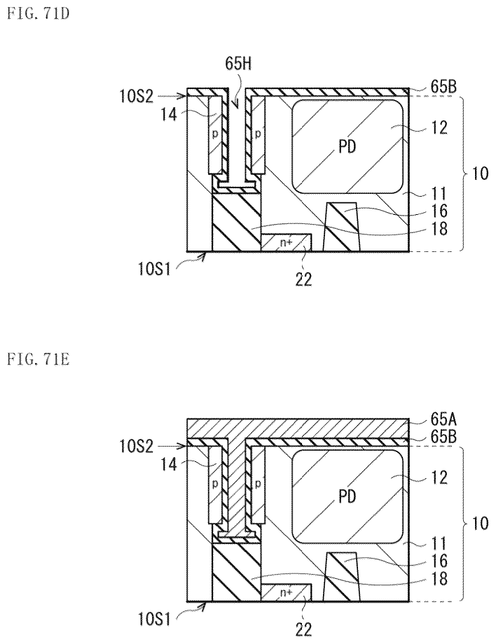

It is to be noted that, as illustrated in FIG. 70, the photodetector 4E may include the vertical transfer transistor TR.

It is possible to form the photodetector 4E as follows, for example.

As with the fourth embodiment described above, the isolator 18 and the isolator 16 are formed in order on side of the surface 10S1 of the semiconductor substrate 10, and the surface 10S1 of the semiconductor substrate 10 is ground to planarize the surface. Thereafter, thinning is performed on side of the surface 10S2 of the semiconductor substrate 10 by, for example, CMP to expose the isolator 15 as illustrated in FIG. 71A.

Next, as illustrated in FIG. 71B, the electrically conductive film 15B embedded in the isolator 15 is removed by etching to form a groove 65H. Subsequently, as illustrated in FIG. 71C, etching is further performed in the groove 65H to remove the insulating film 15A. At this time, an insulating film that is embedded in the isolator 18 and is exposed to a bottom of the groove 65H is also etched and recessed.

Next, as illustrated in FIG. 71D, the fixed electric charge film 65B is formed on a side surface and a bottom surface of the groove 65H. At this time, an antireflective film may be further formed. Subsequently, as illustrated in FIG. 71E, the insulating film 65A is embedded in the groove 65H. Thereafter, for example, the insulating film 65A and the fixed electric charge film 65B that are formed on the surface 10S2 of the semiconductor substrate 10 and the surface 10S2 of the semiconductor substrate 10 are ground by CMP to planarize the surface. Thus, the photodetector 4E illustrated in FIG. 69 is completed.

In the fourth embodiment described above, the insulating film 15A and the electrically conductive film 15B are embedded in the isolator 15. Examples of the electrically conductive film 15B include a polysilicon film; however, polysilicon absorbs light, which may decrease quantum efficiency. In contrast, in the photodetector 4E according to the present modification example, the fixed electric charge film 65B is embedded in the isolator 65 that isolates the unit pixels P adjacent to each other. This makes it possible to induce a hole to the side surface of the isolator 15 without decreasing quantum efficiency, in addition to the effects of the fourth embodiment described above, which makes it possible to suppress a dark current.

### 9. APPLICATION EXAMPLES

### Application Example 1

In addition, the photodetector (e.g., the photodetector 1) described above is applicable to various kinds of electronic apparatuses. Examples of the electronic apparatuses include a camera system such as a digital still camera or a digital video camera, a mobile phone having an imaging function, and any other apparatus having an imaging function.

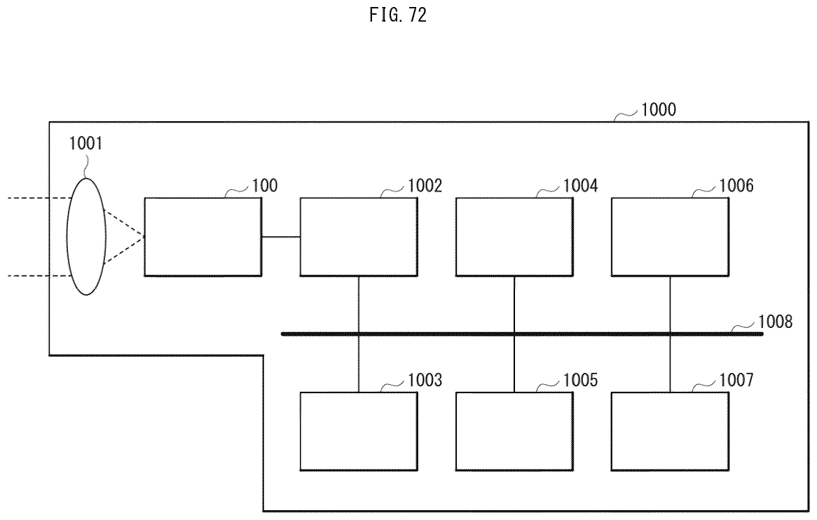

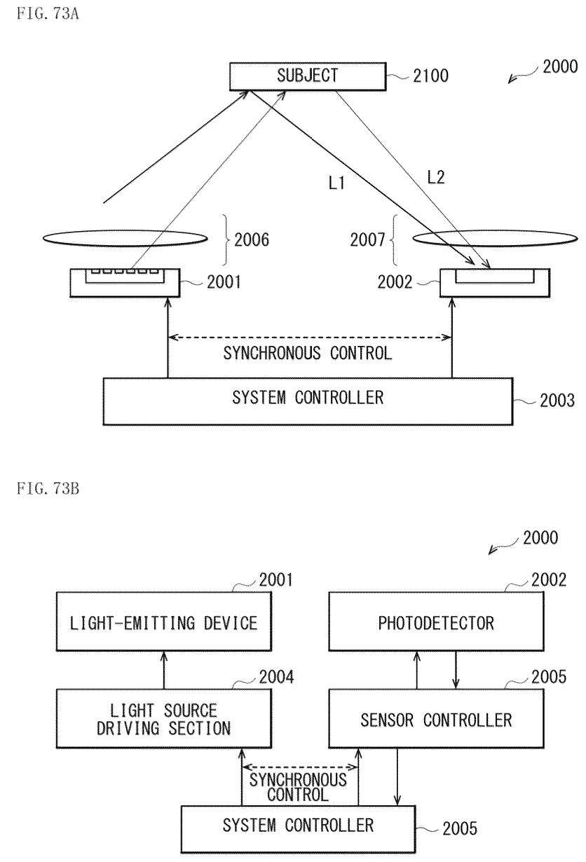

FIG. 72 is a block diagram illustrating a configuration of an electronic apparatus 1000.

As illustrated in FIG. 72, the electronic apparatus 1000 includes an optical system 1001, the photodetector 1, and a DSP (Digital Signal Processor) 1002. The DSP 1002, a memory 1003, a display device 1004, a recording device 1005, an operation system 1006, and a power supply system 1007 are coupled to each other through a bus 1008. It is possible to capture a still image and an moving image.

The optical system 1001 includes one or a plurality of lenses. The optical system 1001 takes in incident light (image light) from a subject to form an image on an imaging plane of the photodetector 1.

The photodetector 1 described above is applied as the photodetector 1. The photodetector 1 converts the light amount of the incident light of which the image is formed on the imaging plane by the optical system 1001 into an electric signal on a pixel-by-pixel basis, and supplies the electric signal as a pixel signal to the DSP 1002.

The DSP 1002 performs various kinds of signal processing on a signal from the photodetector 1 to obtain an image, and temporarily stores data of the image in the memory 1003. The data of the image stored in the memory 1003 is recorded in the recording device 1005, or is supplied to the display device 1004 to display the image. In addition, the operation system 1006 receives various kinds of operations by a user to supply operation signals to respective blocks of the electronic apparatus 1000. The power supply system 1007 supplies electric power necessary for driving the respective blocks of the electronic apparatus 1000.

### Application Example 2

FIG. 73A schematically illustrates an example of an entire configuration of a photodetection system 2000 including the photodetector 1. FIG. 73B illustrates an example of a circuit configuration of the photodetection system 2000. The photodetection system 2000 includes a light-emitting device 2001 as a light source section that emits infrared light L2, and a photodetector 2002 as a light-receiving section including a photoelectric conversion element. As the photodetector 2002, it is possible to use the photodetector 1 described above. The photodetection system 2000 may further include a system controller 2003, a light source driving section 2004, a sensor controller 2005, a light source-side optical system 2006, and a camera-side optical system 2007.

The photodetector 2002 is able to detect light L1 and the light L2. The light L1 is ambient light from outside reflected by a subject (a measurement object) 2100 (FIG. 73A). The light L2 is light emitted from the light-emitting device 2001 and then reflected by the subject 2100. The light L1 is, for example, visible light, and the light L2 is, for example, infrared light. The light L1 is detectable by an photoelectric converter in the photodetector 2002, and the light L2 is detectable by a photoelectric conversion region in the photodetector 2002. It is possible to obtain image information of the subject 2100 from the light L1 and obtain distance information between the subject 2100 and the photodetection system 2000 from the light L2. It is possible to mount the photodetection system 2000 on, for example, an electronic apparatus such as a smartphone and a mobile body such as a car. It is possible to configure the light-emitting device 2001 with, for example, a semiconductor laser, a surface-emitting semiconductor laser, or a vertical cavity surface emitting laser (VCSEL). As a method of detecting the light L2 emitted from the light-emitting device 2001 by the photodetector 2002, for example, it is possible to adopt an iTOF method; however, the method is not limited thereto. In the iTOF method, the photoelectric converter is able to measure a distance to the subject 2100 by time of flight (Time-of-Flight; TOF), for example. As a method of detecting the light L2 emitted from the light-emitting device 2001 by the photodetector 2002, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to obtain two or more images of the subject 2100 viewed from two or more different viewpoints, thereby making it possible to measure the distance between the photodetection system 2000 and the subject 2100. It is to be noted that it is possible to synchronously control the light-emitting device 2001 and the photodetector 2002 by the system controller 2003.

### 5. PRACTICAL APPLICATION EXAMPLES

### (Practical Application Example to Endoscopic Surgery System)

The technology according to the present disclosure (present technology) is applicable to various products. For example, the technology according to the present disclosure may be applied to an endoscopic surgery system.

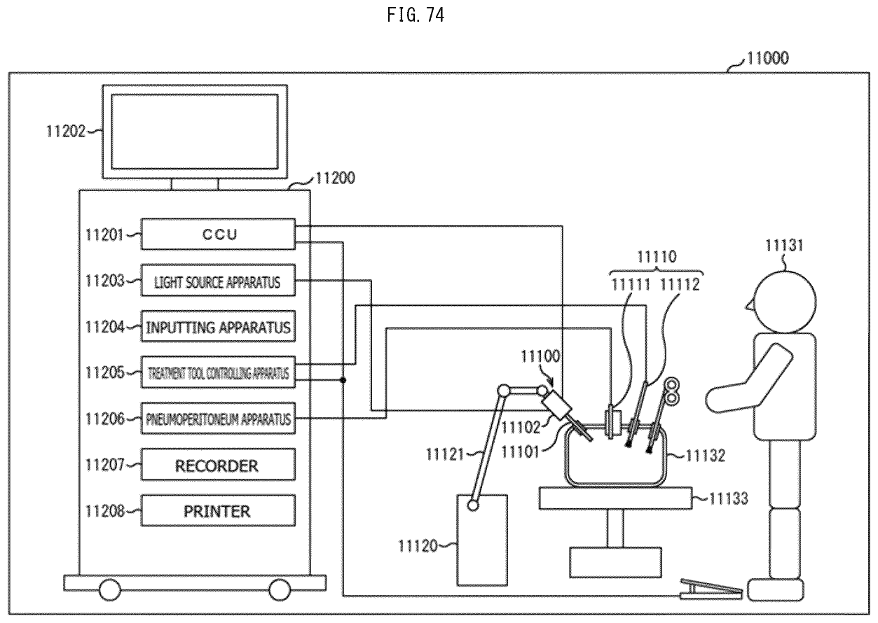

FIG. 74 is a view depicting an example of a schematic configuration of an endoscopic surgery system to which the technology according to an embodiment of the present disclosure (present technology) can be applied.

In FIG. 74, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

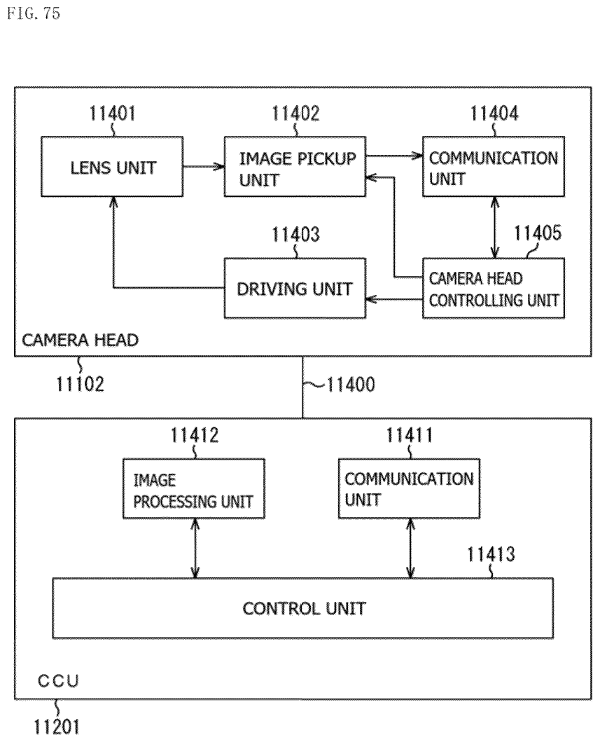

FIG. 75 is a block diagram depicting an example of a functional configuration of the camera head 11102 and the CCU 11201 depicted in FIG. 74.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure is applicable has been described above. The technology according to the present disclosure is applicable to, for example, the image pickup unit 11402 of the configurations described above. Applying the technology according to the present disclosure to the image pickup unit 11402 makes it possible to improve detection accuracy.

It is to be noted that the endoscopic surgery system has been described here as an example, but the technology according to the present disclosure may be additionally applied to, for example, a microscopic surgery system and the like.

### (Practical Application Example to Mobile Body)

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, or an agricultural machine (tractor).

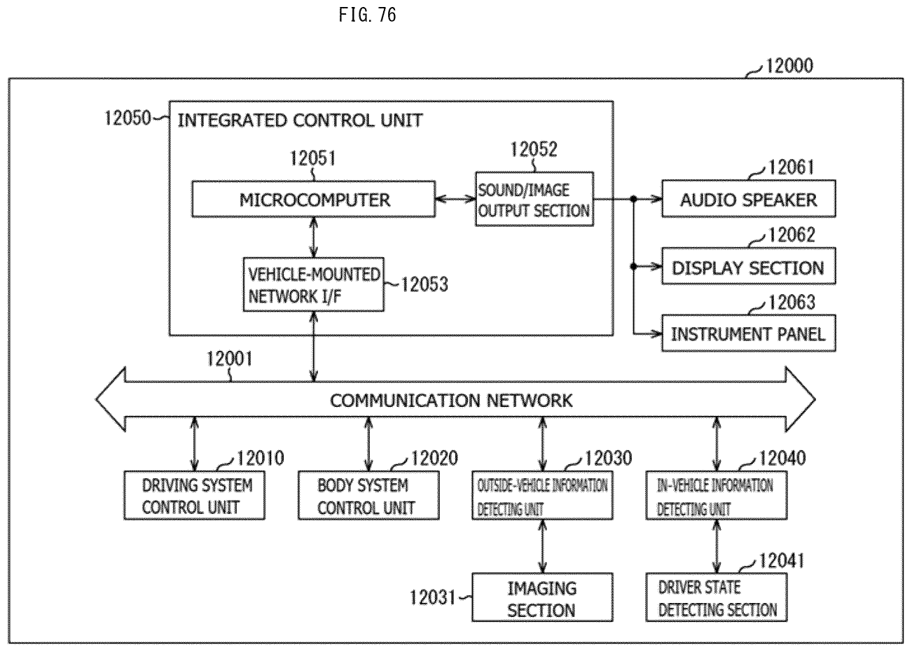

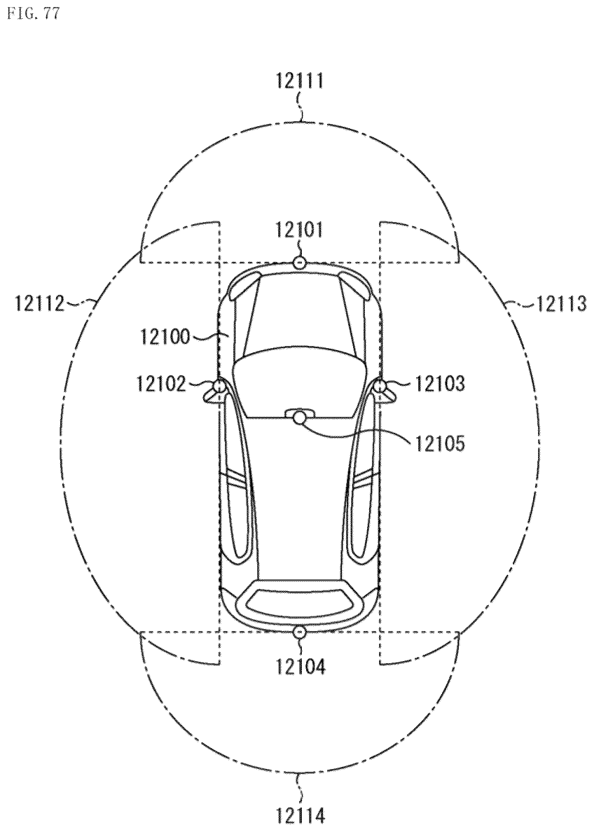

FIG. 76 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 76, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 76, an audio speaker 12061, a display section 12062, and an instrument panel 12063 are illustrated as the output device. The display section 12062 may, for example, include at least one of an on-board display and a head-up display.

FIG. 77 is a diagram depicting an example of the installation position of the imaging section 12031.

In FIG. 77, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 77 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure is applicable has been described above. The technology according to the present disclosure is appliable to the imaging section 12031 of the configurations described above. Specifically, the photodetector (e.g., the photodetector 1) according to any of the embodiments described above and the modification examples thereof is applicable to the imaging section 12031. Applying the technology according to the present disclosure to the imaging section 12031 makes it possible to obtain a high-definition shot image with less noise. This makes it possible to perform highly accurate control with use of the shot image in the mobile body control system.

Although the present disclosure has been described above with reference to the first to fourth embodiments, the modification examples 1 to 19, the application examples, and the practical application examples, the present technology is not limited to the embodiments and the like described above, and may be modified in a variety of ways. For example, the modification examples 1 to 19 described above may be combined with any other embodiment and any other modification example as appropriate.

It is to be noted that the effects described herein are merely illustrative and non-limiting, and other effects may be provided.

It is to be noted that the present disclosure may have the following configurations. According to the present technology having the following configurations, it is possible to reduce a pixel size.

(1)

A photodetector including:
a semiconductor substrate having a first surface and a second surface that are opposed to each other, and including a plurality of pixels arranged in an array;
one or a plurality of transistors provided on the first surface of the semiconductor substrate in the pixel; and
a first isolation trench that is provided in the semiconductor substrate, and isolates the plurality of pixels adjacent to each other from each other, and the first isolation trench being in contact with at least one of a source region or a drain region of the one or plurality of transistors in a plan view.
   (2)

The photodetector according to (1), in which the semiconductor substrate further includes a well contact region provided on the first surface in the pixel, the well contact region including a first p-type impurity region that applies a reference potential to the semiconductor substrate.

(3)

The photodetector according to (1) or (2), in which the first isolation trench penetrates between the first surface and the second surface of the semiconductor substrate.

(4)

The photodetector according to any one of (1) to (3), in which
the semiconductor substrate further includes a plurality of light-receiving sections formed to be embedded on side of the second surface in the plurality of respective pixels, the plurality of light-receiving sections that generates electric charge corresponding to an amount of received light by photoelectric conversion, and
the first isolation trench includes a first isolator and a second isolator, the first isolator that isolates the plurality of light-receiving sections adjacent to each other and has a side surface along which a second p-type impurity region is formed, and the second isolator being in contact with at least one of the source region or the drain region of the one or plurality of transistors.
   (5)

The photodetector according to (4), in which the first isolator and the second isolator are integrally formed.

(6)

The photodetector according to (4) or (5), in which the first isolator and the second isolator have a substantially same isolation width.

(7)

The photodetector according to (4) or (5), in which an isolation width of the second isolator is smaller than an isolation width of the first isolator.

(8)

The photodetector according to any one of (1) to (7), in which the first isolator has an air gap inside.

(9)

The photodetector according to any one of (2) to (8), further including a second isolation trench that is provided on the first surface of the semiconductor substrate, and isolates the well contact region and the one or plurality of transistors in each of the plurality of pixels.

(10)

The photodetector according to (9), in which the second isolation trench extends from the first surface to the second surface of the semiconductor substrate, and has a bottom inside the semiconductor substrate.

(11)

A photodetector including:
a semiconductor substrate having a first surface and a second surface that are opposed to each other, and including a plurality of pixels arranged in an array;
a plurality of light-receiving sections formed to be embedded in the semiconductor substrate for the plurality of respective pixels, the plurality of light-receiving sections that generates electric charge corresponding to an amount of received light by photoelectric conversion;
a first isolation trench that penetrates between the first surface and the second surface of the semiconductor substrate, and isolates the plurality of pixels adjacent to each other;
a plurality of active elements provided on the first surface of the semiconductor substrate in the pixel; and
a second isolation trench that is provided on the first surface of the semiconductor substrate to be spaced apart from the first isolation trench, and isolates the plurality of active elements.
   (12)

The photodetector according to (11), in which the semiconductor substrate at the first surface in the pixel and in proximity to the first surface is continuous.

(13)

The photodetector according to (11) or (12), further including a floating diffusion layer that is provided on the first surface of the semiconductor substrate in the pixel, and temporarily holds the electric charge generated by the light-receiving section, in which the plurality of active elements includes a transfer transistor, and one or a plurality of pixel transistors included in a readout circuit, the transfer transistor that transfers the electric charge generated by the light-receiving section to the floating diffusion layer, and the second isolation trench is provided between the transfer transistor and the one or plurality of pixel transistors.

(14)

The photodetector according to any one of (11) to (13), in which
the semiconductor substrate further includes a third p-type impurity region that is formed along a side surface of the first isolation trench, and
the plurality of active elements is surrounded by the second isolation trench and the third p-type impurity region.
   (15)

The photodetector according to (14), in which an insulating film is embedded in the second isolation trench.

(16)

The photodetector according to (14), in which a fourth p-type impurity region is formed in the second isolation trench.

(17)

The photodetector according to any one of (11) to (16), in which the first isolation trench has a substantially same isolation width between the first surface and the second surface.

(18)
The photodetector according to any one of (11) to (17), in which the first isolation trench includes a first isolator and a second isolator, the first isolator that is provided on side of the second surface of the semiconductor substrate and isolates the plurality of light-receiving sections adjacent to each other, and the second isolator that is provided on side of the first surface of the semiconductor substrate, and
an isolation width of the second isolator and an isolation width of the first isolator are different from each other, and respective bottoms of the second isolator and the second isolation trench are formed at depths different from each other.
   (19)

A photodetector including:
a semiconductor substrate having a first surface and a second surface that are opposed to each other, and including a plurality of pixels arranged in an array;
a plurality of light-receiving sections formed to be embedded in the semiconductor substrate for the plurality of respective pixels, the plurality of light-receiving sections that generates electric charge corresponding to an amount of received light by photoelectric conversion;
a first isolation trench that penetrates between the first surface and the second surface of the semiconductor substrate, and isolates the plurality of pixels adjacent to each other;
a well contact region that is embedded in the first isolation trench and is formed inside the semiconductor substrate, the well contact region including a first p-type impurity region that applies a reference potential to the semiconductor substrate; and
a floating diffusion layer provided on the first surface of the semiconductor substrate in the pixel, and including an n-type impurity region that temporarily holds the electric charge generated by the light-receiving section.
   (20)

The photodetector according to (19), in which the well contact region and the floating diffusion layer are formed in regions different from each other in a plan view.

(21)

The photodetector according to (19) or (20), further including a transfer transistor that is provided on the first surface of the semiconductor substrate in the pixel, and transfers the electric charge generated by the light-receiving section to the floating diffusion layer, in which a gate of the transfer transistor is provided in a region different from the well contact region in a plan view.

(22)

The photodetector according to any one of (19) to (21), in which
the first isolation trench includes a first isolator and a second isolator, the first isolator that is provided on side of the second surface of the semiconductor substrate and isolates the plurality of light-receiving sections adjacent to each other, and the second isolator that is provided on side of the first surface of the semiconductor substrate,
the well contact region is embedded in the second isolator, and
an electrical conductor doped with a p-type impurity is embedded in the first isolator.
   (23)

The photodetector according to (22), in which the well contact region and the floating diffusion layer are electrically coupled to the semiconductor substrate, and the electrical conductor is electrically insulated from the semiconductor substrate in the pixel.

(24)

The photodetector according to (22) or (23), in which the well contact region, the floating diffusion layer, and the electrical conductor are formed at positions different from each other in a cross-sectional view.

(25)

A photodetector including:
a semiconductor substrate having a first surface and a second surface that are opposed to each other, and including a plurality of pixels arranged in an array;
a plurality of light-receiving sections formed to be embedded in the semiconductor substrate for the plurality of respective pixels, the plurality of light-receiving sections that generates electric charge corresponding to an amount of received light by photoelectric conversion;
a plurality of active elements provided on the first surface of the semiconductor substrate in the pixel:
a first isolation trench that extends between the first surface and the second surface of the semiconductor substrate, and isolates the plurality of pixels adjacent to each other;
a second isolation trench that extends from the first surface to the second surface of the semiconductor substrate and has a bottom inside the semiconductor substrate, and isolates the plurality of active elements;
a third isolation trench that extends from the first surface to the second surface of the semiconductor substrate, is stacked on the first isolation trench, and has a bottom closer to the second surface than the bottom of the second isolation trench;
a fifth p-type impurity region formed along a side surface of the first isolation trench; and
a floating diffusion layer provided on the first surface of the semiconductor substrate in the pixel, and including an n-type impurity region that temporarily holds the electric charge generated by the light-receiving section.
   (26)

The photodetector according to (25), in which an isolation width of the third isolation trench is larger than an isolation width of the first isolation trench.

(27)

The photodetector according to (25) or (26), in which
the second isolation trench has a forward-tapered shape having an angle of less than 90° between a side surface of the second isolation trench and the first surface, and
the third isolation trench has a substantially rectangular shape having an angle of about 90°+1° between a side surface of the third isolation trench and the second surface.
   (28)

The photodetector according to any one of (25) to (27), in which the light-receiving section has a surface opposed to the first surface, the surface being closer to the second surface than the bottom of the second isolation trench and closer to the first surface than the bottom of the third isolation trench.

(29)

A method of manufacturing a photodetector including:
forming a groove in a semiconductor substrate having a first surface and a second surface that are opposed to each other, the groove extending from the first surface to the second surface;
forming a first insulating film on a side surface and a bottom surface of the groove, and thereafter forming a polysilicon film in a lower portion of the groove;
forming a second insulating film on a side surface of an upper portion of the groove, and thereafter, removing the polysilicon film and the first insulating film;
forming a p-type impurity region in the semiconductor substrate exposed to the lower portion of the groove, and thereafter, removing the first insulating film and the second insulating film in the upper portion of the groove; and
embedding a third insulating film in the groove to thereby self-alignedly form a first isolator and a second isolator, and thereafter, forming one or a plurality of transistors and a well contact region, the first isolator including a p-type impurity region on a side surface, the second isolator that isolates side of the first surface of the semiconductor substrate, and the well contact region that applies a reference potential to the semiconductor substrate.

This application claims the priority on the basis of U.S. Provisional Application No. 63/310,284 filed on Feb. 15, 2022 with United States Patent and Trademark Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A photodetector, comprising:
a semiconductor substrate having a first surface and a second surface that are opposed to each other, and including a plurality of pixels arranged in an array;
one or a plurality of transistors provided on the first surface of the semiconductor substrate in the pixel; and
a first isolation trench that is provided in the semiconductor substrate, and isolates the plurality of pixels adjacent to each other from each other, and the first isolation trench being in contact with at least one of a source region or a drain region of the one or plurality of transistors in a plan view.

2. The photodetector according to claim 1, wherein the semiconductor substrate further includes a well contact region provided on the first surface in the pixel, the well contact region including a first p-type impurity region that applies a reference potential to the semiconductor substrate.

3. The photodetector according to claim 1, wherein the first isolation trench penetrates between the first surface and the second surface of the semiconductor substrate.

4. The photodetector according to claim 1, wherein
the semiconductor substrate further includes a plurality of light-receiving sections formed to be embedded on side of the second surface in the plurality of respective pixels, the plurality of light-receiving sections that generates electric charge corresponding to an amount of received light by photoelectric conversion, and
the first isolation trench includes a first isolator and a second isolator, the first isolator that isolates the plurality of light-receiving sections adjacent to each other and has a side surface along which a second p-type impurity region is formed, and the second isolator being in contact with at least one of the source region or the drain region of the one or plurality of transistors.

5. The photodetector according to claim 4, wherein the first isolator and the second isolator are integrally formed.

6. The photodetector according to claim 4, wherein the first isolator and the second isolator have a substantially same isolation width.

7. The photodetector according to claim 4, wherein an isolation width of the second isolator is smaller than an isolation width of the first isolator.

8. The photodetector according to claim 4, wherein the first isolator has an air gap inside.

9. The photodetector according to claim 2, further comprising a second isolation trench that is provided on the first surface of the semiconductor substrate, and isolates the well contact region and the one or plurality of transistors in each of the plurality of pixels.

10. The photodetector according to claim 9, wherein the second isolation trench extends from the first surface to the second surface of the semiconductor substrate, and has a bottom inside the semiconductor substrate.

11. A photodetector, comprising:
a semiconductor substrate having a first surface and a second surface that are opposed to each other, and including a plurality of pixels arranged in an array;
a plurality of light-receiving sections formed to be embedded in the semiconductor substrate for the plurality of respective pixels, the plurality of light-receiving sections that generates electric charge corresponding to an amount of received light by photoelectric conversion;
a first isolation trench that penetrates between the first surface and the second surface of the semiconductor substrate, and isolates the plurality of pixels adjacent to each other;
a plurality of active elements provided on the first surface of the semiconductor substrate in the pixel; and
a second isolation trench that is provided on the first surface of the semiconductor substrate to be spaced apart from the first isolation trench, and isolates the plurality of active elements.

12. The photodetector according to claim 11, wherein the semiconductor substrate at the first surface in the pixel and in proximity to the first surface is continuous.

13. The photodetector according to claim 11, further comprising a floating diffusion layer that is provided on the first surface of the semiconductor substrate in the pixel, and temporarily holds the electric charge generated by the light-receiving section, wherein
the plurality of active elements includes a transfer transistor, and one or a plurality of pixel transistors included in a readout circuit, the transfer transistor that transfers the electric charge generated by the light-receiving section to the floating diffusion layer, and
the second isolation trench is provided between the transfer transistor and the one or plurality of pixel transistors.

14. The photodetector according to claim 11, wherein
the semiconductor substrate further includes a third p-type impurity region that is formed along a side surface of the first isolation trench, and
the plurality of active elements is surrounded by the second isolation trench and the third p-type impurity region.

15. The photodetector according to claim 14, wherein an insulating film is embedded in the second isolation trench.

16. The photodetector according to claim 14, wherein a fourth p-type impurity region is formed in the second isolation trench.

17. The photodetector according to claim 11, wherein the first isolation trench has a substantially same isolation width between the first surface and the second surface.

18. The photodetector according to claim 11, wherein
the first isolation trench includes a first isolator and a second isolator, the first isolator that is provided on side of the second surface of the semiconductor substrate and isolates the plurality of light-receiving sections adjacent to each other, and the second isolator that is provided on side of the first surface of the semiconductor substrate, and
an isolation width of the second isolator and an isolation width of the first isolator are different from each other, and respective bottoms of the second isolator and the second isolation trench are formed at depths different from each other.

19. A photodetector, comprising:
a semiconductor substrate having a first surface and a second surface that are opposed to each other, and including a plurality of pixels arranged in an array;
a plurality of light-receiving sections formed to be embedded in the semiconductor substrate for the plurality of respective pixels, the plurality of light-receiving sections that generates electric charge corresponding to an amount of received light by photoelectric conversion;
a first isolation trench that penetrates between the first surface and the second surface of the semiconductor substrate, and isolates the plurality of pixels adjacent to each other;
a well contact region that is embedded in the first isolation trench and is formed inside the semiconductor substrate, the well contact region including a first p-type impurity region that applies a reference potential to the semiconductor substrate; and
a floating diffusion layer provided on the first surface of the semiconductor substrate in the pixel, and including an n-type impurity region that temporarily holds the electric charge generated by the light-receiving section.

20. The photodetector according to claim 19, wherein the well contact region and the floating diffusion layer are formed in regions different from each other in a plan view.

21. The photodetector according to claim 19, further comprising a transfer transistor that is provided on the first surface of the semiconductor substrate in the pixel, and transfers the electric charge generated by the light-receiving section to the floating diffusion layer, wherein
a gate of the transfer transistor is provided in a region different from the well contact region in a plan view.

22. The photodetector according to claim 19, wherein
the first isolation trench includes a first isolator and a second isolator, the first isolator that is provided on side of the second surface of the semiconductor substrate and isolates the plurality of light-receiving sections adjacent to each other, and the second isolator that is provided on side of the first surface of the semiconductor substrate,
the well contact region is embedded in the second isolator, and
an electrical conductor doped with a p-type impurity is embedded in the first isolator.

23. The photodetector according to claim 22, wherein the well contact region and the floating diffusion layer are electrically coupled to the semiconductor substrate, and the electrical conductor is electrically insulated from the semiconductor substrate in the pixel.

24. The photodetector according to claim 22, wherein the well contact region, the floating diffusion layer, and the electrical conductor are formed at positions different from each other in a cross-sectional view.

25. A photodetector, comprising:
a semiconductor substrate having a first surface and a second surface that are opposed to each other, and including a plurality of pixels arranged in an array;
a plurality of light-receiving sections formed to be embedded in the semiconductor substrate for the plurality of respective pixels, the plurality of light-receiving sections that generates electric charge corresponding to an amount of received light by photoelectric conversion;
a plurality of active elements provided on the first surface of the semiconductor substrate in the pixel:
a first isolation trench that extends between the first surface and the second surface of the semiconductor substrate, and isolates the plurality of pixels adjacent to each other;
a second isolation trench that extends from the first surface to the second surface of the semiconductor substrate and has a bottom inside the semiconductor substrate, and isolates the plurality of active elements;
a third isolation trench that extends from the first surface to the second surface of the semiconductor substrate, is stacked on the first isolation trench, and has a bottom closer to the second surface than the bottom of the second isolation trench;
a fifth p-type impurity region formed along a side surface of the first isolation trench; and
a floating diffusion layer provided on the first surface of the semiconductor substrate in the pixel, and including an n-type impurity region that temporarily holds the electric charge generated by the light-receiving section.

26. The photodetector according to claim 25, wherein an isolation width of the third isolation trench is larger than an isolation width of the first isolation trench.

27. The photodetector according to claim 25, wherein
the second isolation trench has a forward-tapered shape having an angle of less than 90° between a side surface of the second isolation trench and the first surface, and
the third isolation trench has a substantially rectangular shape having an angle of about 90°±1° between a side surface of the third isolation trench and the second surface.

28. The photodetector according to claim 25, wherein the light-receiving section has a surface opposed to the first surface, the surface being closer to the second surface than the bottom of the second isolation trench and closer to the first surface than the bottom of the third isolation trench.

29. A method of manufacturing a photodetector, comprising:
forming a groove in a semiconductor substrate having a first surface and a second surface that are opposed to each other, the groove extending from the first surface to the second surface;
forming a first insulating film on a side surface and a bottom surface of the groove, and thereafter forming a polysilicon film in a lower portion of the groove;
forming a second insulating film on a side surface of an upper portion of the groove, and thereafter, removing the polysilicon film and the first insulating film;
forming a p-type impurity region in the semiconductor substrate exposed to the lower portion of the groove, and thereafter, removing the first insulating film and the second insulating film in the upper portion of the groove; and
embedding a third insulating film in the groove to thereby self-alignedly form a first isolator and a second isolator, and thereafter, forming one or a plurality of transistors and a well contact region, the first isolator including a p-type impurity region on a side surface, the second isolator that isolates side of the first surface of the semiconductor substrate, and the well contact region that applies a reference potential to the semiconductor substrate.
